(19) United States
(12) Patent Application Publication
(10) Pub. No.: US 2025/0366304 A1
(43) Pub. Date: Nov. 27, 2025

(54) LIGHT EMITTING ELEMENT AND DISPLAY DEVICE INCLUDING THE SAME

(71) Applicant: Samsung Display Co., Ltd., Yongin-si (KR)

(72) Inventors: HYOSUP SHIN, Yongin-si (KR); TSUYOSHI NAIJO, Yongin-si (KR); SUNG-SOO BAE, Yongin-si (KR); JIYOUNG LEE, Yongin-si (KR); CHANGWOONG CHU, Yongin-si (KR); MORAN HA, Yongin-si (KR)

(73) Assignee: Samsung Display Co., Ltd., Yongin-si (KR)

(21) Appl. No.: 19/208,743

(22) Filed: May 15, 2025

(30) Foreign Application Priority Data
May 22, 2024 (KR) 10-2024-0066710

(51) Int. Cl. H10K 50/15; H10K 50/16

(52) U.S. Cl. CPC H10K 50/156; H10K 50/166

(57) ABSTRACT

Embodiments provide a light emitting element and an electric device including the light emitting element. The light emitting element includes a first electrode, a hole transport region, an emission layer, an electron transport region, and a second electrode. The hole transport region includes a hole injection layer, at least one hole transport layer, and an electron blocking layer having a first negative giant surface potential; and the electron transport region includes at least one electron transport layer and an electron injection layer. In case that the light emitting element includes a plurality of hole transport layers, a hole transport layer adjacent to the emission layer has a second negative giant surface potential, and in case that the light emitting element includes a plurality of the electron transport layers, an electron transport layer adjacent to the second electrode has a first positive giant surface potential.

### CROSS-REFERENCE TO RELATED APPLICATION(S)

This application claims priority to and benefits of Korean Patent Application No. 10-2024-0066710 under 35 U.S.C. § 119, filed on May 22, 2024 in the Korean Intellectual Property Office, the entire contents of which are incorporated herein by reference.

### BACKGROUND

### 1. Technical Field

The disclosure relates to a light emitting element and an electric device including the same.

### 2. Description of the Related Art

Ongoing development continues for organic electroluminescence display devices and the like as image display devices. In contrast to liquid crystal display devices and the like, organic electroluminescence display devices are so-called self-emissive display devices in which holes and electrons respectively injected from a first electrode and a second electrode recombine in an emission layer, so that in the emission layer a light emitting material, which includes an organic compound, emits light to achieve display.

In the application of organic electroluminescence elements to display devices, there is a persistent demand for organic electroluminescence elements having a low driving voltage. Thus, continuous development is required for a light emitting element that is capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element exhibiting low capacitance.

The disclosure also provides a display device providing enhanced display quality.

According to an embodiment, a light emitting element may include a first electrode, a hole transport region disposed on the first electrode, an emission layer disposed on the hole transport region, an electron transport region disposed on the emission layer, and a second electrode disposed on the electron transport region; the hole transport region may include a hole injection layer disposed on the first electrode, at least one hole transport layer disposed on the hole injection layer, and an electron blocking layer disposed on the hole transport layer and having a first negative giant surface potential; the electron transport region may include at least one electron transport layer disposed on the emission layer, and an electron injection layer disposed on the electron transport layer; the at least one hole transport layer may include multiple hole transport layers and/or the at least one electron transport layer may include multiple electron transport layers; when the light emitting element includes multiple hole transport layers, a hole transport layer adjacent to the emission layer among the hole transport layers may have a second negative giant surface potential; and when the light emitting element includes multiple electron transport layers, an electron transport layer adjacent to the second electrode among the electron transport layers may have a first positive giant surface potential.

In an embodiment, the second negative giant surface potential may have an absolute value that is less than an absolute value of the first negative giant surface potential.

In an embodiment, the first negative giant surface potential may be equal to or less than about −10 mV/nm.

In an embodiment, the at least one hole transport layer may include a first hole transport layer disposed on the hole injection layer, and a second hole transport layer disposed on the first hole transport layer and having the second negative giant surface potential; and the second negative giant surface potential may be equal to or less than about −10 mV/nm.

In an embodiment, the first hole transport layer may have a second positive giant surface potential or a third negative giant surface potential; and an absolute value of the second positive giant surface potential and an absolute value of the third negative giant surface potential may each independently be equal to or less than about 10 mV/nm.

In an embodiment, the second positive giant surface potential and the third negative giant surface potential may each have a smaller absolute value than the second negative giant surface potential.

In an embodiment, the at least one hole transport layer may include a first hole transport layer disposed on the hole injection layer, a second hole transport layer disposed on the first hole transport layer, and a third hole transport layer disposed on the second hole transport layer; at least one of the second hole transport layer and the third hole transport layer may have the second negative giant surface potential; and the second negative giant surface potential may be equal to or less than about −10 mV/nm.

In an embodiment, the second hole transport layer may have the second negative giant surface potential; the first hole transport layer and the third hole transport layer may each independently have a third positive giant surface potential or a fourth negative giant surface potential; and an absolute value of the third positive giant surface potential and an absolute value of the fourth negative giant surface potential may each independently be equal to or less than about 10 mV/nm.

In an embodiment, the third hole transport layer may have the second negative giant surface potential; the first hole transport layer and the second hole transport layer may each independently have a third positive giant surface potential or a fourth negative giant surface potential; and an absolute value of the third positive giant surface potential and an absolute value of the fourth negative giant surface potential may each independently be equal to or less than about 10 mV/nm.

In an embodiment, the emission layer may have a fourth positive giant surface potential.

In an embodiment, the fourth positive giant surface potential may be equal to or greater than about 10 mV/nm.

In an embodiment, the electron transport region may further include a hole blocking layer disposed between the emission layer and the electron transport layer.

In an embodiment, the at least one electron transport layer may include a first electron transport layer disposed on the emission layer, and a second electron transport layer disposed on the first electron transport layer and having the first positive giant surface potential; and the first positive giant surface potential may be equal to or greater than about 10 mV/nm.

In an embodiment, the first electron transport layer may have a fifth positive giant surface potential or a fifth negative giant surface potential; and an absolute value of the fifth positive giant surface potential and an absolute value of the fifth negative giant surface potential may each independently be equal to or less than about 10 mV/nm.

In an embodiment, the fifth positive giant surface potential and the fifth negative giant surface potential may each have a smaller absolute value than the first positive giant surface potential.

In an embodiment, the at least one electron transport layer may include a first electron transport layer disposed on the emission layer, a second electron transport layer disposed on the first electron transport layer, and a third electron transport layer disposed on the second electron transport layer; the second electron transport layer or the third electron transport layer may have the first positive giant surface potential; and the first positive giant surface potential may be equal to or greater than about 10 mV/nm.

In an embodiment, the second electron transport layer may have the first positive giant surface potential; the first electron transport layer and the third electron transport layer may each independently have a sixth positive giant surface potential or a sixth negative giant surface potential; and an absolute value of the sixth positive giant surface potential and an absolute value of the sixth negative giant surface potential may each independently be equal to or less than about 10 mV/nm.

In an embodiment, the third electron transport layer may have the first positive giant surface potential; the first electron transport layer and the second electron transport layer may each independently have a sixth positive giant surface potential or a sixth negative giant surface potential; and an absolute value of the sixth positive giant surface potential and an absolute value of the sixth negative giant surface potential may each independently be equal to or less than about 10 mV/nm.

In an embodiment, the at least one hole transport layer may include a first hole transport layer disposed on the hole injection layer, and a second hole transport layer disposed on the first hole transport layer and having the second negative giant surface potential; the at least one electron transport layer may include a first electron transport layer disposed on the emission layer; the second negative giant surface potential may be equal to or less than about −10 mV/nm; and an absolute value of the giant surface potential of the first hole transport layer and an absolute value of the giant surface potential of the first electron transport layer may each independently be equal to or less than about 10 mV/nm.

In an embodiment, the at least one hole transport layer may include a first hole transport layer disposed on the hole injection layer; the at least one electron transport layer may include a first electron transport layer disposed on the emission layer, and a second electron transport layer disposed on the first electron transport layer and having the first positive giant surface potential; the first positive giant surface potential may be equal to or greater than about 10 mV/nm; and an absolute value of the giant surface potential of the first hole transport layer and an absolute value of the giant surface potential of the first electron transport layer may each independently be equal to or less than about 10 mV/nm.

In an embodiment, the at least one hole transport layer may include a first hole transport layer disposed on the hole injection layer, and a second hole transport layer disposed on the first hole transport layer and having the second negative giant surface potential; the at least one electron transport layer may include a first electron transport layer disposed on the emission layer, and a second electron transport layer disposed on the first electron transport layer and having the first positive giant surface potential; the second negative giant surface potential may be equal to or less than about −10 mV/nm; the first positive giant surface potential may be equal to or greater than about 10 mV/nm; and an absolute value of the giant surface potential of the first hole transport layer and an absolute value of the giant surface potential of the first electron transport layer may each independently be equal to or less than about 10 mV/nm.

According to an embodiment, a light emitting element may include a first electrode, a hole transport region disposed on the first electrode, an emission layer disposed on the hole transport region, an electron transport region disposed on the emission layer, and a second electrode disposed on the electron transport region; the hole transport region may include a hole injection layer disposed on the first electrode, at least one hole transport layer disposed on the hole injection layer, and an electron blocking layer disposed on the hole transport layer and having a giant surface potential equal to or less than about −10 mV/nm; the electron transport region may include at least one electron transport layer disposed on the emission layer, and an electron injection layer disposed on the electron transport layer; the at least one hole transport layer may include multiple hole transport layers and/or the at least one electron transport layer may include multiple electron transport layers; when the light emitting element includes multiple hole transport layers, a hole transport layer adjacent to the emission layer among the hole transport layers may have a giant surface potential equal to or less than about −10 mV/nm; and when the light emitting element includes multiple electron transport layers, an electron transport layer adjacent to the second electrode among the electron transport layers may have a giant surface potential equal to or greater than about 10 mV/nm.

According to an embodiment, an electric device may comprise a display device. The display device may include a circuit layer disposed on a base layer, a pixel defining film disposed on the circuit layer and having pixel openings defined therein, and light emitting elements disposed on the circuit layer; each light emitting element may include a first electrode, a hole transport region, an emission layer, an electron transport region, and a second electrode that are sequentially stacked; the hole transport region may include a hole injection layer disposed on the first electrode, at least one hole transport layer disposed on the hole injection layer, and an electron blocking layer disposed on the hole transport layer and having a first negative giant surface potential; the electron transport region may include at least one electron transport layer disposed on the emission layer, and an electron injection layer disposed on the electron transport layer; the at least one hole transport layer may include multiple hole transport layers and/or the at least one electron transport layer may include multiple electron transport layers; when the at least one hole transport layer includes multiple hole transport layers, a hole transport layer adjacent to the emission layer among the hole transport layers may have a second negative giant surface potential; and when the at least one electron transport layer includes multiple electron transport layers, an electron transport layer adjacent to the second electrode among the electron transport layers may have a first positive giant surface potential.

In an embodiment, the display device may further include a light control layer including quantum dots, and a color filter layer disposed on the light control layer, wherein the color filter layer may include a first filter that transmits red light, a second filter that transmits green light, and a third filter that transmits blue light.

According to an embodiment, a display device may include a red light emitting region, a green light emitting region, and a blue light emitting region, which are distinct from each other in a plan view, a circuit layer disposed on a base layer, and a display element layer disposed on the circuit layer; the display element layer may include light emitting elements that are disposed to correspond to each of the red light emitting region, the green light emitting region, and the blue light emitting region; at least one of the light emitting elements may include a hole transport region, an emission layer, and an electron transport layer that are sequentially stacked; the hole transport region may include a hole injection layer disposed on the first electrode, at least one hole transport layer disposed on the hole injection layer, and an electron blocking layer disposed on the hole transport layer and having a first negative giant surface potential; the electron transport region may include at least one electron transport layer disposed on the emission layer, and an electron injection layer disposed on the electron transport layer; the at least one hole transport layer may include multiple hole transport layers and/or the at least one electron transport layer may include multiple electron transport layers; when the at least one hole transport layer includes multiple hole transport layers, a hole transport layer adjacent to the emission layer among the hole transport layers may have a second negative giant surface potential; and when the at least one electron transport layer includes multiple electron transport layers, an electron transport layer adjacent to the second electrode among the electron transport layers may have a first positive giant surface potential.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a display device according to an embodiment;

FIGS. 3 to 10 are each a schematic cross-sectional view of a light emitting element according to an embodiment;

FIGS. 11A to 11E are each a schematic cross-sectional view of a light emitting element according to an embodiment;

FIGS. 12 and 13 are each a schematic cross-sectional view of a display device according to an embodiment;

FIG. 14 is a schematic cross-sectional view of a display device according to an embodiment; and

FIG. 15 is a schematic cross-sectional view of a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the term “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. A hydrocarbon ring and a heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbons in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbons in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

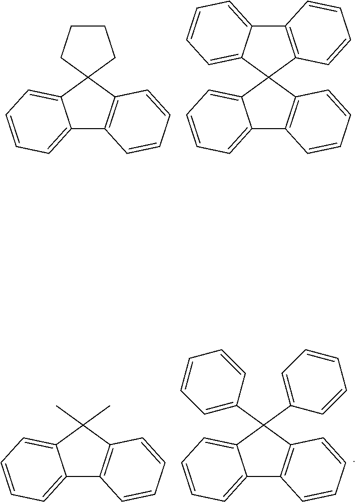

In the specification, a heterocyclic group may be any functional group or substituent derived from a ring that includes at least one of B, O, N, P, Si, and S as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group contains two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may include one of the following structures, but embodiments are not limited thereto.

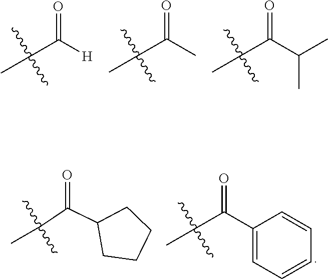

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or to an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or to an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or to an aryl group as defined above. A boron group may be an alkyl boron group or an aryl boron group. Examples of a boron group may include a dimethylboron group, a t-butylmethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols [symbol] and [symbol] each represent a bond to a neighboring atom in a corresponding formula or moiety.

Hereinafter, embodiments will be described with reference to the accompanying drawings.

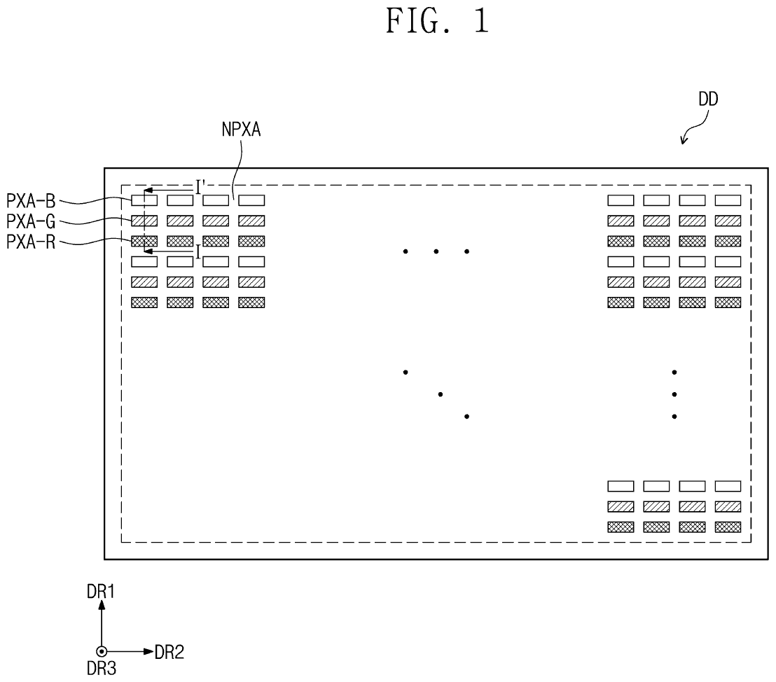

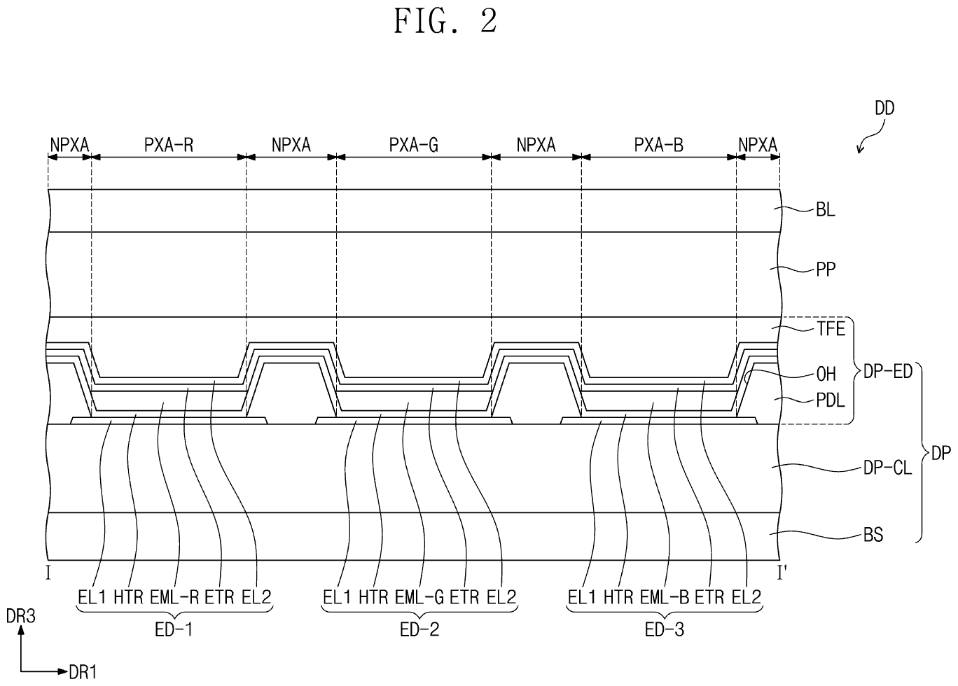

FIG. 1 is a schematic plan view of a display device DD according to an embodiment. FIG. 2 is a schematic cross-sectional view of the display device DD according to an embodiment. FIG. 2 is a schematic cross-sectional view of a portion taken along virtual line I-I′ in FIG. 1.

The display device DD may include a display panel DP and an optical layer PP disposed on the display panel DP. The display panel DP includes light-emitting elements ED-1, ED-2, and ED-3. The display device DD may include multiples of each of the light-emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display device layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display device layer DP-ED. The display device layer DP-ED may include a pixel defining film PDL, light-emitting elements ED-1, ED-2, and ED-3 disposed between portions of the pixel defining film PDL, and an encapsulation layer TFE disposed on the light-emitting elements ED-1, ED-2, and ED-3.

The base layer BS may provide a base surface on which the display device layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light-emitting elements ED-1, ED-2, and ED-3 of the display device layer DP-ED.

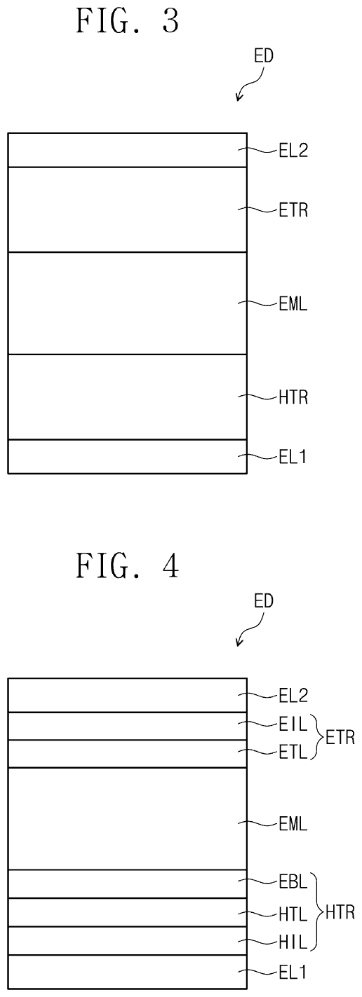

The light-emitting elements ED-1, ED-2, and ED-3 may each have a structure of a light-emitting element ED according to any one of FIGS. 3 to 6, which will be described later. The light-emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light-emitting elements ED-1, ED-2, and ED-3 are disposed in openings OH defined in the pixel defining film PDL, and the hole transport region HTR, the electron transport region ETR, and the second electrode EL2 are each provided as a common layer for the light-emitting elements ED-1, ED-2, and ED-3. However, embodiments are not limited thereto. Although not shown in FIG. 2, in an embodiment, the hole transport region HTR and the electron transport region ETR may each be provided by being patterned in the openings OH defined in the pixel defining film PDL. For example, in an embodiment, the hole transport region HTR, the emission layers EML-R, EML-G, and EML-B, and the electron transport region ETR of the light-emitting element ED-1, ED-2, and ED-3 may be provided by being patterned through an inkjet printing method.

The encapsulation layer TFE may cover the light-emitting elements ED-1, ED-2, and ED-3. The encapsulation layer TFE may seal the display device layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). The encapsulation layer TFE according to an embodiment may include at least one organic film (hereinafter, an encapsulation-organic film) and at least one encapsulation-inorganic film.

The encapsulation-inorganic film protects the display device layer DP-ED from moisture and/or oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light-emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining film PDL. The non-light emitting regions NPXA may be regions between the adjacent light emitting regions PXA-R, PXA-G, and PXA-B, and which may correspond to the pixel defining film PDL. In an embodiment, the light emitting regions PXA-R, PXA-G, and PXA-B may each correspond to a pixel. The pixel defining film PDL may separate the light-emitting elements ED-1, ED-2, and ED-3. The emission layers EML-R, EML-G, and EML-B of the light-emitting elements ED-1, ED-2, and ED-3 may be disposed in openings OH defined in the pixel defining film PDL and separated from each other.

The light emitting regions PXA-R, PXA-G, and PXA-B may be arranged into groups according to the color of light generated from the light-emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light-emitting elements ED-1, ED-2, and ED-3 may emit light having wavelengths that are different from each other. For example, in an embodiment, the display device DD may include a first light-emitting element ED-1 that emits red light, a second light-emitting element ED-2 that emits green light, and a third light-emitting element ED-3 that emits blue light. For example, the red light emitting region PXA-R, the green light emitting region PXA-G, and the blue light emitting region PXA-B of the display device DD may respectively correspond to the first light-emitting element ED-1, the second light-emitting element ED-2, and the third light-emitting element ED-3.

However, embodiments are not limited thereto, and the first to third light-emitting elements ED-1, ED-2, and ED-3 may emit light in a same wavelength range, or at least one light-emitting element may emit light in a wavelength range that is different from the remainder. For example, the first to third light-emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2. The third directional axis DR3 may be perpendicular to a plane defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIGS. 3 to 10 are each a schematic cross-sectional view of a light emitting element ED according to an embodiment. The light emitting elements ED according to embodiments may each include a first electrode EL1, a second electrode EL2 facing the first electrode EL1, and at least one functional layer disposed between the first electrode EL1 and the second electrode EL2.

The light emitting element ED may include a hole transport region HTR, an emission layer EML, and an electron transport region ETR, which may be stacked in that order, as the at least one functional layer. As shown in FIG. 3, the light emitting element ED according to an embodiment may include a first electrode EL1, a hole transport region HTR, an emission layer EML, an electron transport region ETR, and a second electrode EL2.

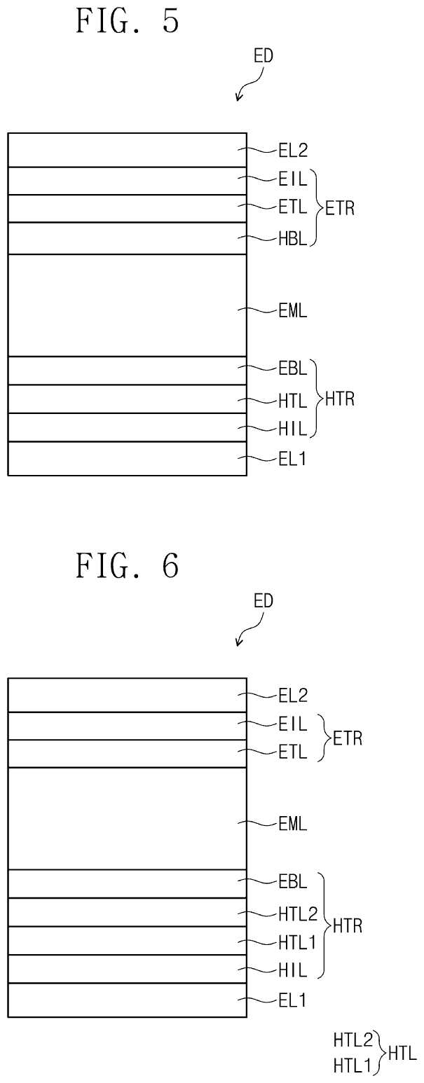

In comparison to FIG. 3, FIG. 4 is a schematic cross-sectional view of a light emitting element ED, in which the hole transport region HTR includes a hole injection layer HIL, a hole transport layer HTL, and an electron blocking layer EBL, and the electron transport region ETR includes an electron injection layer EIL and an electron transport layer ETL. In comparison to FIG. 3, FIG. 5 is a schematic cross-sectional view of a light emitting element ED, in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL.

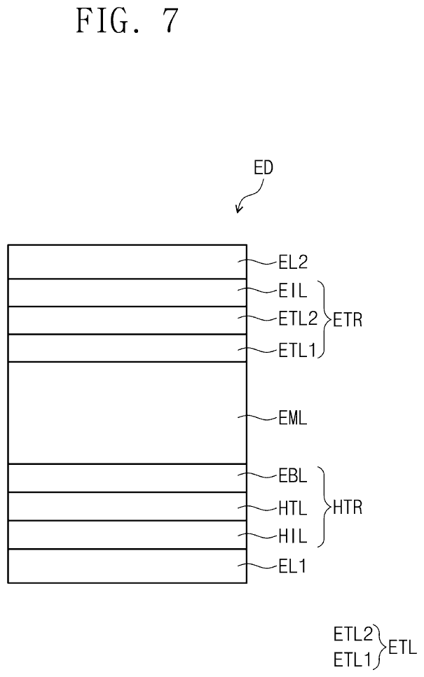

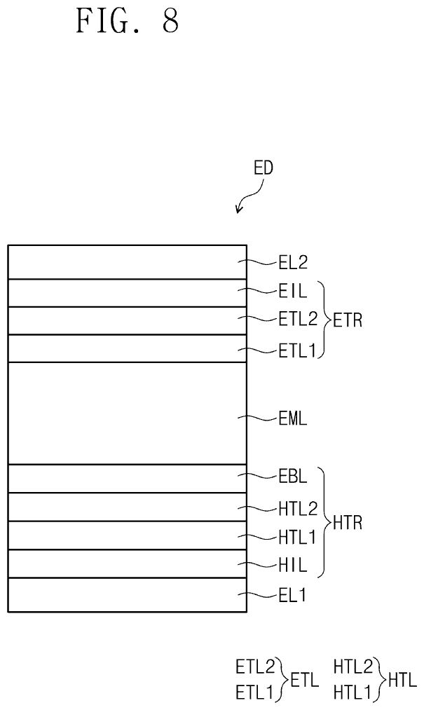

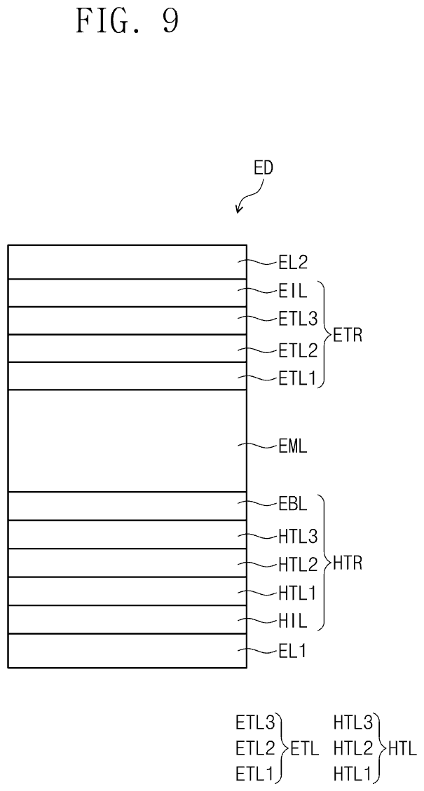

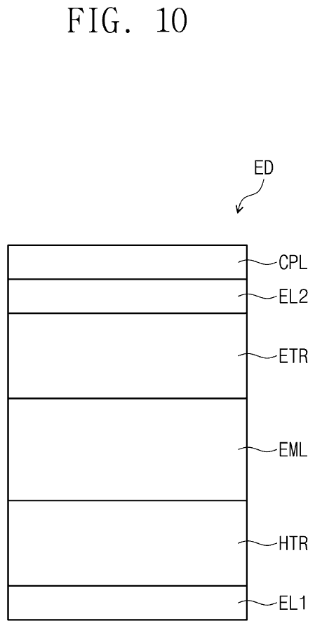

In comparison to FIG. 4, FIG. 6 is a schematic cross-sectional view of a light emitting element ED, in which the hole transport layer HTL includes hole transport layers HTL1 and HTL2. In comparison to FIG. 4, FIG. 7 is a schematic cross-sectional view of a light emitting element ED, in which the electron transport layer ETL includes electron transport layers ETL1 and ETL2. In comparison to FIG. 4, FIG. 8 is a schematic cross-sectional view of a light emitting element ED, in which the hole transport layer HTL includes hole transport layers HTL1 and HTL2, and the electron transport layer ETL includes electron transport layers ETL1 and ETL2. In comparison to FIG. 4, FIG. 9 is a schematic cross-sectional view of a light emitting element ED, in which the hole transport layer HTL includes hole transport layers HTL1, HTL2, and HTL3, and the electron transport layer ETL includes electron transport layers ETL1, ETL2, and ETL3. In comparison to FIG. 3, FIG. 10 is a schematic cross-sectional view of a light emitting element ED, in which a capping layer CPL is disposed on the second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, and a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayered structure that includes a reflective film or a transflective film formed of the above-described materials, and a transparent conductive film formed of ITO, IZO, ZnO, ITZO, etc. For example, the first electrode EL1 may have a three-layered structure of ITO/Ag/ITO, but the embodiments are not limited thereto. In an embodiment, the first electrode EL1 may include the above-described metal materials, combinations of at least two of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

In the light emitting element ED according to embodiments as shown in FIGS. 3 to 10, the hole transport region HTR may be provided on the first electrode EL1. The hole transport region HTR may include at least one of a hole injection layer HIL, a hole transport layer HTL, a buffer layer (not shown), a light emitting auxiliary layer (not shown), and an electron blocking layer EBL.

The hole transport region HTR may have a structure including multiple layers including different materials. In an embodiment, the hole transport region HTR may have a structure in which a hole injection layer HIL/hole transport layer HTL/electron blocking layer EBL are stacked in the stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 250 Å to about 1,000 Å. When the hole transport region HTR includes an electron blocking layer EBL, the electron blocking layer EBL may have a thickness in a range of about 10 Å to about 1,000 Å. If the thicknesses of the hole transport region HTR, the hole injection layer HIL, the hole transport layer HTL, and the electron blocking layer EBL satisfy the above-described ranges, satisfactory hole transport properties may be achieved without a substantial increase in driving voltage.

An electron blocking layer EBL according to an embodiment will be described. The electron blocking layer EBL may prevent the injection of electrons from an electron transport region ETR to a hole transport region HTR. Among the layers of the hole transport region HTR, the electron blocking layer EBL may be disposed adjacent (for example, directly adjacent) to the emission layer EML.

The electron blocking layer EBL according to an embodiment may have a giant surface potential. For example, the electron blocking layer EBL may have a negative giant surface potential. In embodiments, the electron blocking layer EBL may include a compound having a negative giant surface potential.

In the specification, a giant surface potential may be a surface potential that is induced in an organic layer due to electric fields generated by dipoles when organic materials having dipoles are aligned in one direction. Hereinafter, the giant surface potential may be referred to as “GSP”.

In the specification, a negative giant surface potential indicates a surface potential at which a positive charge is induced toward the first electrode EL1, for example, in an anode direction. In the specification, a positive giant surface potential indicates a surface potential at which a negative charge is induced toward the first electrode EL1, for example, in an anode direction.

A negative giant surface potential and a positive giant surface potential may each be a potential gradient of the surface potential obtained by measuring the surface potential according to a thickness of an organic layer through a Kelvin probe. The negative giant surface potential may be a giant surface potential having a negative slope, and the positive giant surface potential may be a giant surface potential having a positive slope. Hereinafter, a negative giant surface potential may be referred to as a “negative GSP”, and a positive giant surface potential may be referred to as a “positive GSP”.

In embodiments, the electron blocking layer EBL may have a first negative GSP. The first negative GSP may be equal to or less than about −10 mV/nm. The electron blocking layer EBL may be an organic layer that includes a compound having the first negative GSP. For example, a compound having the first negative GSP may be Compound EBL1, but embodiments are not limited thereto.

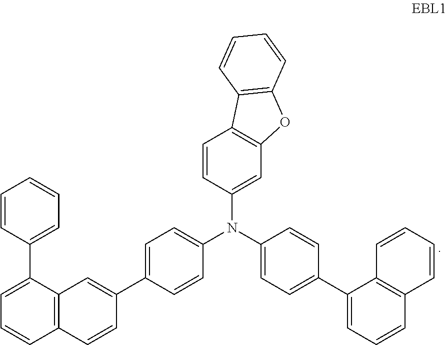 [SMILES: c1ccc(-c2cccc3ccc(-c4ccc(N(c5ccc(-c6cccc7ccccc67)cc5)c5ccc6c(c5)oc5ccccc56)cc4)cc23)cc1]

The light emitting element ED according to an embodiment includes the electron blocking layer EBL having a first negative GSP equal to or less than about −10 mV/nm, and thus may reduce changes in resistance and offset increased capacitance caused by an emission layer EML having a positive GSP.

The hole transport region HTR according to an embodiment may include a hole transport layer HTL. The hole transport layer HTL may be disposed between the electron blocking layer EBL and the hole injection layer HIL. The hole transport layer HTL may include at least one layer. The hole transport layer HTL may have a structure consisting of a layer consisting of a single material, a structure consisting of a layer including different materials, or a structure including multiple layers including different materials.

In embodiments, the hole transport layer HTL may have a single-layered structure consisting of one hole transport material or including multiple hole transport materials. For example, a single-layered hole transport layer HTL may consist of a first hole transport layer HTL1. In embodiments, the hole transport layer HTL may have a first hole transport layer HTL1/second hole transport layer HTL2 structure, or first hole transport layer HTL1/second hole transport layer HTL2/third hole transport layer HTL3 structure, in which the layers of each structure may be stacked from the hole injection layer HIL in its respective stated order. However, embodiments are not limited to thereto, and the hole transport layer HTL may have a multilayered structure including four or more layers.

The hole transport layer HTL may have a GSP. In an embodiment, when the hole transport layer HTL has a multilayered structure, a hole transport layer HTL adjacent to the emission layer EML among the layers included in the hole transport layer HTL may have a second negative GSP. However, embodiments are not limited thereto. For example, when the electron transport layer ETL, which will be described later, has a multilayered structure, and an electron transport layer ETL adjacent to the second electrode EL2 among the electron transport layers ETL has a first positive GSP, the hole transport layer HTL that is adjacent to the emission layer EML may not have the second negative GSP.

In an embodiment, multiple hole transport layers HTL may be stacked between the first electrode EL1 and the emission layer EML. Among the stack of hole transport layers HTL, at least one hole transport layer HTL disposed adjacent to the emission layer EML may have the second negative GSP. The second negative GSP may be equal to or less than about −10 mV/nm. In an embodiment, an absolute value of the second negative GSP may not be equal to or greater than an absolute value of the first negative GSP (|second negative GSP|<|first negative GSP|). Thus, the absolute value of the second negative GSP may be less than the absolute value of the first negative GSP described above.

Referring to FIGS. 6 and 8, the hole transport layer HTL may include the first hole transport layer HTL1 and the second hole transport layer HTL2 disposed between the first electrode EL1 and the emission layer EML. The first hole transport layer HTL1 and the second hole transport layer HTL2 may be sequentially disposed on the first electrode EL1. The first hole transport layer HTL1 may be adjacent to the first electrode EL1, and the second hole transport layer HTL2 may be disposed on the first hole transport layer HTL1 and closer to the emission layer EML than the first hole transport layer HTL1. Among the first hole transport layer HTL1 and the second hole transport layer HTL2, the second hole transport layer HTL2 may have the second negative GSP. For example, among the first hole transport layer HTL1 and the second hole transport layer HTL2, the second hole transport layer HTL2 that is adjacent to the emission layer EML may have the second negative GSP. The second hole transport layer HTL2 may be an organic layer that includes a compound having the second negative GSP.

In the light emitting element ED shown in FIGS. 6 and 8, the first hole transport layer HTL1 may be spaced farther away from the emission layer EML and positioned closer to the first electrode EL1 than the second hole transport layer HTL2. The first hole transport layer HTL1 may not have the second negative GSP. The first hole transport layer HTL1 may have a second positive GSP or a third negative GSP. The first hole transport layer HTL1 may be an organic layer that includes a compound having the second positive GSP or a compound having the third negative GSP. The third negative GSP may be different from the first negative GSP and the second negative GSP.

In embodiments, the second positive GSP may have an absolute value equal to or less than about 10 mV/nm (|second positive GSP|≤10 mV/nm), and the third negative GSP may have an absolute value equal to or less than about 10 mV/nm (|third negative GSP|≤10 mV/nm). The second positive GSP and the third negative GSP that are applicable to the first hole transport layer HTL1 may each independently have an absolute value equal to or less than about 10 mV/nm, but embodiments are not limited thereto.

In an embodiment, an absolute value of the second positive GSP and an absolute value of the third negative GSP may each not be equal to or greater than the absolute value of the second negative GSP (|second positive GSP or third negative GSP|<|second negative GSP|). Thus, when the first hole transport layer HTL1 has the second positive GSP or the third negative GSP, the second positive GSP and the third negative GSP may each have an absolute value that is less than an absolute value of the second negative GSP. For example, when the first hole transport layer HTL1 has the second positive GSP, the absolute value of the second positive GSP may be less than the absolute value of the second negative GSP of the second hole transport layer HTL2. For example, when the first hole transport layer HTL1 has the third negative GSP, the absolute value of the third negative GSP may be less than the absolute value of the second negative GSP of the second hole transport layer HTL2.

In embodiments, when the hole transport layer HTL includes multiple hole transport layers, a hole transport layer HTL adjacent to the emission layer EML among the hole transport layers HTL may not have the second negative GSP. For example, in the light emitting element ED shown in FIG. 8, the second hole transport layer HTL2 may not have the second negative GSP. In the light emitting element ED shown in FIG. 8, the electron transport layer ETL may have a multilayered structure, and the second electron transport layer ETL2 adjacent to the second electrode EL2 among the electron transport layers ETL1 and ETL2 may have the first positive GSP.

Referring to FIG. 7, the hole transport layer HTL may have a single-layered structure. The single-layered hole transport layer HTL may be similar to the first hole transport layer HTL1 as described above with reference to FIGS. 6 and 8.

The hole transport layer HTL having a single-layered structure may have the second positive GSP or the third negative GSP. The hole transport layer HTL having a single-layered structure may be an organic layer that includes a compound having the second positive GSP or a compound having the third negative GSP. For example, an absolute value of the second positive GSP may be equal to or less than about 10 mV/nm (|second positive GSP|≤10 mV/nm), and an absolute value of the third negative GSP may be equal to or less than about 10 mV/nm (|third negative GSP|≤10 mV/nm). The second positive GSP and the third negative GSP that are applicable to the hole transport layer HTL having a single-layered structure may each independently have an absolute value equal to or less than about 10 mV/nm, but embodiments are not limited thereto.

When the hole transport layer HTL included in the light emitting element ED has a single-layered structure and the single-layered hole transport layer HTL has the second positive GSP or the third negative GSP, the electron transport layer ETL, which will be described later, may have a multilayered structure. In an embodiment, when the electron transport layer ETL has a multilayered structure, an electron transport layer ETL adjacent to the second electrode EL2 may have the first positive GSP.

Referring to FIG. 9, the hole transport layer HTL may have a multilayered structure that includes three layers. The hole transport layer HTL may include a first hole transport layer HTL1, a second hole transport layer HTL2, and a third hole transport layer HTL3 disposed between the first electrode EL1 and the emission layer EML. The first hole transport layer HTL1, the second hole transport layer HTL2, and the third hole transport layer HTL3 may be sequentially disposed on the first electrode EL1. Accordingly, the second hole transport layer HTL2 may be positioned closer to the emission layer EML than the first hole transport layer HTL1, and the third hole transport layer HTL3 may be positioned closer to the emission layer EML than the second hole transport layer HTL2. The first hole transport layer HTL1 is spaced farther away from the emission layer EML than the second and third hole transport layers HTL2 and HTL3 and may be adjacent to the first electrode EL1.

As described above, in the hole transport layer HTL having a multilayered structure, a hole transport layer HTL adjacent to the emission layer EML may have the second negative GSP. In the light emitting element ED shown in FIG. 9, at least one of the second hole transport layer HTL2 and the third hole transport layer HTL3, which are adjacent to the emission layer EML among the first to third hole transport layers HTL1, HTL2, and HTL3, may each independently have the second negative GSP. For example, among the first to third hole transport layers HTL1, HTL2, and HTL3, the second hole transport layer HTL2 may have the second negative GSP, and the first hole transport layer HTL1 and the third hole transport layer HTL3 may not have the second negative GSP. As another example, among the first to third hole transport layers HTL1, HTL2, and HTL3, the third hole transport layer HTL3 may have the second negative GSP, and the first hole transport layer HTL1 and the second hole transport layer HTL2 may not have the second negative GSP. The second hole transport layer HTL2 or the third hole transport layer HTL3 may be an organic layer that includes a compound having the second negative GSP.

In the light emitting element ED shown in FIG. 9, among the first to third hole transport layers HTL1, HTL2, and HTL3, the first hole transport layer HTL1 may be spaced away from the emission layer EML and positioned adjacent to the first electrode EL1. The first hole transport layer HTL1 may not have the second negative GSP. In an embodiment, the first hole transport layer HTL1 may have a third positive GSP or a fourth negative GSP. In an embodiment, among the second hole transport layer HTL2 and the third hole transport layer HTL3, the layer that does not have the second negative GSP may have the third positive GSP or the fourth negative GSP.

For example, the second hole transport layer HTL2 may have the second negative GSP. Thus, the first hole transport layer HTL1 and the third hole transport layer HTL3 may not have the second negative GSP. In an embodiment, the first hole transport layer HTL1 and the third hole transport layer HTL3 may each independently have the third positive GSP or the fourth negative GSP. The first hole transport layer HTL1 and the third hole transport layer HTL3 may each be an organic layer that includes a compound having the third positive GSP or a compound having the fourth negative GSP. The GSP of the first hole transport layer HTL1 and the GSP of the third hole transport layer HTL3 may be the same as or different from each other.

For example, the third hole transport layer HTL3 may have the second negative GSP, and the first hole transport layer HTL1 and the second hole transport layer HTL2 may not have the second negative GSP. The first hole transport layer HTL1 and the second hole transport layer HTL2 that do not have the second negative GSP may each independently have the third positive GSP or the fourth negative GSP. The first hole transport layer HTL1 and the second hole transport layer HTL2 may each be an organic layer that includes a compound having the third positive GSP or a compound having the fourth negative GSP. The GSP of the first hole transport layer HTL1 and the GSP of the second hole transport layer HTL2 may be the same as or different from each other.

In an embodiment, an absolute value of the third positive GSP may be equal to or less than about 10 mV/nm (|third positive GSP|≤10 mV/nm), and an absolute value of the fourth negative GSP may be equal to or less than about 10 mV/nm (|fourth negative GSP|≤10 mV/nm). An absolute value of the third positive GSP and an absolute value of the fourth negative GSP may each independently be equal to or less than about 10 mV/nm, but embodiments are not limited thereto.

In an embodiment, the absolute value of the third positive GSP may not be equal to or greater than the absolute value of the second negative GSP (|third positive GSP|<|second negative GSP|), and the absolute value of the fourth negative GSP may not be equal to or greater than the absolute value of the second negative GSP (|fourth negative GSP|<|second negative GSP|). Thus, an absolute value of the third positive GSP and an absolute value of the fourth negative GSP of the first hole transport layer HTL1 may each be less than the absolute value of the second negative GSP. In embodiments, an absolute value of the third positive GSP and an absolute value of the fourth negative GSP of the second hole transport layer HTL2 or the third hole transport layer HTL3 may each be less than the absolute value of the second negative GSP.

For example, when the first hole transport layer HTL1 has the third positive GSP, an absolute value of the third positive GSP may be less than the absolute value of the second negative GSP of the second hole transport layer HTL2 or the third hole transport layer HTL3. For example, when the first hole transport layer HTL1 has the fourth negative GSP, an absolute value of the fourth negative GSP may be less than the absolute value of the second negative GSP of the second hole transport layer HTL2 or the third hole transport layer HTL3.

In embodiments, when the second hole transport layer HTL2 has the third positive GSP and the third hole transport layer HTL3 has the second negative GSP, an absolute value of the third positive GSP may be less than an absolute value of the second negative GSP. In embodiments, when the second hole transport layer HTL2 has the fourth negative GSP and the third hole transport layer HTL3 has the second negative GSP, an absolute value of the fourth negative GSP may be less than an absolute value of the second negative GSP. When the third hole transport layer HTL3 has the third positive GSP and the second hole transport layer HTL2 has the second negative GSP, an absolute value of the third positive GSP may be less than an absolute value of the second negative GSP of the second hole transport layer HTL2. When the third hole transport layer HTL3 has the fourth negative GSP and the second hole transport layer HTL2 has the second negative GSP, an absolute value of the fourth negative GSP may be less than an absolute value of the second negative GSP of the second hole transport layer HTL2.

In embodiments, among the first to third hole transport layers HTL1, HTL2, and HTL3, at least one of the second hole transport layer HTL2 and the third hole transport layer HTL3 adjacent to the emission layer EML may not have the second negative GSP. For example, in the light emitting element ED shown in FIG. 9, the second hole transport layer HTL2 and/or the third hole transport layer HTL3 may not have the second negative GSP. Thus, as shown in FIG. 9, the electron transport layer ETL may have a multilayered structure, and the electron transport layer ETL that is adjacent to the second electrode EL2 may have the first positive GSP.

In the light emitting element ED according to an embodiment, the hole transport region HTR may include a compound represented by Formula H-1:

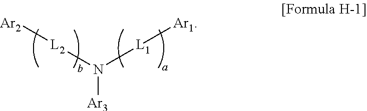

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ or multiple L₂ may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and a compound represented by Formula H-1 is not limited to Compound Group H:

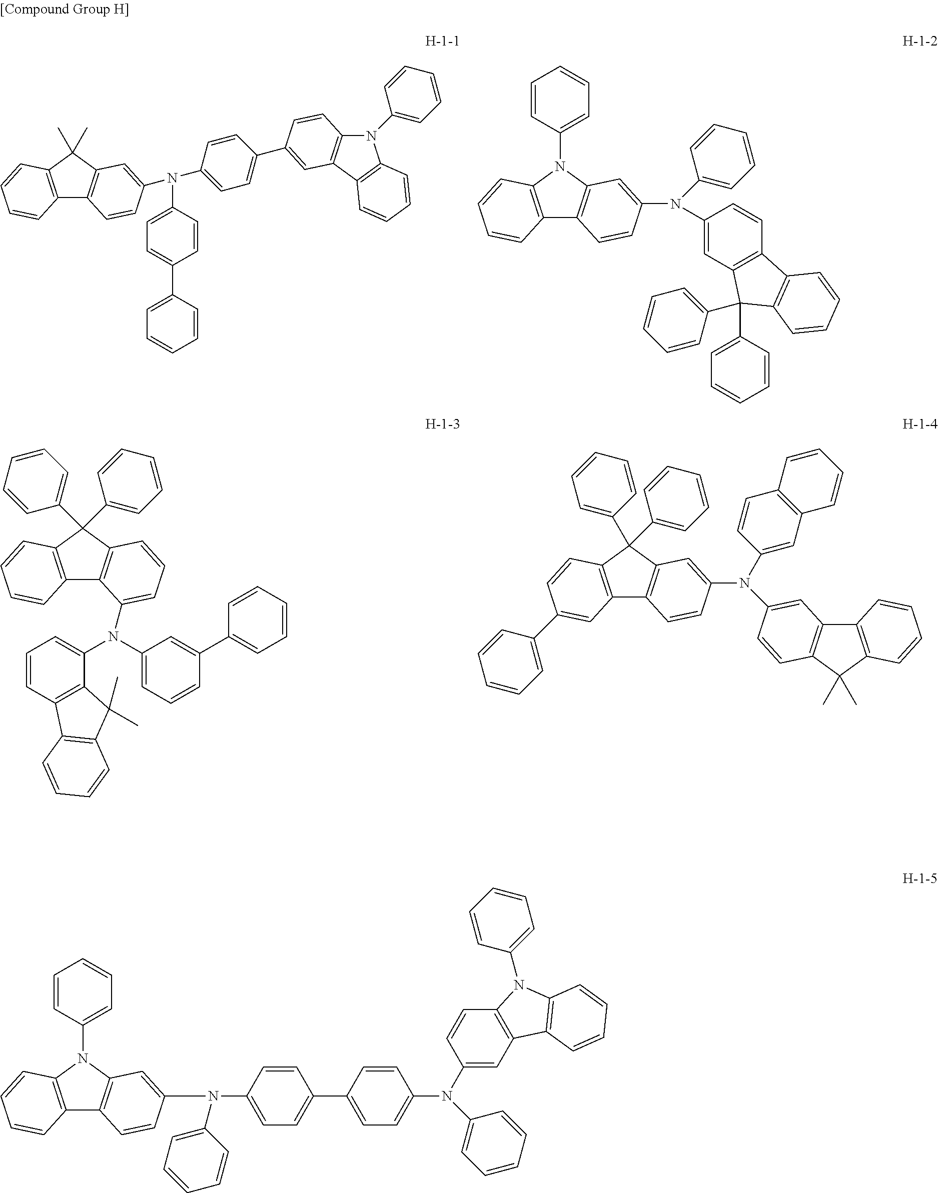 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

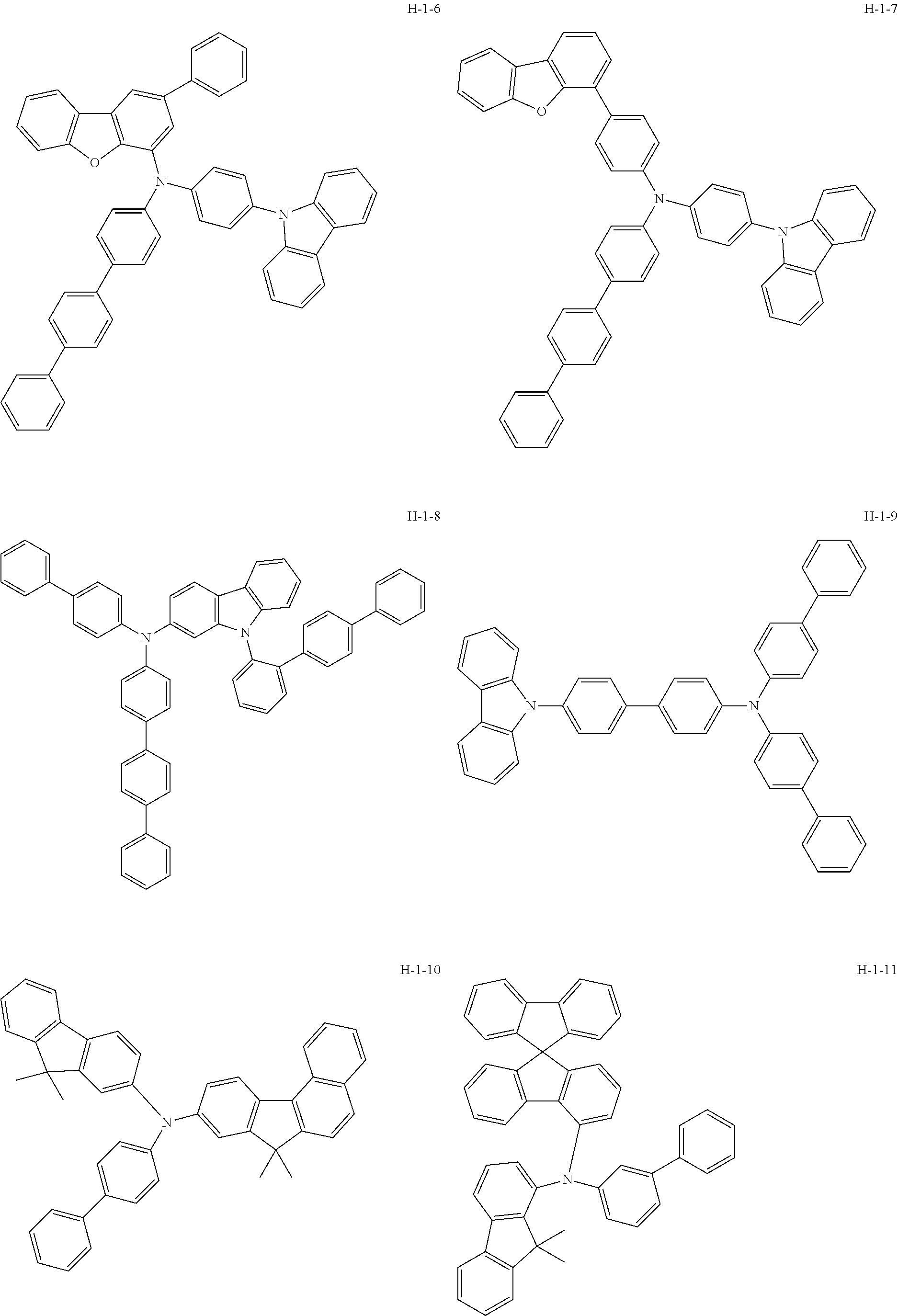

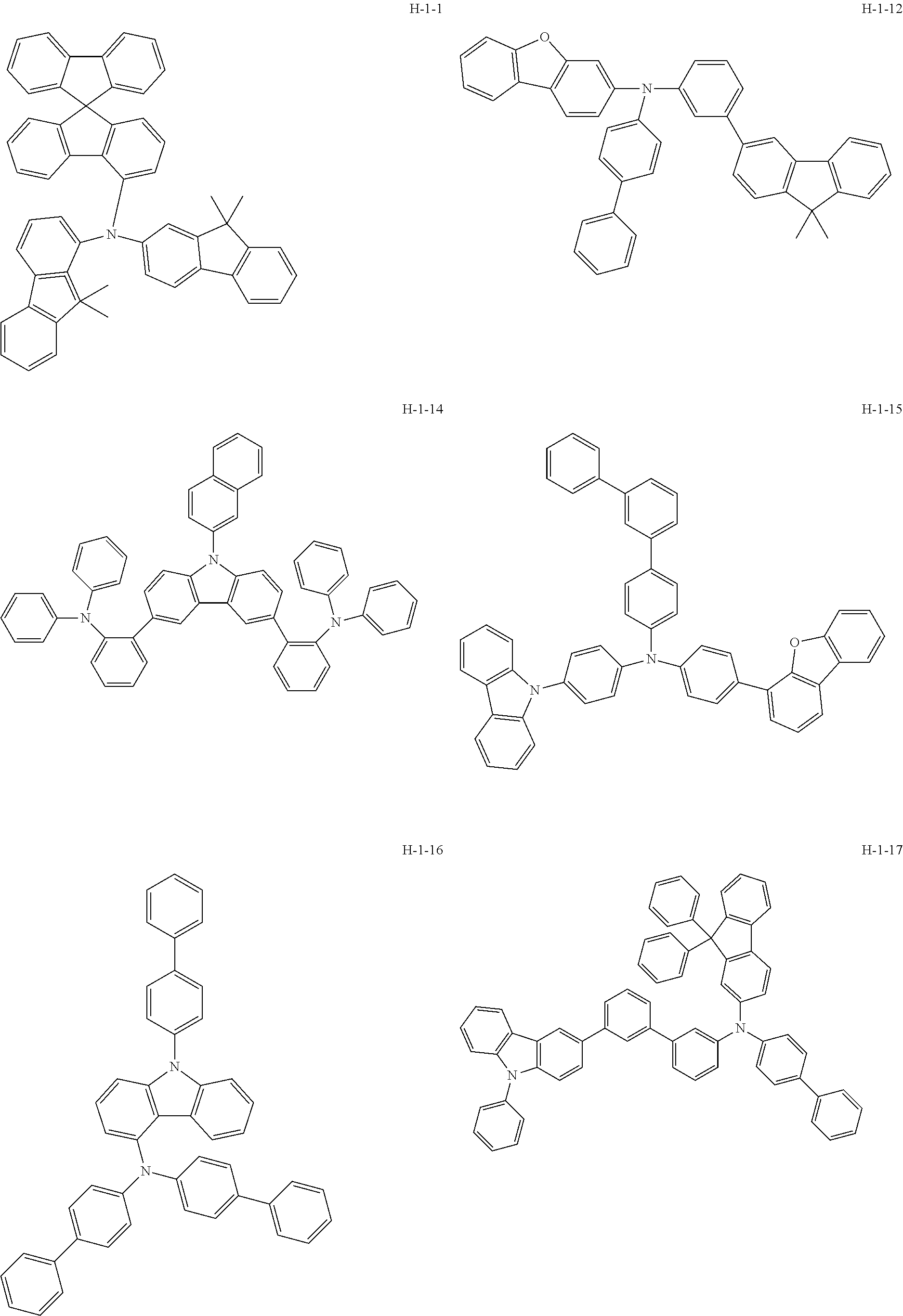

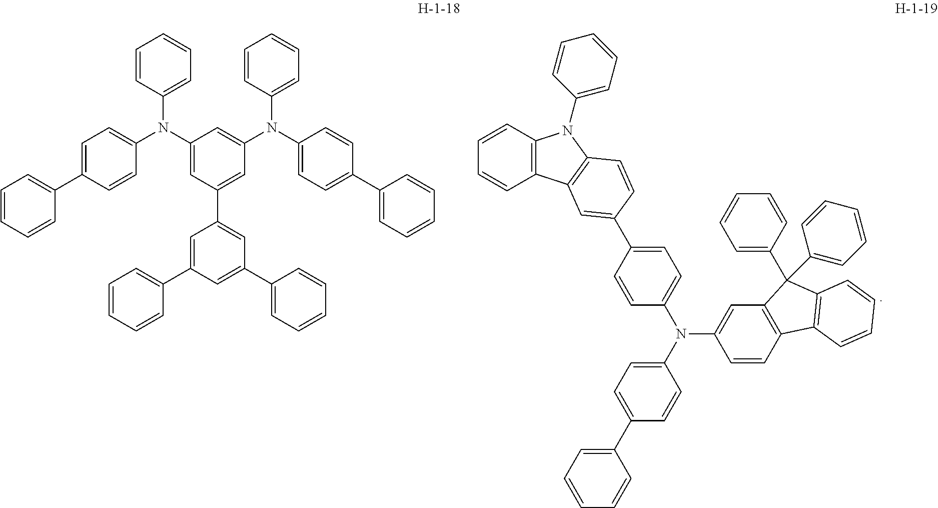 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium[tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In an embodiment, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a hole transport layer HTL, and an electron blocking layer EBL.

The hole transport region HTR may further include a charge generating material to increase conductivity, in addition to the above-described materials. The charge generating material may be dispersed uniformly or non-uniformly in the hole transport region HTR. The charge generating material may be, for example, a p-dopant. The p-dopant may include at least one of a metal halide, a quinone derivative, a metal oxide, and a cyano group-containing compound, but embodiments are not limited thereto. For example, the p-dopant may include a metal halide compound such as CuI or RbI, a quinone derivative such as tetracyanoquinodimethane (TCNQ) or 2,3,5,6-tetrafluoro-7,7′8,8-tetracyanoquinodimethane (F4-TCNQ), a metal oxide such as tungsten oxide or molybdenum oxide, a cyano group-containing compound such as dipyrazino[2,3-f: 2′,3′-h]quinoxaline-2,3,6,7,10,11-hexacarbonitrile (HATCN) or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments are not limited thereto.

As described above, the hole transport region HTR may further include a buffer layer (not shown), in addition to the hole injection layer HIL, the hole transport layer HTL, and the electron blocking layer EBL. The buffer layer (not shown) may compensate for a resonance distance according to a wavelength of light emitted from the emission layer EML and may thus increase light emission efficiency. A material that may be included in the hole transport region HTR may be used as a material in the buffer layer (not shown).

The emission layer EML may be provided on the hole transport region HTR. The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

In an embodiment, the emission layer EML may have a positive GSP. This may prevent an increase in element driving voltage. For example, the emission layer EML may have a fourth positive GSP. The fourth positive GSP may be equal to or greater than about 10 mV/nm. The emission layer EML may be an organic layer that includes a compound having the fourth positive GSP.

In the light emitting element ED, the emission layer EML may emit blue light. For example, the emission layer EML of the light emitting element ED may emit blue light in a wavelength range equal to or less than about 490 nm. However, embodiments are not limited thereto, and the emission layer EML may emit green light or red light.

In the light emitting element ED, the emission layer EML may include an anthracene derivative, a pyrene derivative, a fluoranthene derivative, a chrysene derivative, a dihydrobenzanthracene derivative, or a triphenylene derivative. For example, the emission layer EML may include an anthracene derivative or a pyrene derivative.

In the light emitting element ED according to embodiments as shown in FIGS. 3 to 10, the emission layer EML may further include a host of the related art and a dopant of the related art, in addition to the above-described host and dopant. In an embodiment, the emission layer EML may include a compound represented by Formula E-1. The compound represented by Formula E-1 may be used as a fluorescent host material.

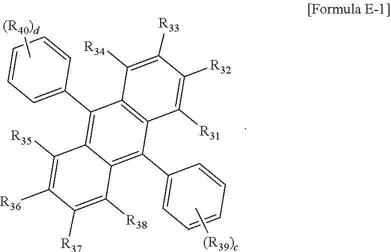

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

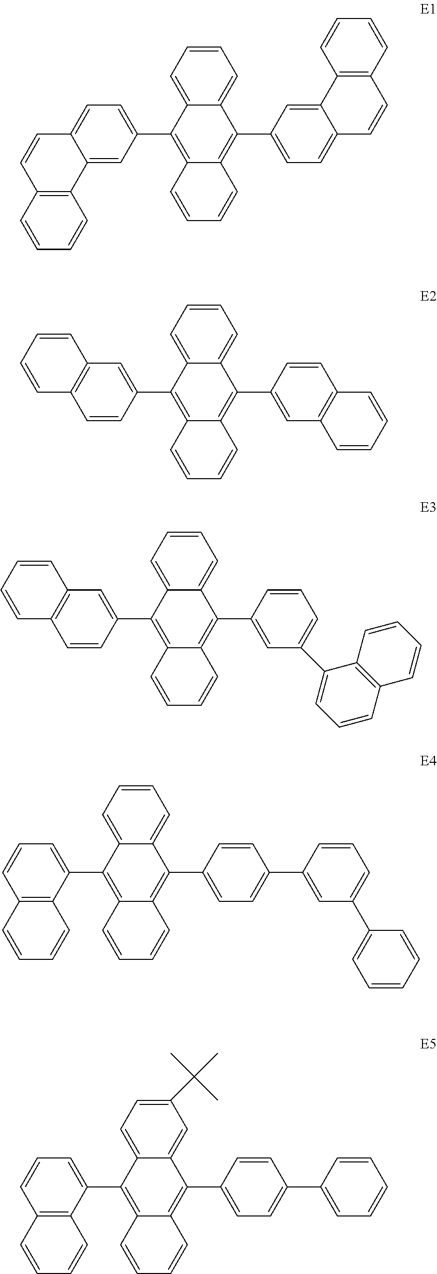

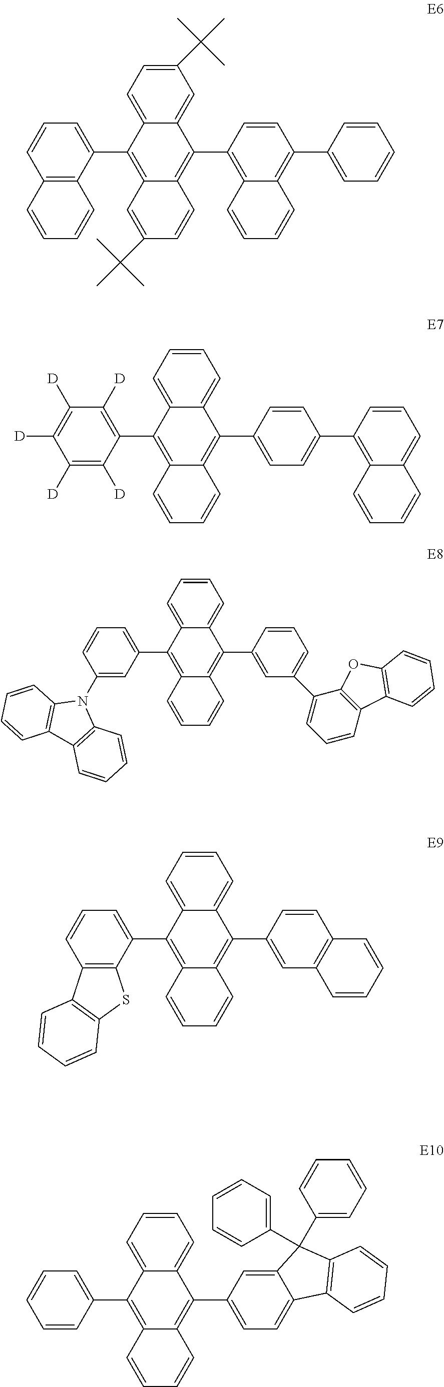

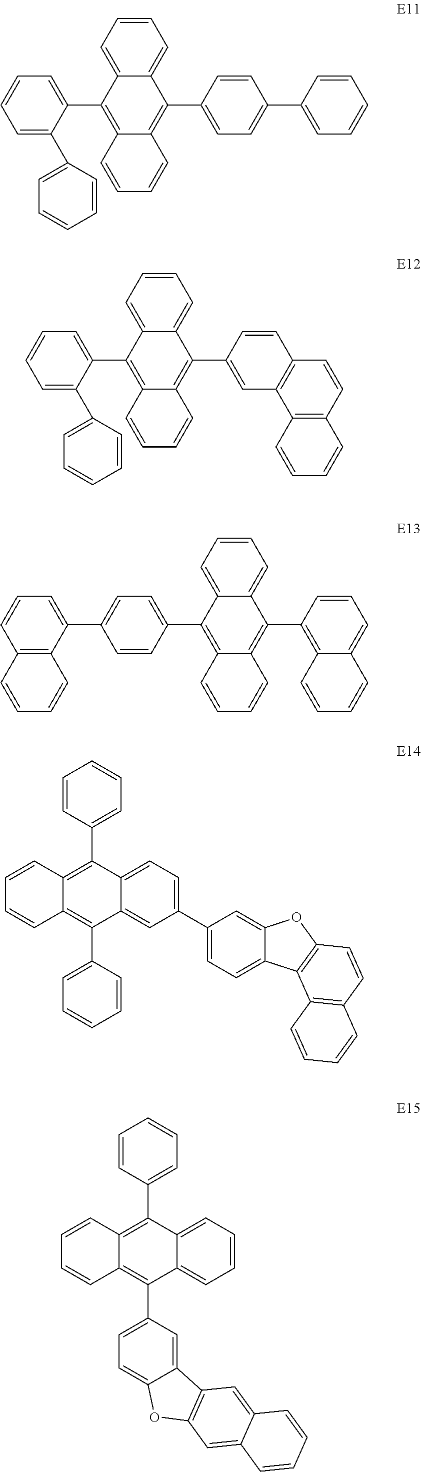

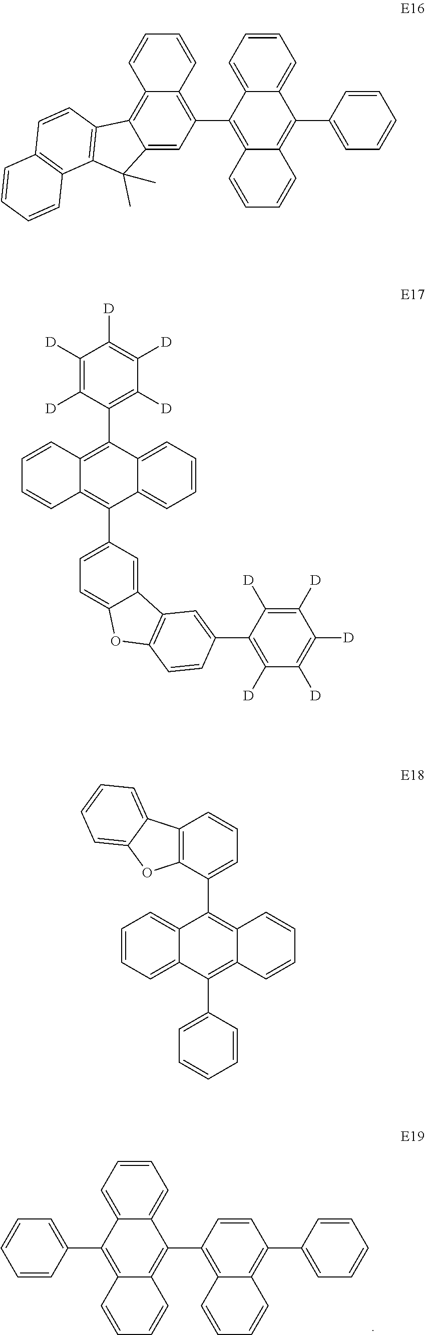

In an embodiment, the emission layer EML may include a hole transporting host compound represented by Formula HT-1:

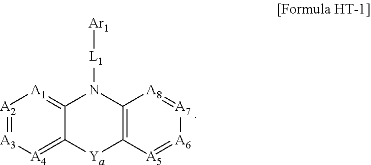

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

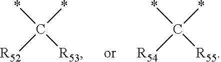

In Formula HT-1, when Yₐ is a direct linkage, the compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the hole transporting host represented by Formula HT-1 may be selected from Compound Group HT. In an embodiment, in the light emitting element ED, the hole transporting host may include at least one compound selected from Compound Group HT.

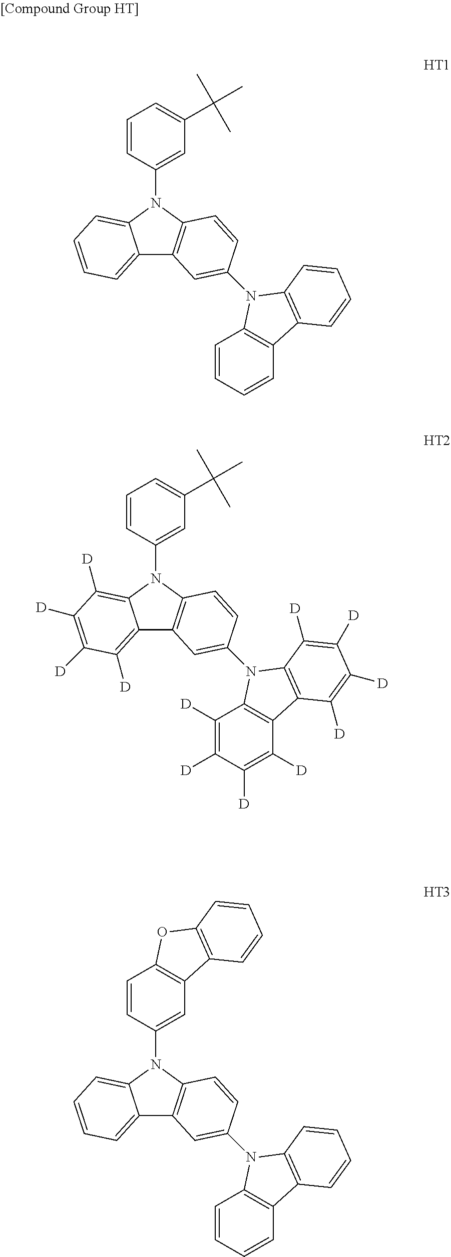 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

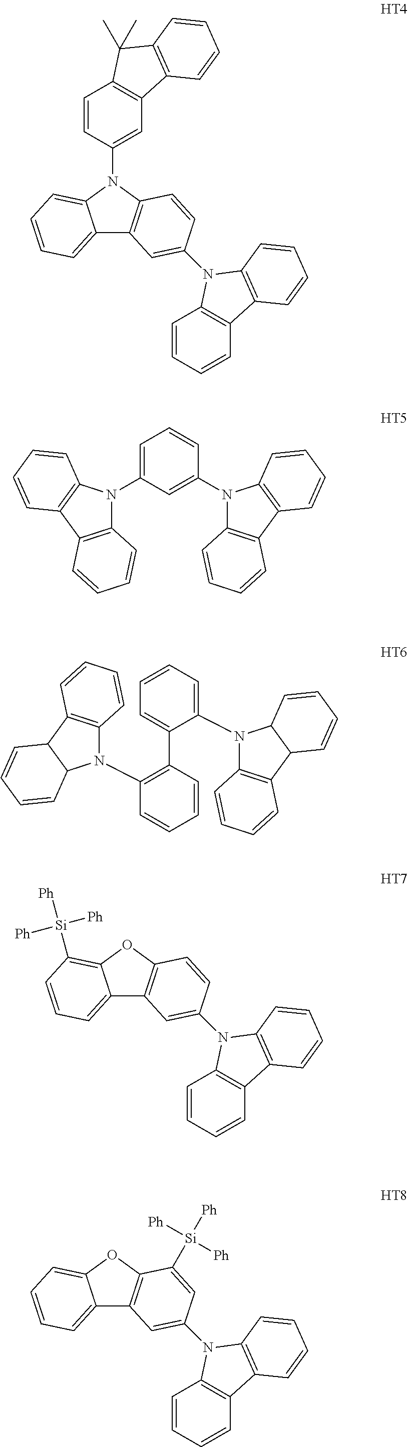 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; C1=CC2c3ccccc3N(c3ccccc3-c3ccccc3N3c4ccccc4C4C=CC=CC43)C2C=C1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

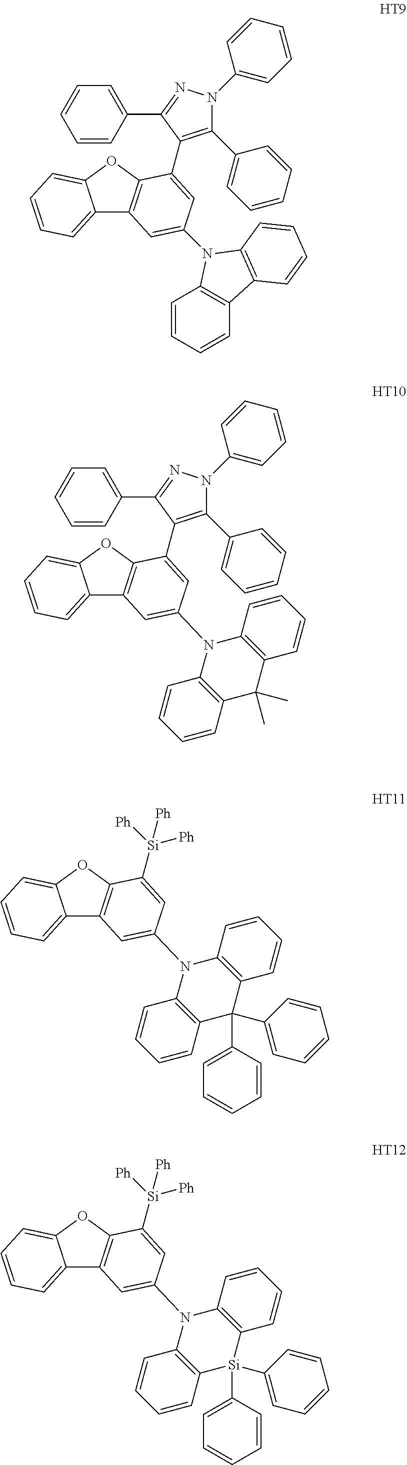 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

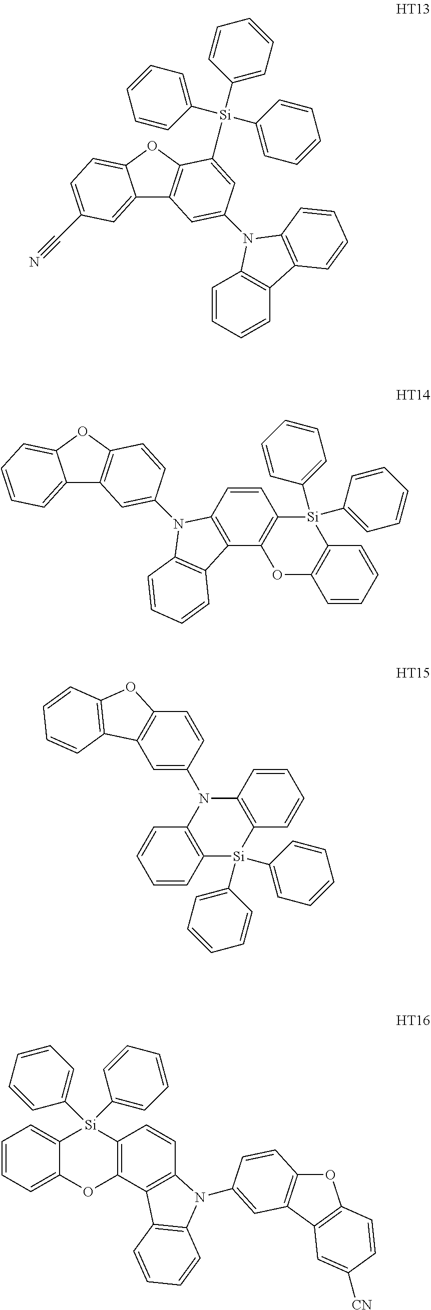 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

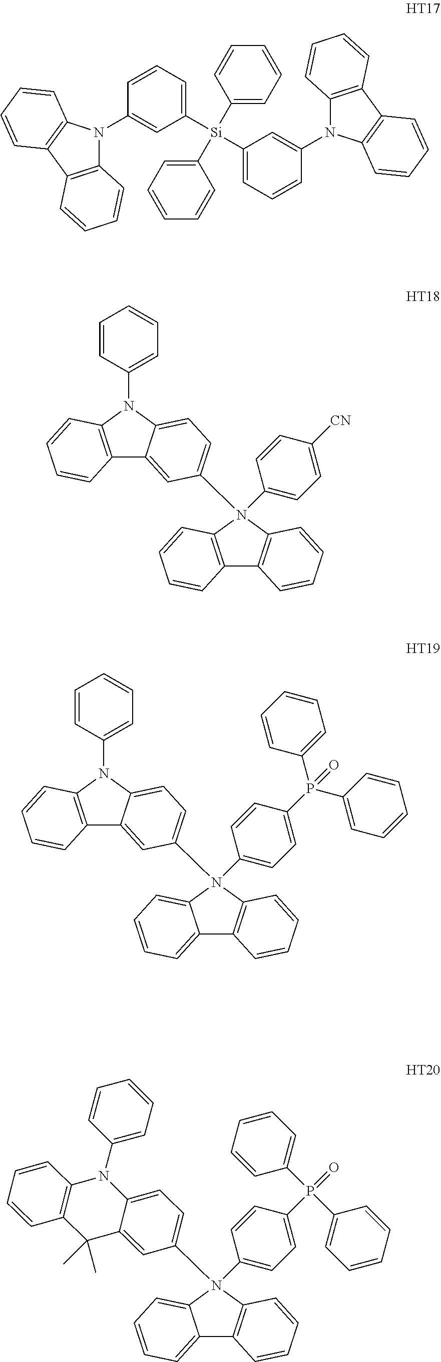

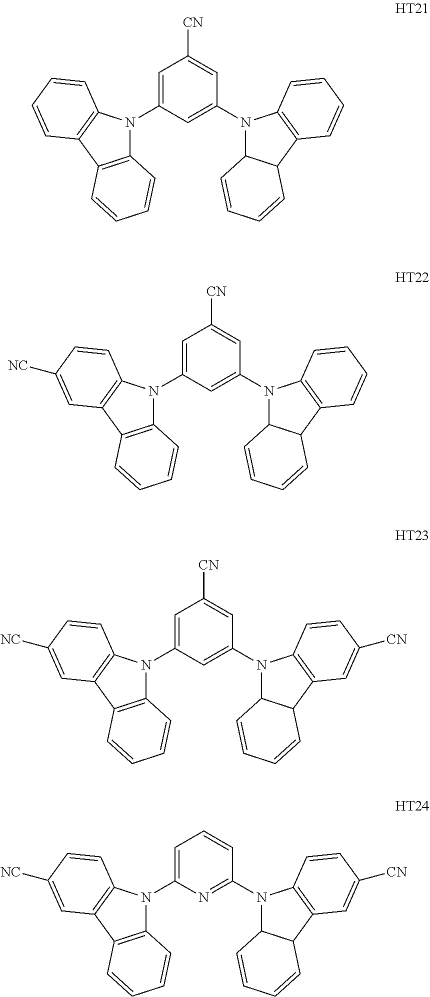 [SMILES: N#Cc1cc(N2c3ccccc3C3C=CC=CC32)cc(-n2c3ccccc3c3ccccc32)c1 ; N#Cc1cc(N2c3ccccc3C3C=CC=CC32)cc(-n2c3ccccc3c3cc(C#N)ccc32)c1 ; N#Cc1cc(N2c3ccc(C#N)cc3C3C=CC=CC32)cc(-n2c3ccccc3c3cc(C#N)ccc32)c1 ; N#Cc1ccc2c(c1)C1C=CC=CC1N2c1cccc(-n2c3ccccc3c3cc(C#N)ccc32)n1]

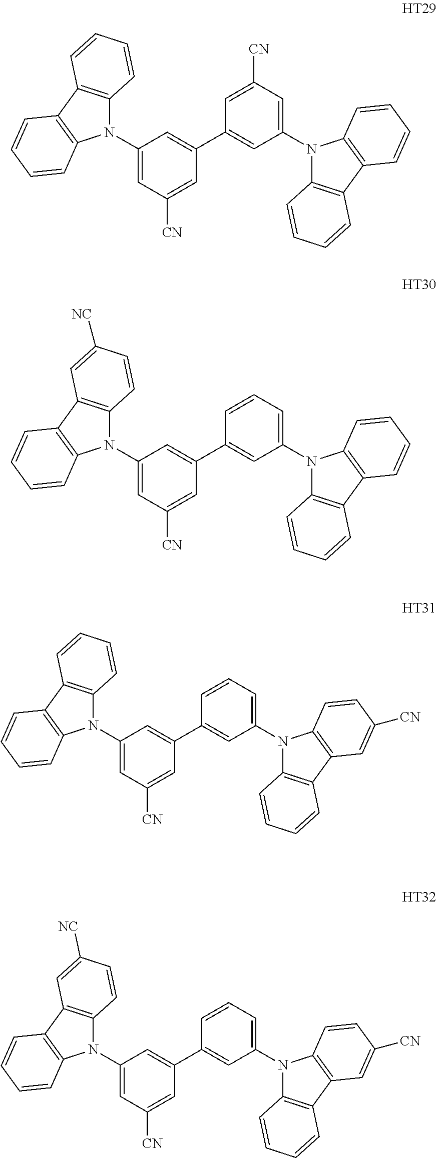 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

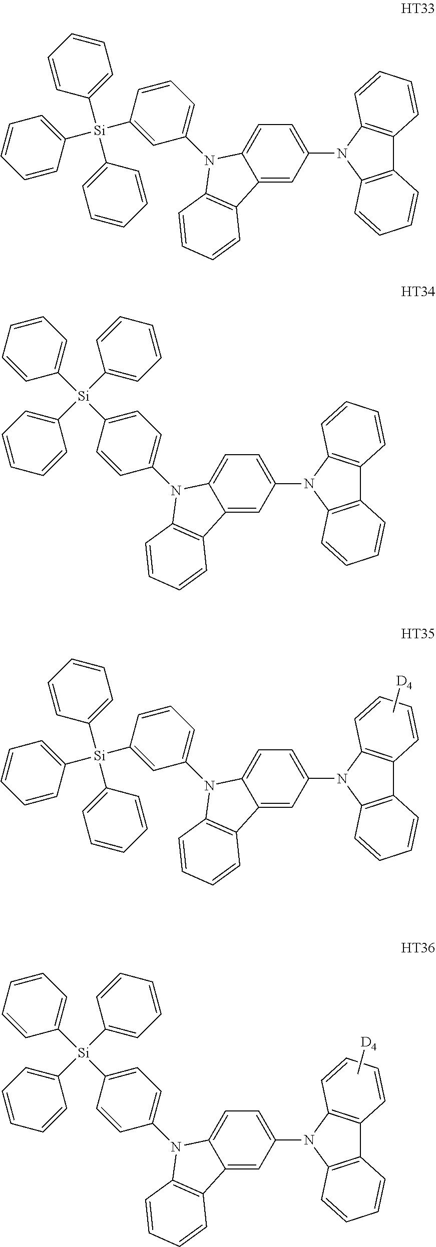

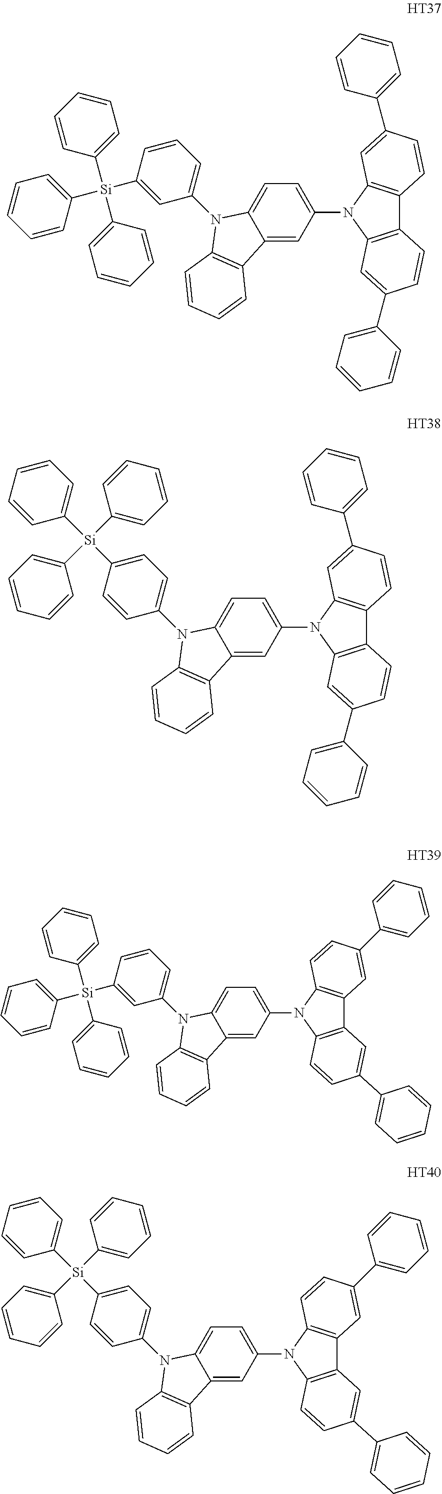 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

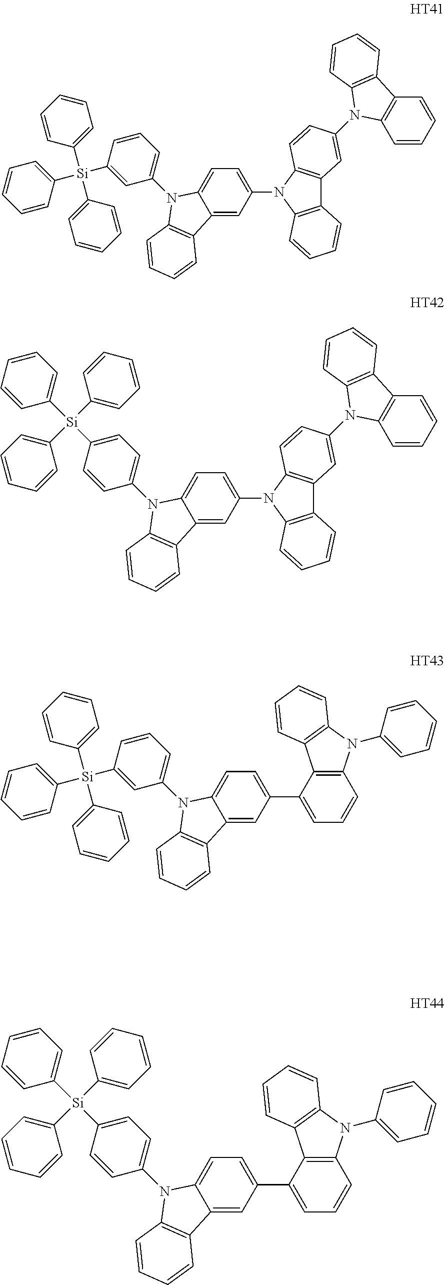 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

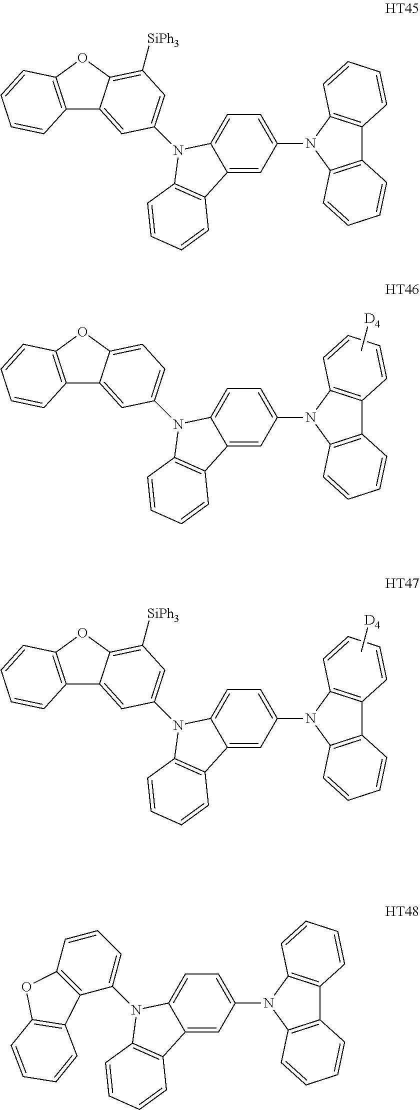

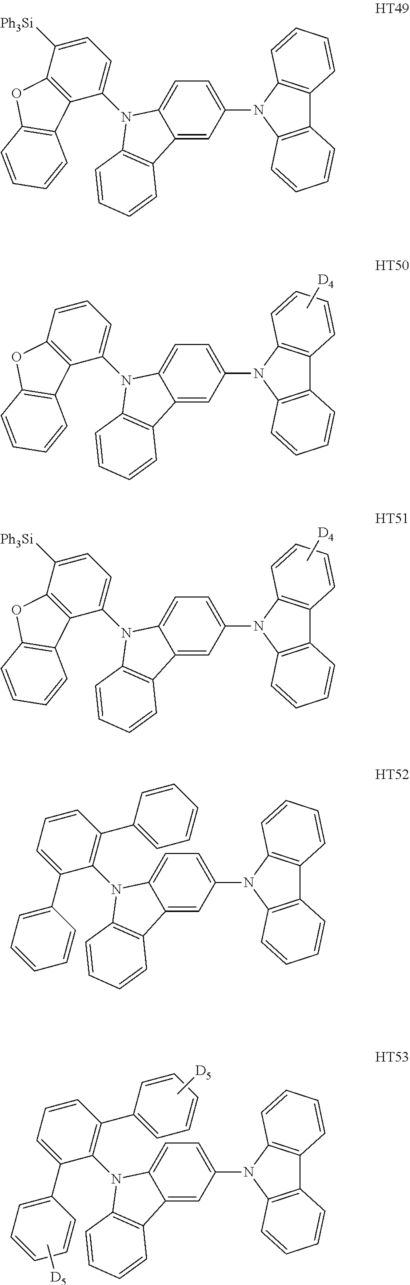

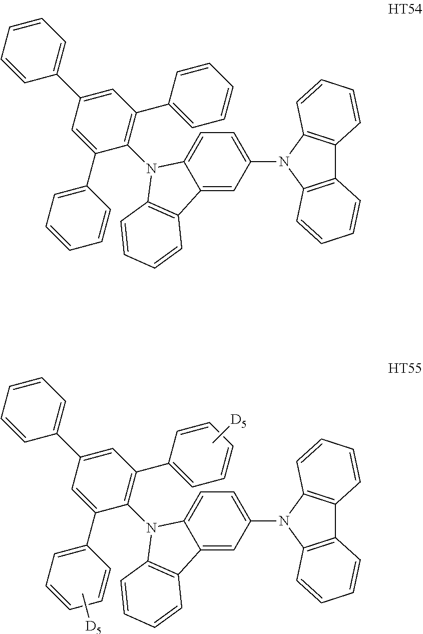

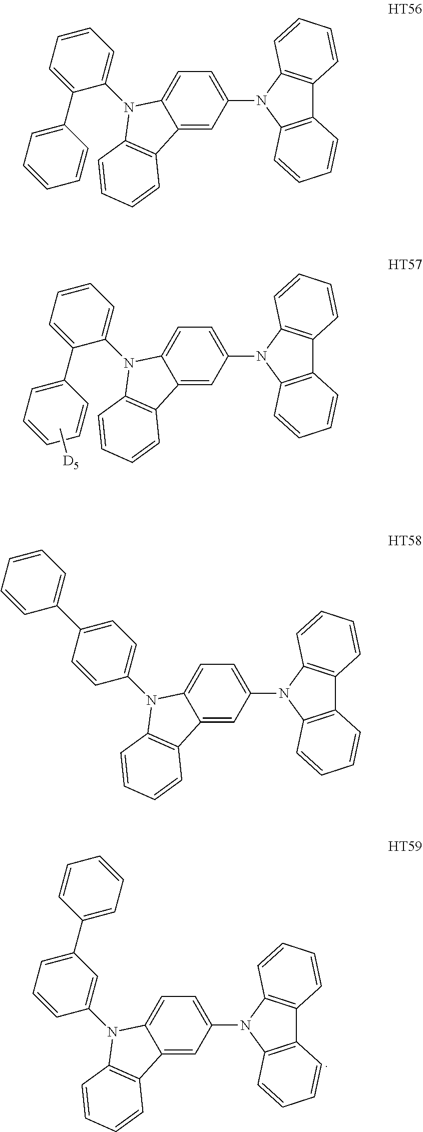

In Compound Group HT, D represents a deuterium atom, and Ph represents a substituted or unsubstituted phenyl group. For example, in Compound Group HT, Ph may represent an unsubstituted phenyl group.

In an embodiment, the emission layer EML may include an electron transporting host compound represented by Formula ET-1:

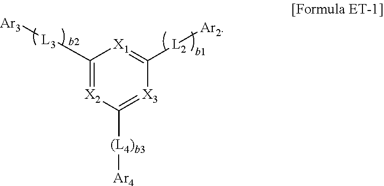

In Formula ET-1, at least one of X₁ to X₃ may each be N, and the remainder of X₁ to X₃ may independently be C(R₅₆). For example, one of X₁ to X₃ may be N, and the remainder of X₁ to X₃ may each independently be C(R₅₆). Thus, the compound represented by Formula ET-1 may include a pyridine moiety. As another example, two of X₁ to X₃ may each be N, and the remainder of X₁ to X₃ may be C(R₅₆). Thus, the compound represented by Formula ET-1 may include a pyrimidine moiety. As yet another example, X₁ to X₃ may each be N. Thus, the compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the electron transporting host represented by Formula ET-1 may be selected from Compound Group ET. In an embodiment, in the light emitting element ED, the electron transporting host may include at least one compound selected from Compound Group ET.

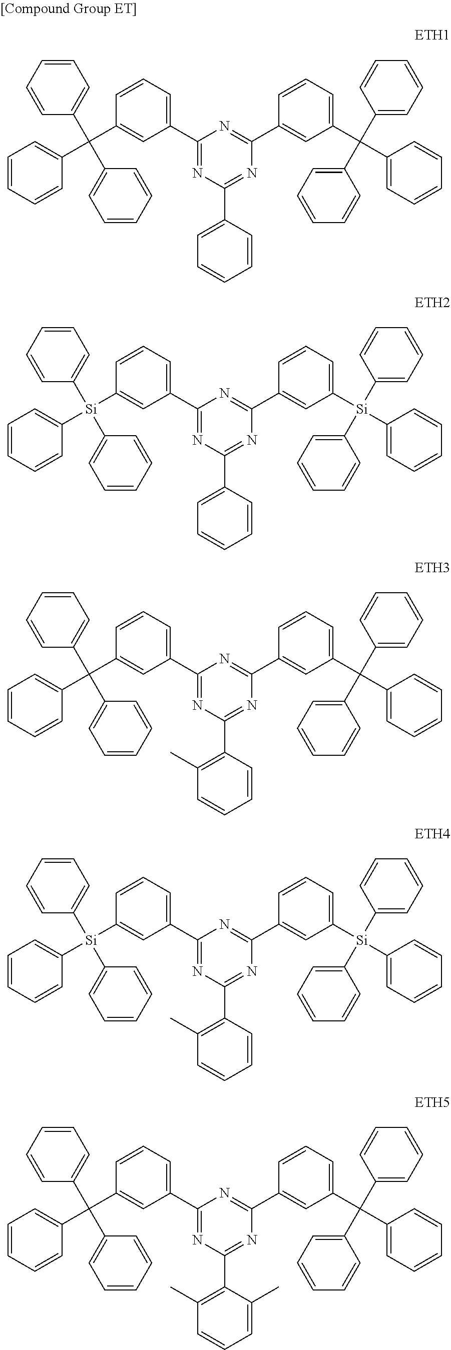

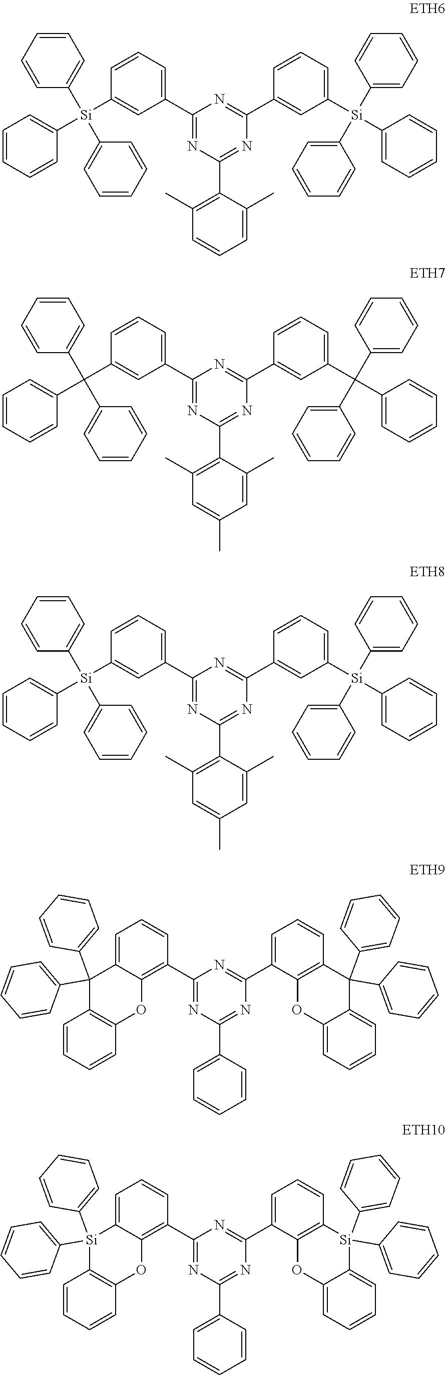

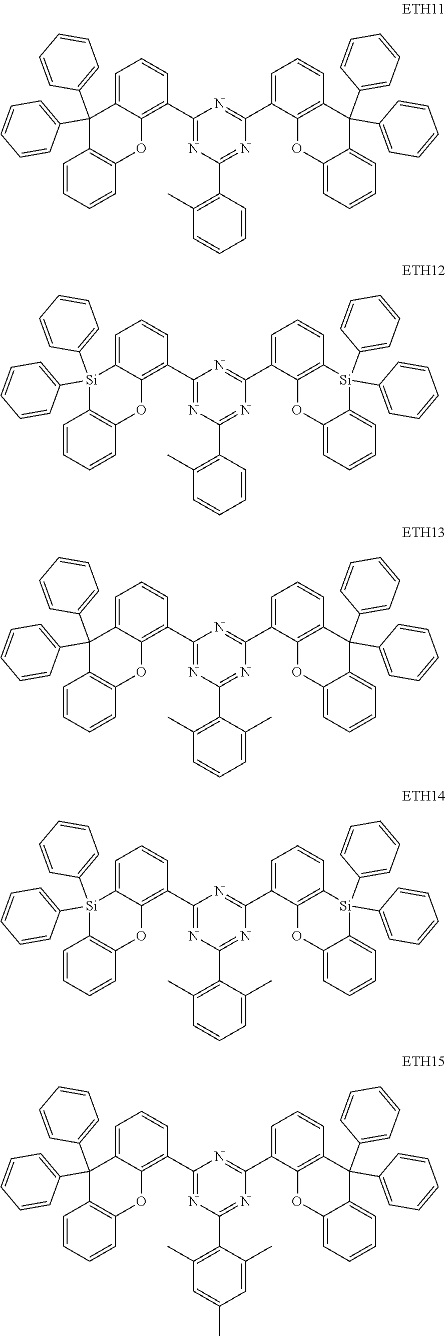

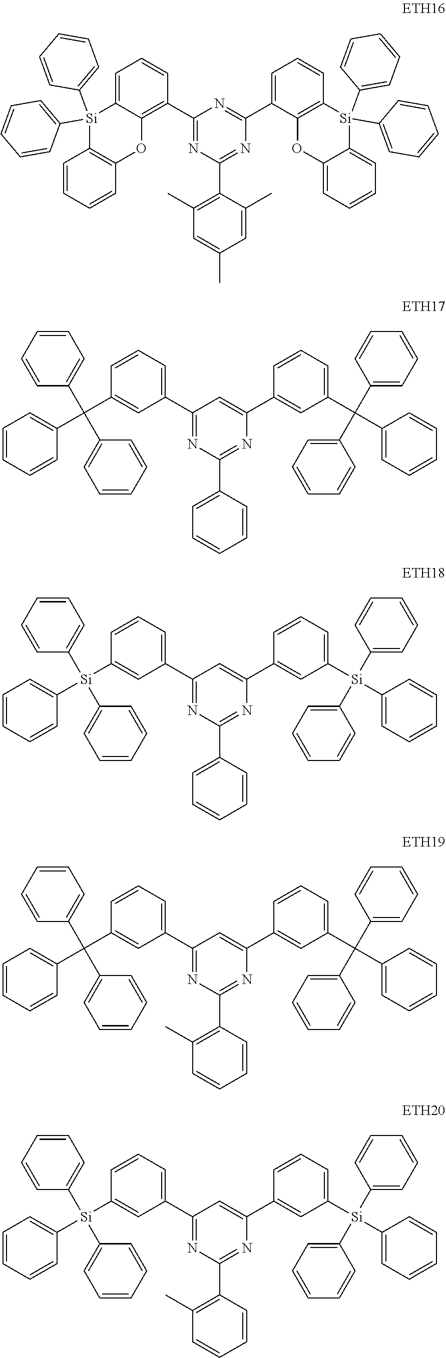

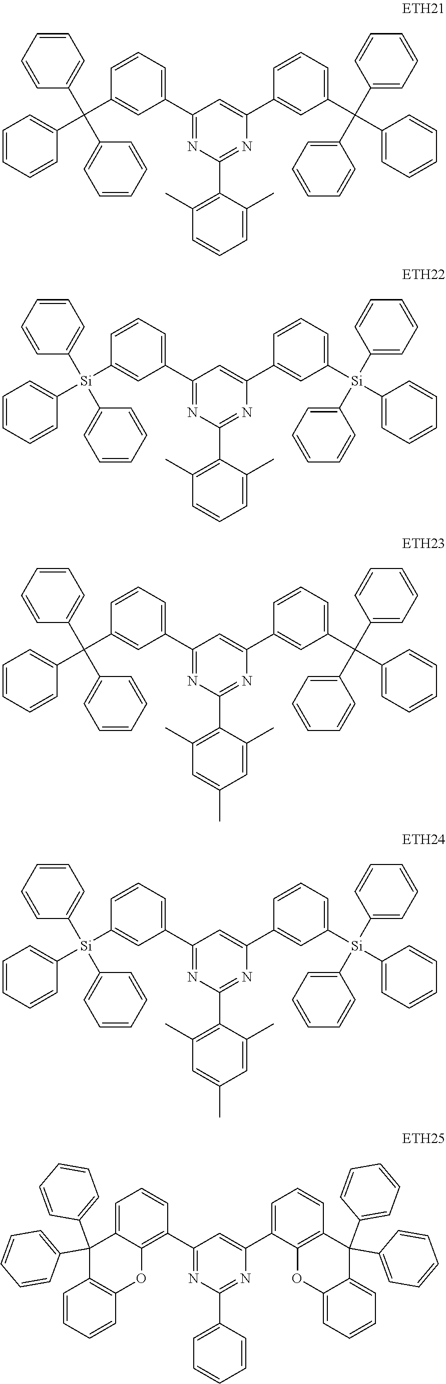

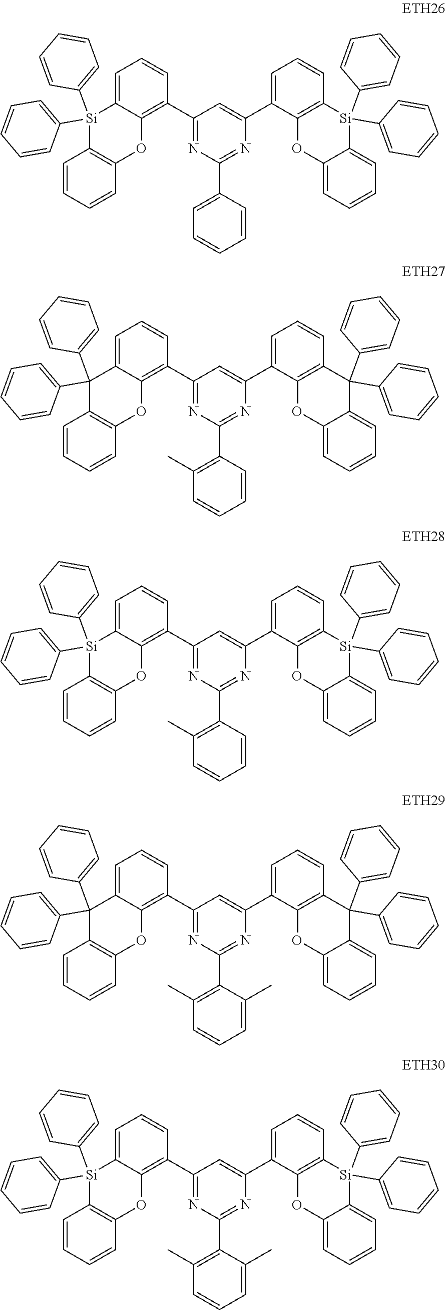

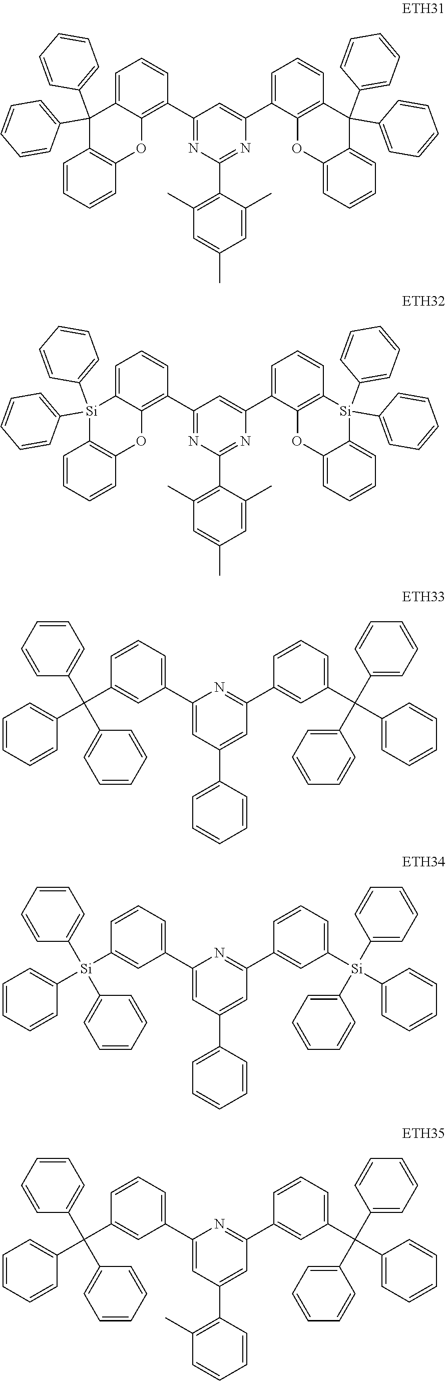

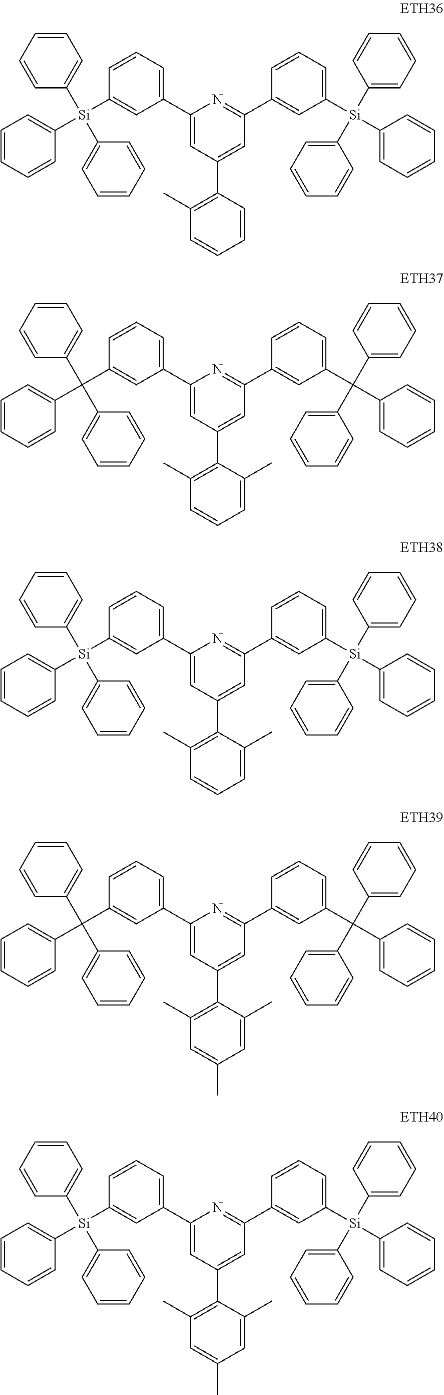

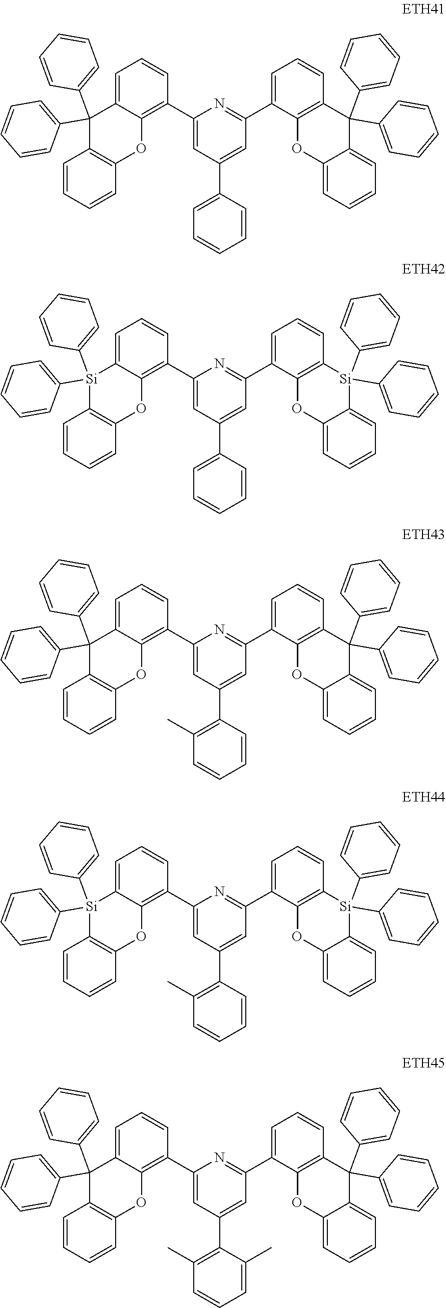

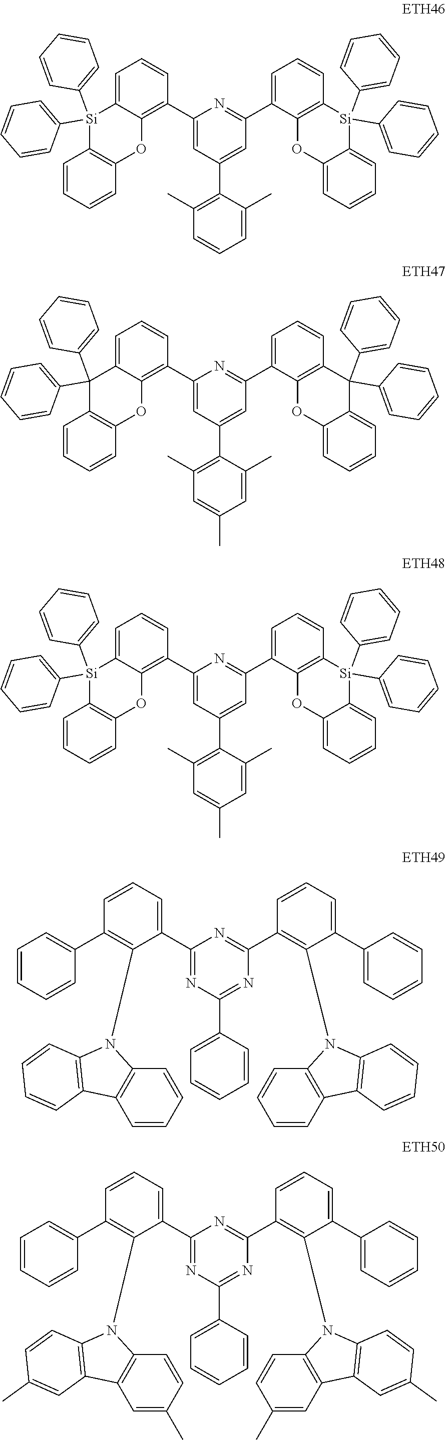

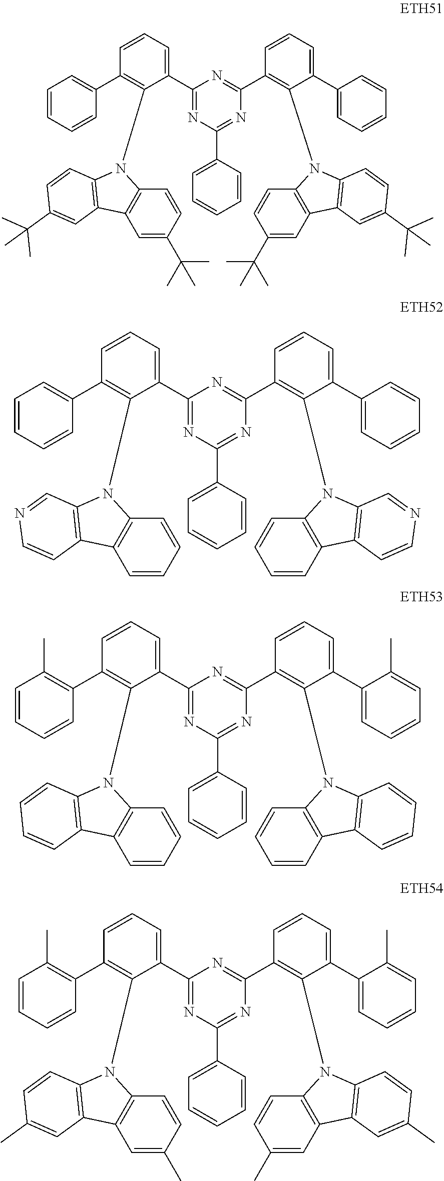

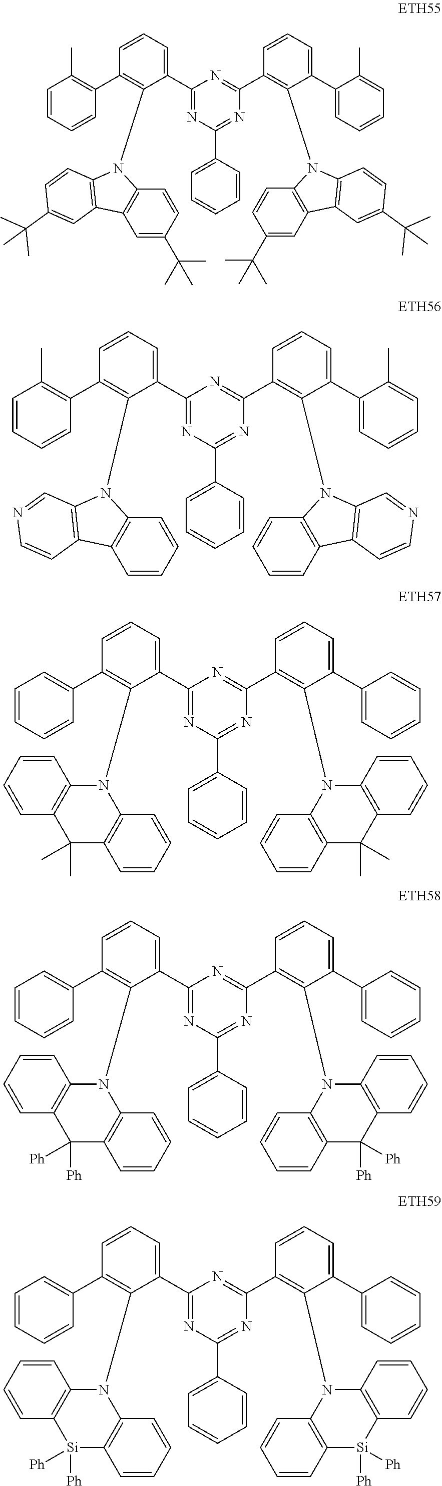

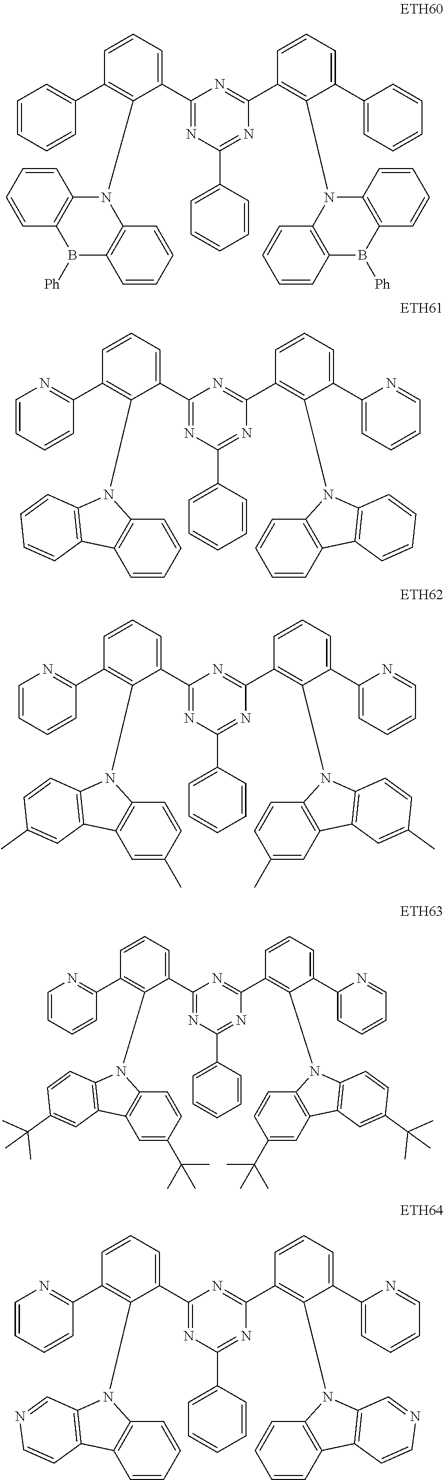

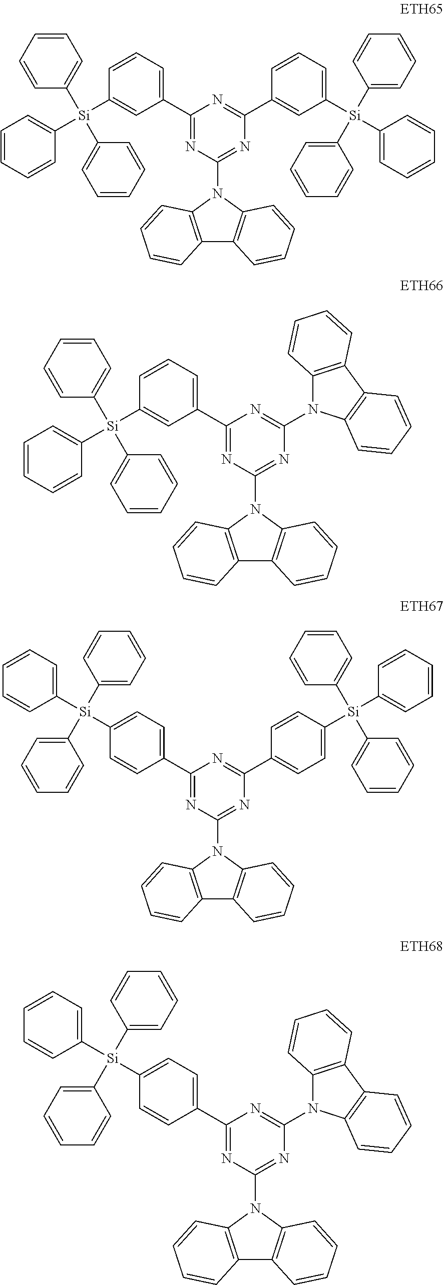 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

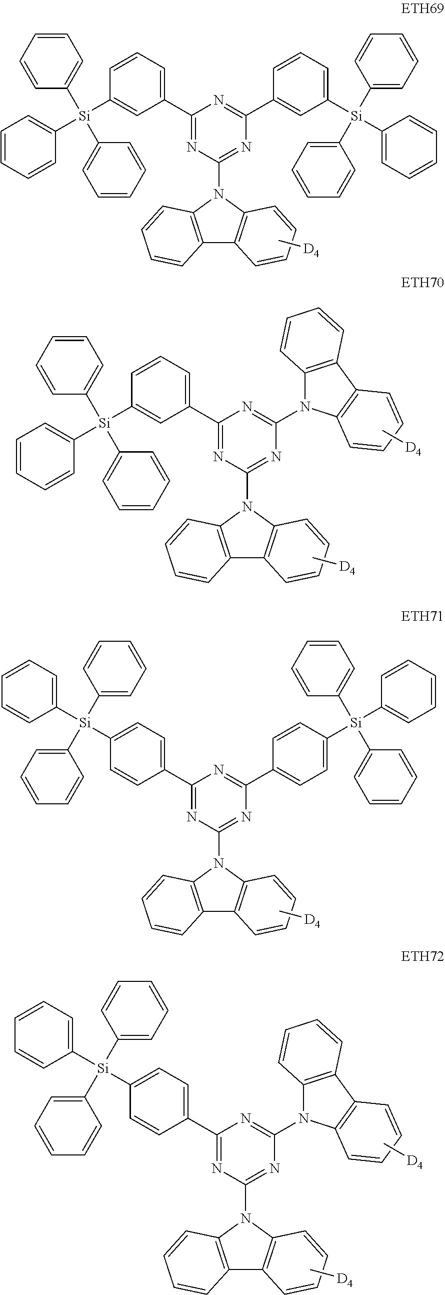

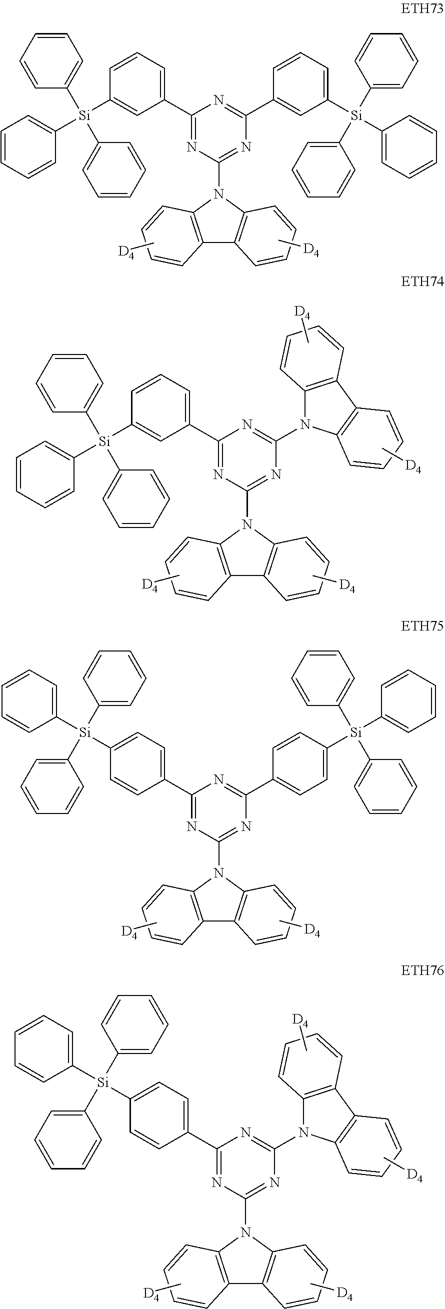

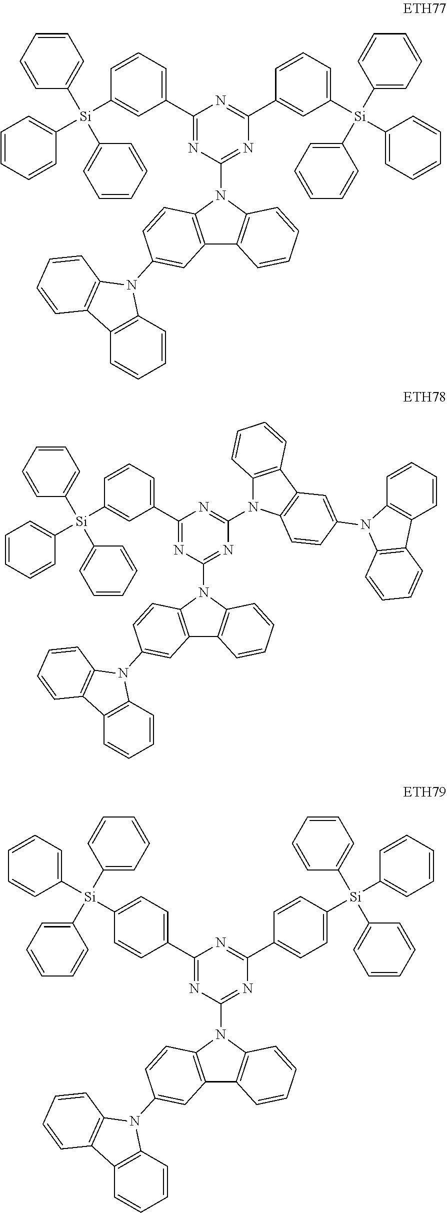 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1]

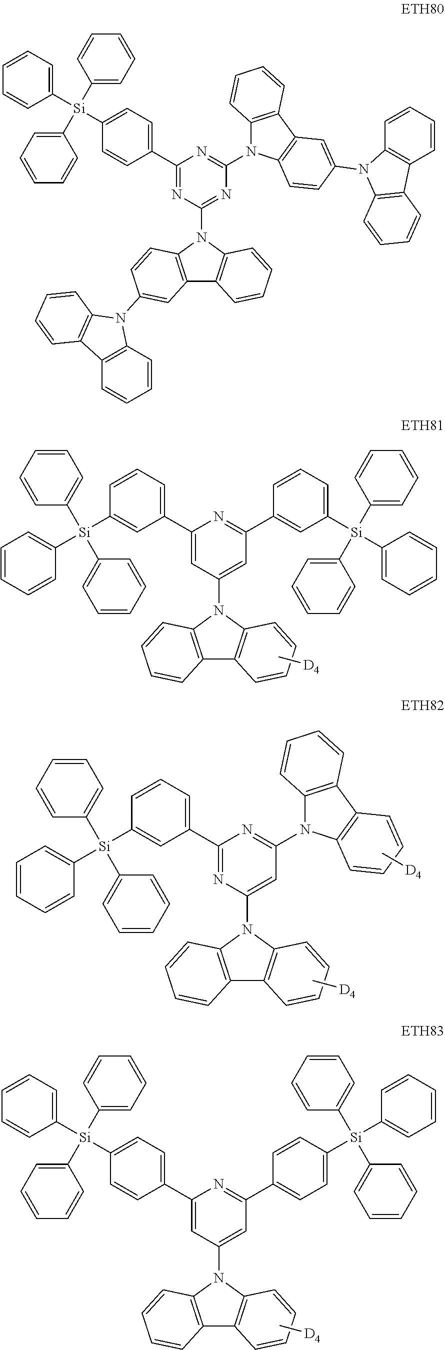

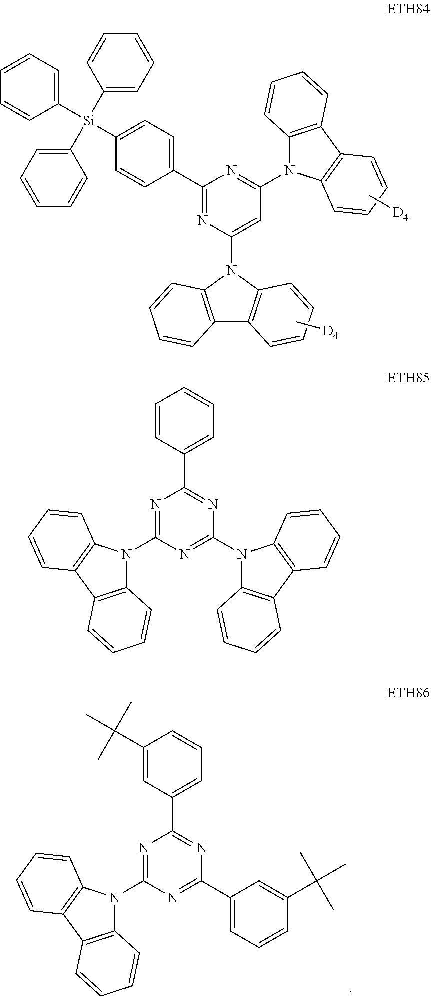

In Compound Group ET, D represents a deuterium atom, and Ph represents an unsubstituted phenyl group.

The emission layer EML may include the hole transporting host and the electron transporting host, and the hole transporting host and the electron transporting host may form an exciplex. A triplet energy of the exciplex formed by the hole transporting host and the electron transporting host may correspond to the difference between a lowest unoccupied molecular orbital (LUMO) energy level of the electron transporting host and a highest occupied molecular orbital (HOMO) energy level of the hole transporting host.

For example, an absolute value of a triplet energy level (T1) of the exciplex formed by the hole transporting host and the electron transporting host may be in a range of about 2.4 eV to about 3.0 eV. The triplet energy of the exciplex may be a value that is less than an energy gap of each host material. The exciplex may have a triplet energy level equal to or less than about 3.0 eV, which is an energy gap between the hole transporting host and the electron transporting host.

In an embodiment, the emission layer EML may include a compound represented by Formula E-2a or Formula E-2b. The compound represented by Formula E-2a or Formula E-2b may be used as a phosphorescent host material.

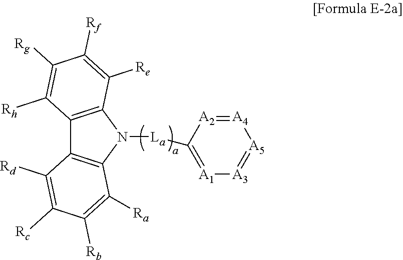

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

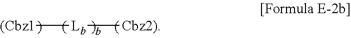

In Formula E-2b, Cbz1 and Cbz2 may each independently be an unsubstituted carbazole group or a carbazole group substituted with an aryl group having 6 to 30 ring-forming carbon atoms. In Formula E-2b, L_{b} is a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or more, multiple L_{b} may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

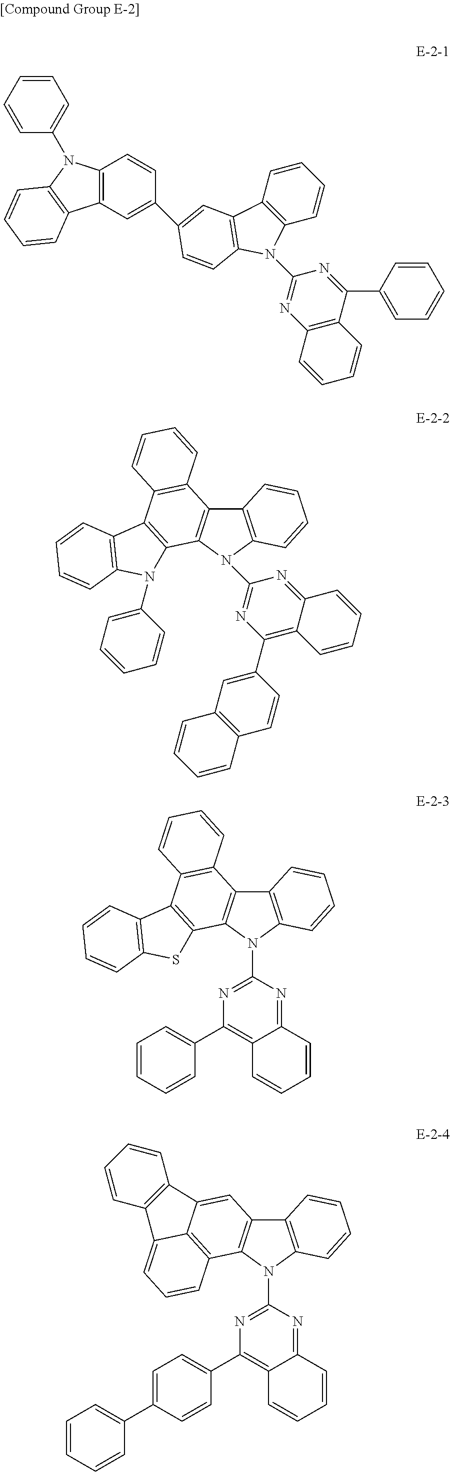

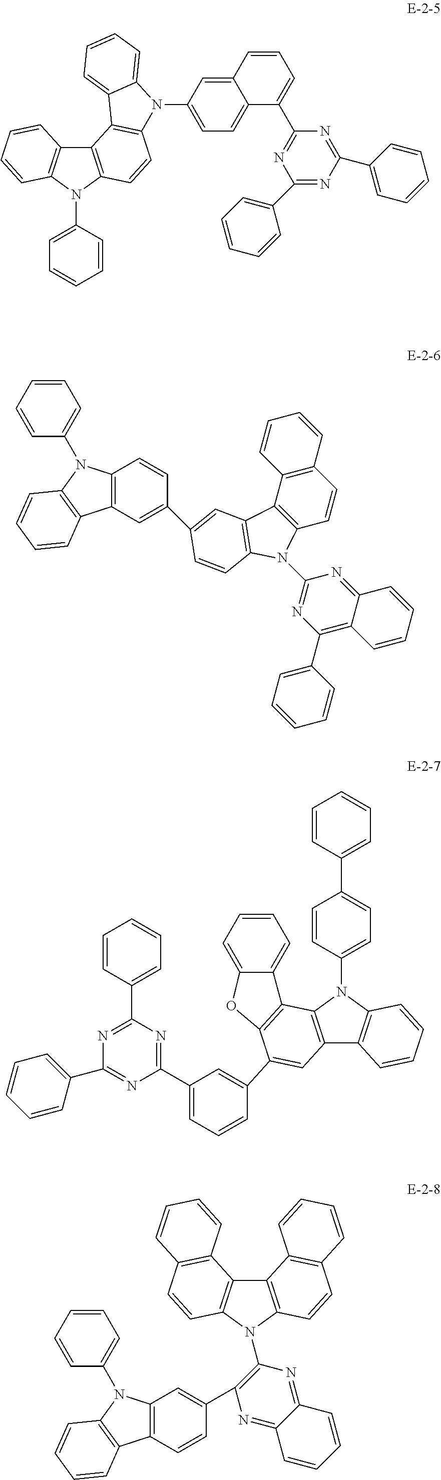 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

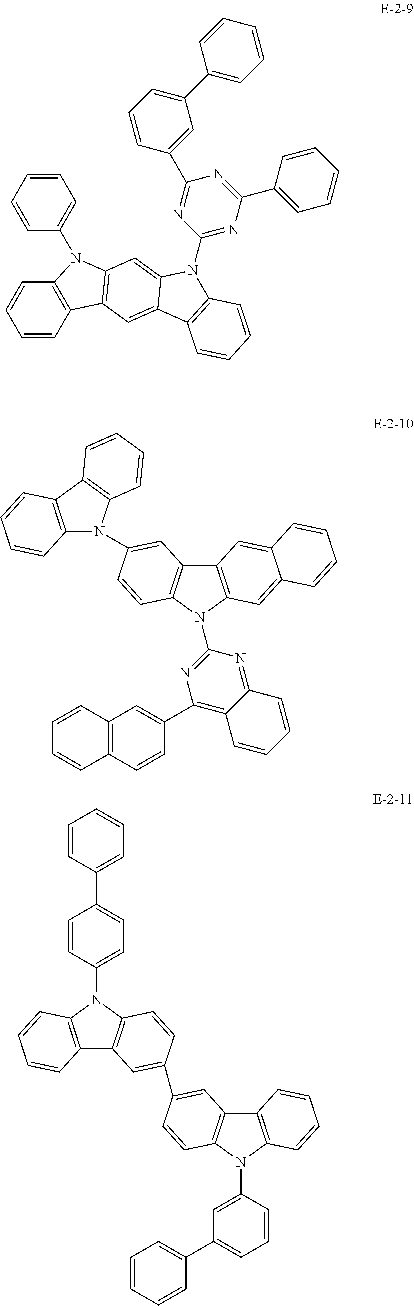

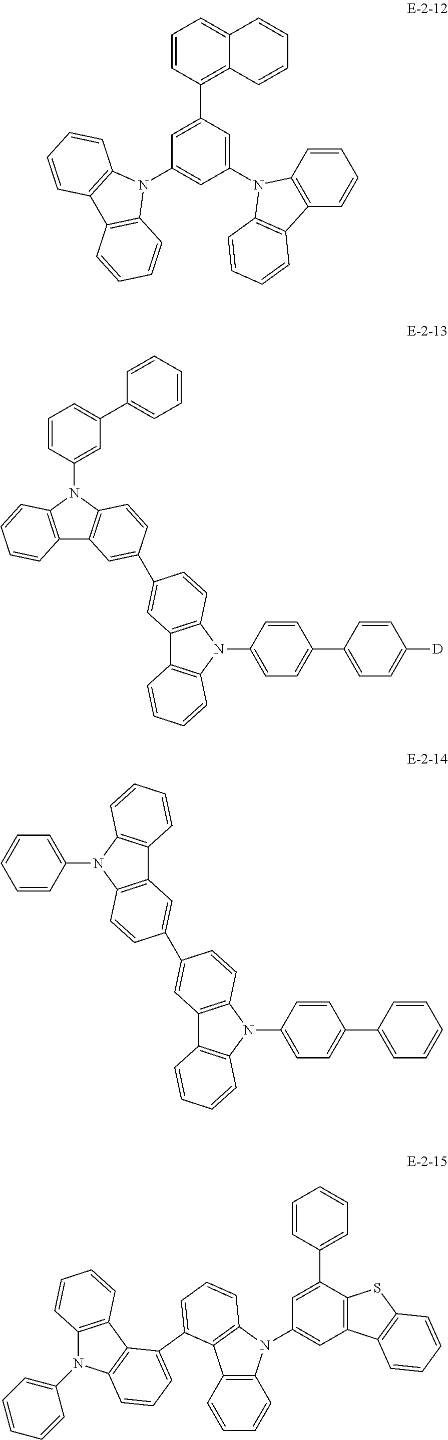 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

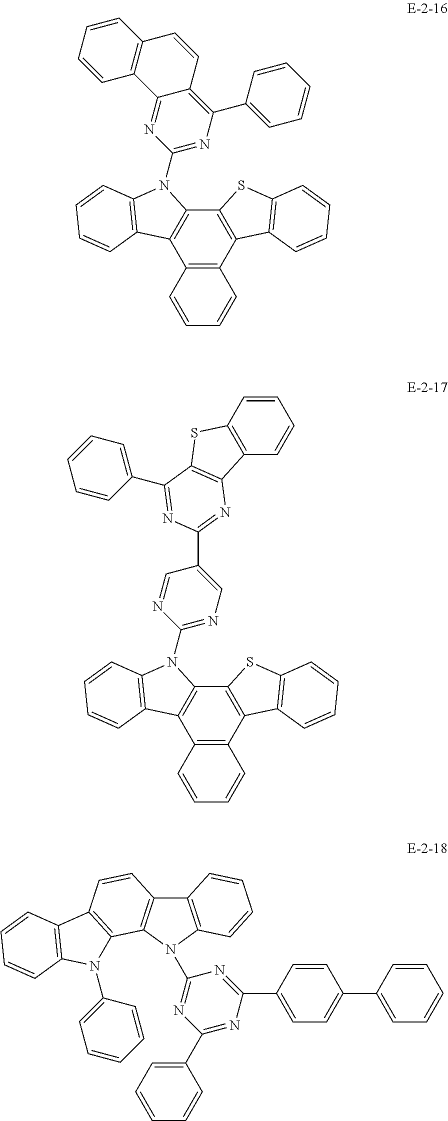 [SMILES: c1ccc(-c2nc(-n3c4ccccc4c4c5ccccc5c5c6ccccc6sc5c43)nc3c2ccc2ccccc23)cc1 ; c1ccc(-c2nc(-c3cnc(-n4c5ccccc5c5c6ccccc6c6c7ccccc7sc6c54)nc3)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

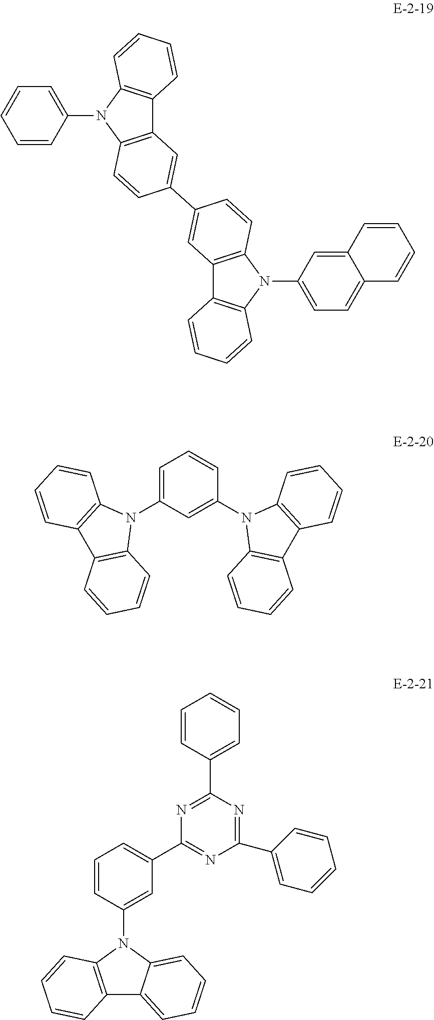 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1]

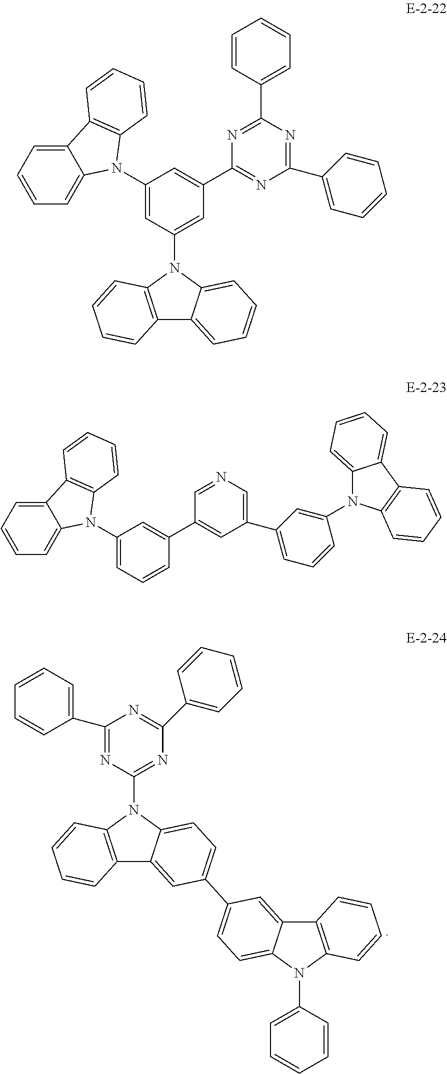 [SMILES: c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In embodiments, the emission layer EML may further include a material of the related art as a host material. For example, the emission layer EML may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), and 1,3,5-tris(1-phenyl-1H-benzo[d]imidazole-2-yl)benzene (TPBi). However, embodiments are not limited thereto. For example, tris(8-hydroxyquinolino)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO3), octaphenylcyclotetrasiloxane (DPSiO4), etc. may be used as a host material.

In an embodiment, the emission layer EML may include a compound represented by Formula M-a or Formula M-b. The compound represented by Formula M-a or Formula M-b may be used as a phosphorescent dopant material.

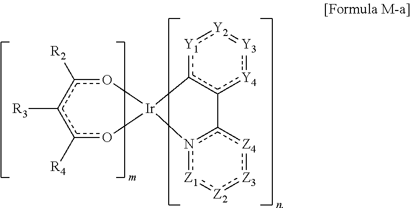

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

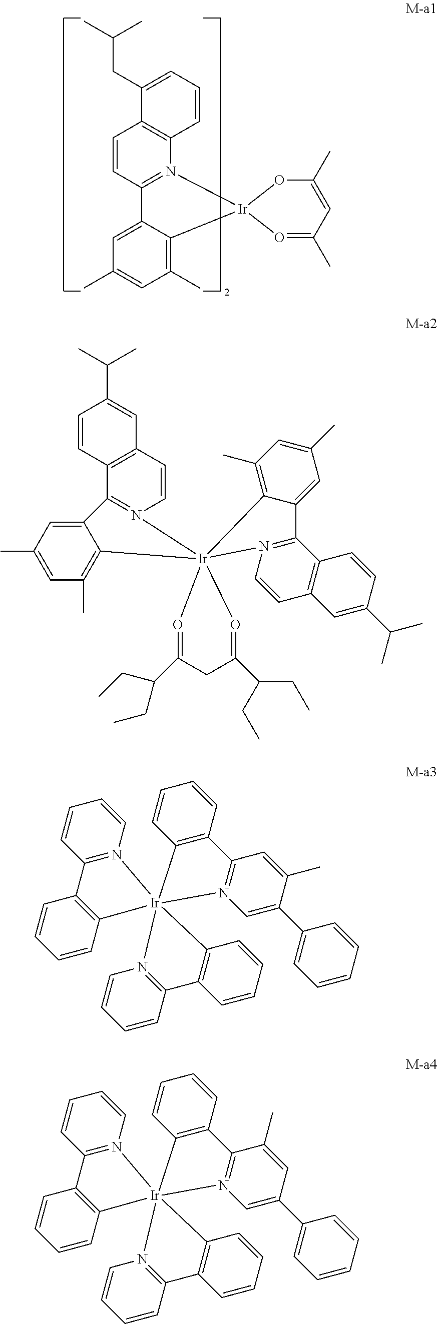

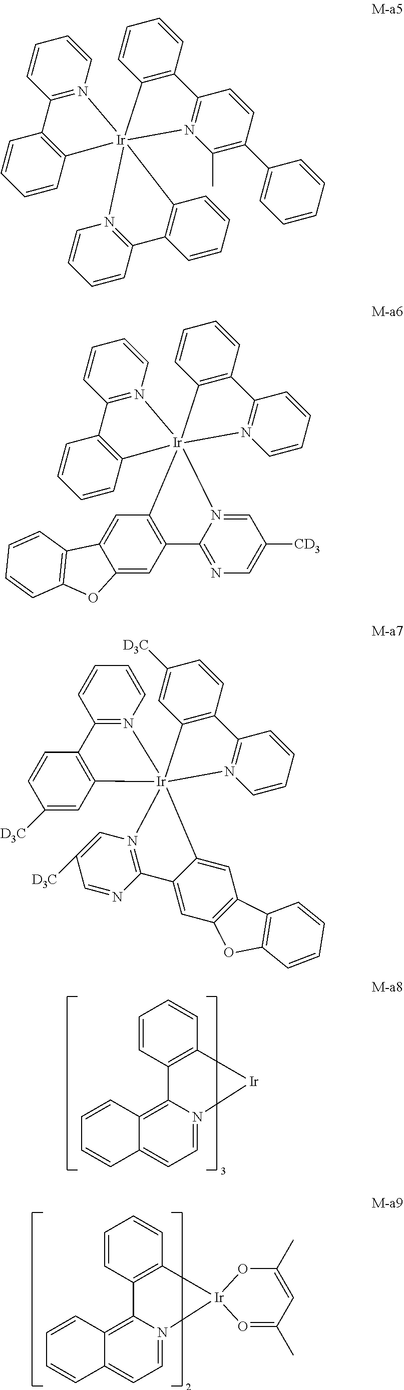

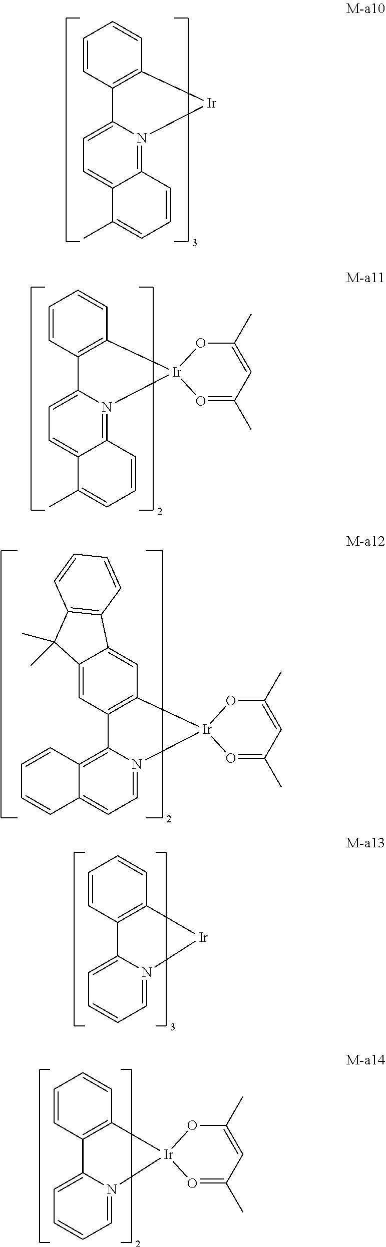

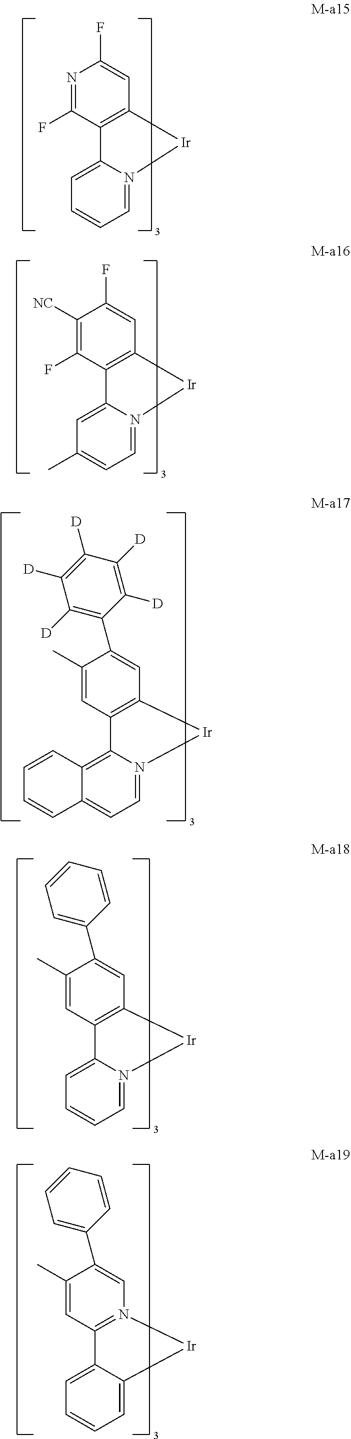

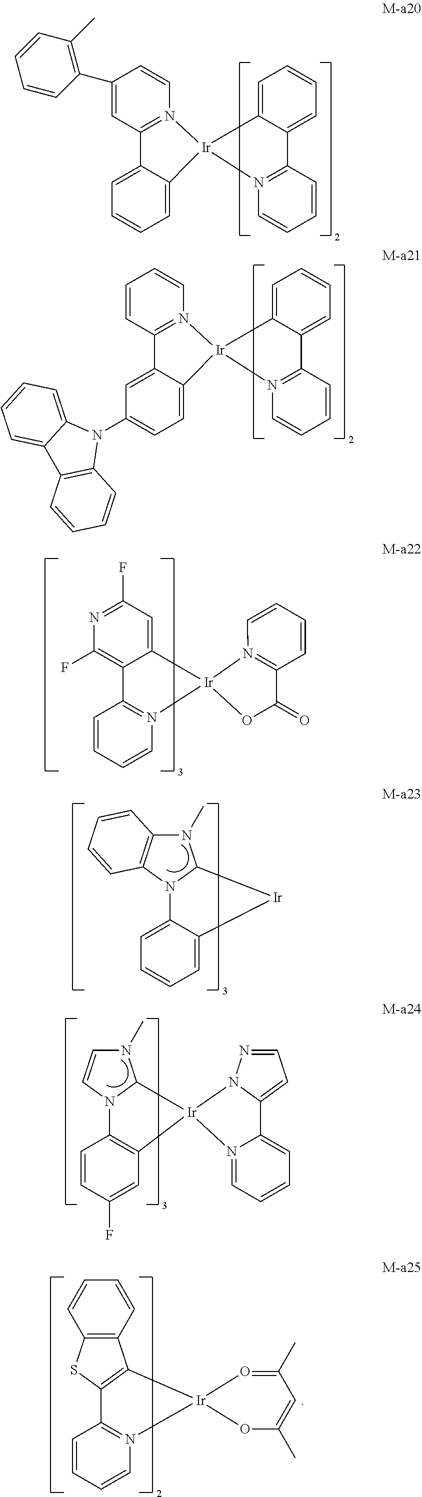

Compound M-a1 and Compound M-a2 may each be used as a red dopant material, and Compound M-a3 to Compound M-a7 may each be used as a green dopant material.

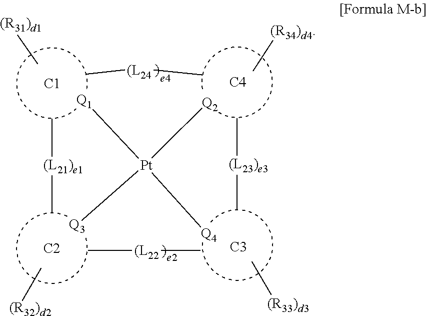

In Formula M-b, Q₁ to Q₄ may each independently be C or N; and C1 to C4 may each independently be a substituted or unsubstituted hydrocarbon ring having 5 to 30 ring-forming carbon atoms or a substituted or unsubstituted hetero ring having 2 to 30 ring-forming carbon atoms.

In Formula M-b, L₂₁ to L₂₄ may each independently be a direct linkage,

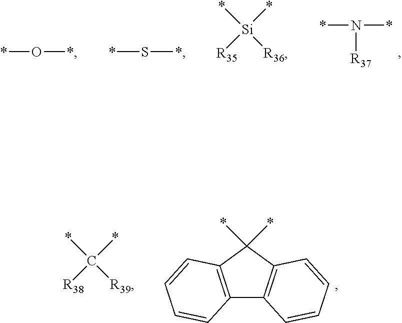

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms; and e1 to e4 may each independently be 0 or 1.

In Formula M-b, R₃₁ to R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring; and d1 to d4 may each independently be an integer from 0 to 4.

The compound represented by Formula M-b may be used as a blue phosphorescent dopant or a green phosphorescent dopant. In an embodiment, the compound represented by Formula M-b may be further included in the emission layer EML as an auxiliary dopant.

In an embodiment, the compound represented by Formula M-b may be any compound selected from Compounds M-b-1 to M-b-12. However, Compounds M-b-1 to M-b-12 are only examples, and the compound represented by Formula M-b is not limited to Compounds M-b-1 to M-b-12:

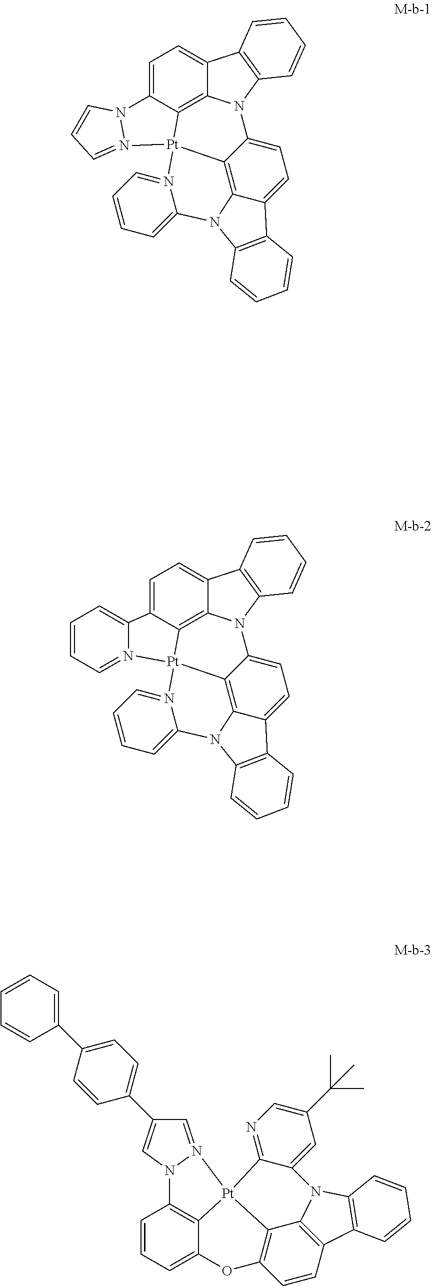

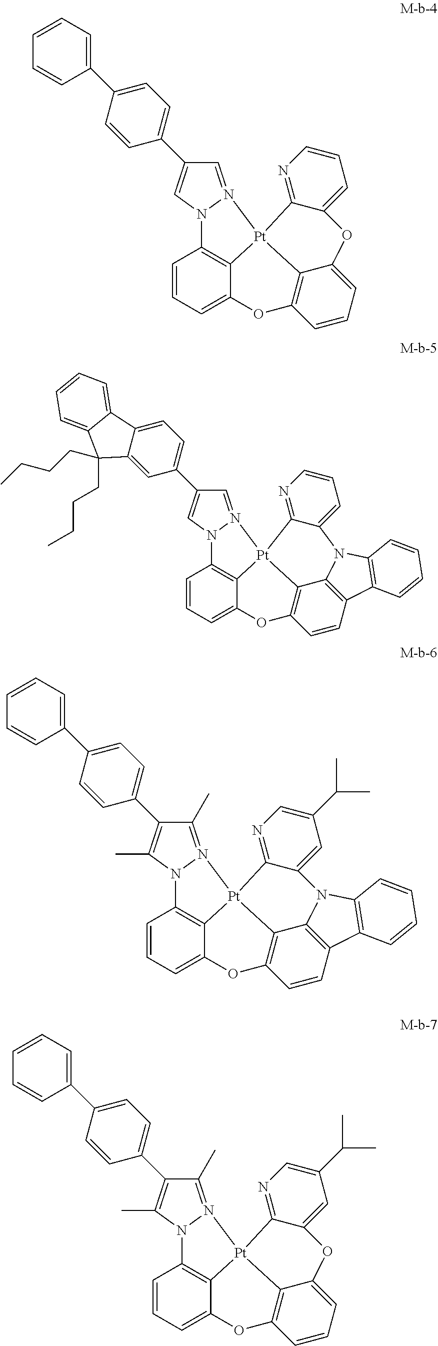

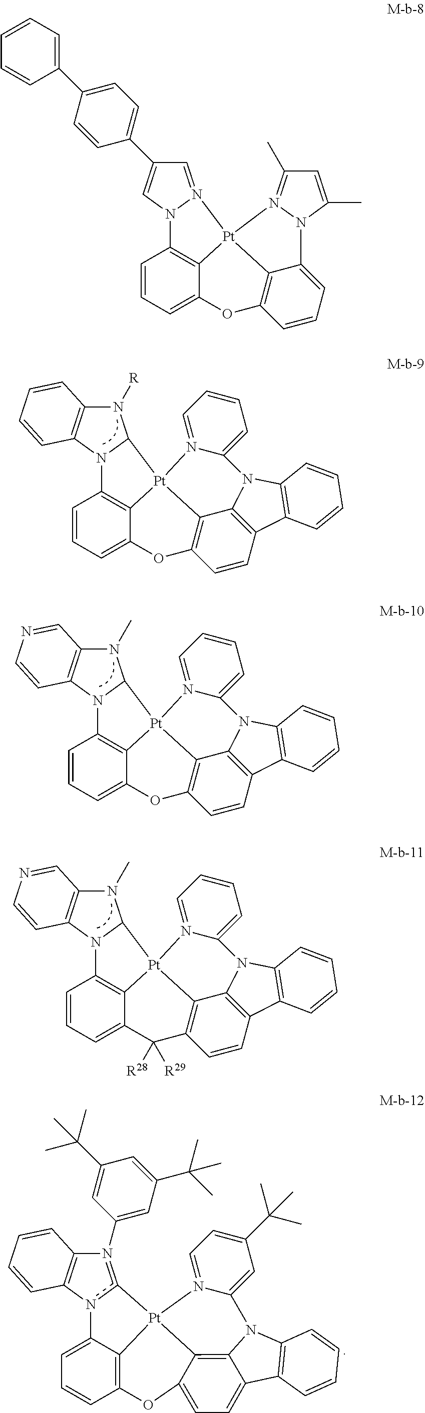

In Compounds M-b-1 to M-b-12, R, R₃₈, and R₃₉ may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In an embodiment, the emission layer EML may include a compound represented by one of Formula F-a to Formula F-c. The compound represented by one of Formula F-a to Formula F-c may be used as a fluorescence dopant material.

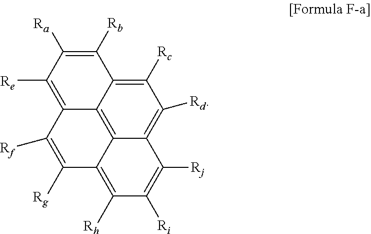

In Formula F-a, two of Rₐ to Rⱼ may each independently be substituted with a group represented by

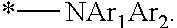

The remainder of Rₐ to Rⱼ that are not substituted with the group represented by

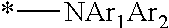

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

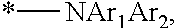

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group including O or S as a ring-forming atom.

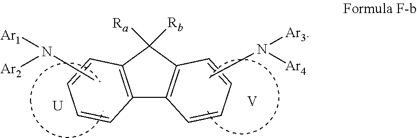

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group including O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having the fluorene core of Formula F-b may be a cyclic compound having four rings. When the number of U and V is each 0, a fused ring having the fluorene core of Formula F-b may be a cyclic compound having three rings. When the number of U and V is each 1, a fused ring having the fluorene core of Formula F-b may be a cyclic compound having five rings.

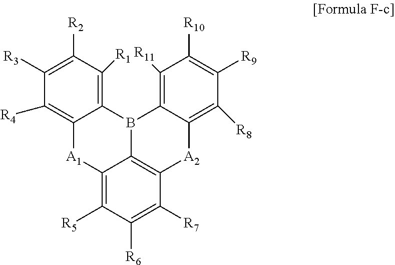

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a ring, and/or A₂ may be bonded to R₇ or R₈ to form a ring.

In an embodiment, the emission layer EML may further include, as a dopant material of the related art, a styryl derivative (e.g., 1,4-bis[2-(3-N-ethylcarbazolyl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium (III) bis(4,6-difluorophenylpyridinato-N,C2′) picolinate (FIrpic), bis(2,4-difluorophenylpyridinato)-tetrakis(1-pyrazolyl)borate iridium (III) (FIr6), or platinum octaethyl porphyrin (PtOEP) may be used as a phosphorescent dopant. However, embodiments are not limited thereto.

As described above, the emission layer EML may include the hole transporting host and the electron transporting host. In embodiments, the emission layer EML may further include an auxiliary dopant and an emission dopant. The auxiliary dopant may include a phosphorescent dopant material or a thermally activated delayed fluorescent dopant material. For example, in an embodiment, the emission layer EML may include a hole transporting host, an electron transporting host, an auxiliary dopant, and an emission dopant.

In an embodiment, the emission layer EML may include a quantum dot. In the specification, a quantum dot may be a crystal of a semiconductor compound. A quantum dot may emit light of various emission wavelengths, depending on a size of the crystal. The quantum dot may also emit light of various emission wavelengths by adjusting an elemental ratio of a quantum dot compound. A diameter of the quantum dot may be, for example, in a range of about 1 nm to about 10 nm, but embodiments are not limited thereto.

The quantum dot may be synthesized by a wet chemical process, an organometallic vapor deposition process, a molecular beam epitaxy process, or any similar process. The wet chemical process is a method of growing a quantum dot particle crystal in which an organic solvent and a precursor material are mixed together. When the crystal grows, the organic solvent naturally serves as a dispersant coordinated onto the surface of the quantum dot crystal and may control the growth of the crystal. Therefore, the wet chemical process may be more readily performed than a vapor deposition method such as metal organic chemical vapor deposition (MOCVD) or molecular beam epitaxy (MBE), and may control the growth of the quantum dot particle through a low-cost process.

The quantum dot may include a Group II-VI compound, a Group III-V compound, a Group III-VI compound, a Group I-III-VI compound, a Group IV-VI compound, a Group IV element, a Group IV compound, or a combination thereof.

Examples of a Group II-VI compound may include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as CdZnSeS, CdZnSeTe, CdZnSTe, CdHgSeS, CdHgSeTe, CdHgSTe, HgZnSeS, HgZnSeTe, HgZnSTe, and a mixture thereof; and any combination thereof. In an embodiment, a Group II-VI compound may further include a Group I metal and/or a Group IV element. Examples of a Group I-II-VI compound may include CuSnS and CuZnS; and examples of a Group II-IV-VI compound may include ZnSnS, etc. Examples of a Group I-II-IV-VI compound may include a quaternary compound such as Cu₂ZnSnS₂, Cu₂ZnSnS₄, Cu₂ZnSnSe₄, Ag₂ZnSnS₂, and a mixture thereof.

Examples of a Group III-VI compound may include: a binary compound such as In₂S₃ and In₂Se₃; a ternary compound such as InGaS₃ and InGaSe₃; and any combination thereof.

Examples of a Group I-III-VI compound may include: a ternary compound such as AgInS, AgInS₂, CuInS, CuInS₂, AgGaS₂, CuGaS₂CuGaO₂, AgGaO₂, AgAlO₂, and a mixture thereof; a quaternary compound such as AgInGaS₂ and CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II metal. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof.

Examples of a Group II-IV-V compound may include a ternary compound such as ZnSnP, ZnSnP₂, ZnSnAs₂, ZnGeP₂, ZnGeAs₂, CdSnP₂, CdGeP₂, and a mixture thereof.

Examples of a Group IV element may include Si, Ge, and a mixture thereof. Examples of a Group IV compound may include a binary compound such as SiC, SiGe, and a mixture thereof.

Each element included in a compound, such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (wherein x is a real number between 0 and 1).

In an embodiment, a quantum dot may have a core/shell structure in which a quantum dot surrounds another quantum dot. A quantum dot having a core/shell structure may have a concentration gradient in which the concentration of an element that is present in the shell decreases toward the core.

In embodiments, the quantum dot may have the above-described core/shell structure that includes a core containing nanocrystals and a shell surrounding the core. The shell of a quantum dot may serve as a protection layer that prevents chemical deformation of the core to maintain semiconductor properties, and/or may serve as a charging layer that imparts electrophoretic properties to the quantum dot. The shell may be single-layered or multilayered. Examples of a shell of a quantum dot may include a metal oxide, a non-metal oxide, a semiconductor compound, and a combination thereof.

Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fc₃O₄, CoO, Co₃O₄, and NiO; a ternary compound such as MgAl₂O₄, CoFc₂O₄, NiFe₂O₄, and CoMn₂O₄; and any combination thereof, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width at half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited, and may be any form that is used in the related art. For example, a quantum dot may have a spherical shape, a pyramidal shape, a multi-arm shape, or a cubic shape, or a quantum dot may be in the form of nanoparticles, nanotubes, nanowires, nanofibers, nanoplate, etc.

As a size of a quantum dot is adjusted or an elemental ratio of a quantum dot compound is adjusted, an energy band gap may be controlled accordingly, so that light in various wavelength ranges may be obtained from a quantum dot emission layer. Therefore, by utilizing a quantum dot as described herein (using different sizes of quantum dots or having different elemental ratios in a quantum dot compound), a light emitting element that emits light in various wavelength ranges may be implemented. For example, a size of a quantum dot may be adjusted or an elemental ratio of a quantum dot compound may be adjusted to emit red light, green light, and/or blue light. In an embodiment, quantum dots may be configured to emit white light by combining various colors of light.

In the light-emitting elements ED according to embodiments as shown in FIGS. 3 to 10, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single-layered structure consisting of an electron injection layer EIL or an electron transport layer ETL, or may have a single-layered structure formed of an electron injection material and an electron transport material. The electron transport region ETR may have a single-layered structure formed of different materials. In embodiments, the electron transport region ETR may have an electron transport layer ETL/electron injection layer EIL structure, or a hole blocking layer HBL/electron transport layer ETL/electron injection layer EIL structure, in which the layers of each structure are stacked from the emission layer EML in its respective stated order, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

The electron transport layer ETL may be disposed between the emission layer EML and the electron injection layer EIL. The electron transport layer ETL may include at least one layer. The electron transport layer ETL may have a structure consisting of a layer consisting of a single material, a structure consisting of a layer including different materials, or a structure including multiple layers including different materials.

In embodiments, the electron transport layer ETL may have a single-layered structure. For example, an electron transport layer ETL having a single-layered structure may consist of one electron transport material or may include multiple electron transport materials. For example, an electron transport layer ETL having a single-layered structure may consist of a first electron transport layer ETL1. In embodiments, the electron transport layer ETL may have a first electron transport layer ETL1/second electron transport layer ETL2 structure, or a first electron transport layer ETL1/second electron transport layer ETL2/third electron transport layer ETL3 structure, in which the layers of each structure may be stacked from the emission layer EML in its respective stated order. However, embodiments are not limited thereto, and the electron transport layer ETL may have a multilayered structure including four or more layers.

The electron transport layer ETL having a single-layered structure may have a fifth positive GSP or a fifth negative GSP. The electron transport layer ETL having a single-layered structure may be an organic layer that includes a compound having the fifth positive GSP or a compound having the fifth negative GSP. For example, an absolute value of the fifth positive GSP may be equal to or less than about 10 mV/nm (|fifth positive GSP|≤10 mV/nm), and an absolute value of the fifth negative GSP may be equal to or less than about 10 mV/nm (|fifth negative GSP|≤10 mV/nm). The fifth positive GSP and the fifth negative GSP that are applicable to the hole transport layer HTL having a single-layered structure may each independently have an absolute value equal to or less than about 10 mV/nm, but embodiments are not limited thereto.

When the electron transport layer ETL has a single-layered structure and the single-layered electron transport layer ETL has the fifth positive GSP or the fifth negative GSP, the hole transport layer HTL may have a multilayered structure. In an embodiment, when the hole transport layer HTL has a multilayered structure, a hole transport layer HTL adjacent to the emission layer EML may have the second negative GSP.

In an embodiment, when the electron transport layer ETL has a multilayered structure, an electron transport layer ETL adjacent to the second electrode EL2 (for example, a cathode) among the layers included in the electron transport layer ETL may have the first positive GSP. However, embodiments are not limited thereto. For example, when the hole transport layer HTL has a multilayered structure, and a hole transport layer HTL adjacent to the emission layer EML among the hole transport layers HTL has the second negative GSP, the electron transport layer ETL that is adjacent to the second electrode EL2 may not have the first positive GSP.

In an embodiment, multiple electron transport layers ETL may be stacked between the emission layer EML and the second electrode EL2. Among the stack of electron transport layers ETL, at least one electron transport layer ETL disposed adjacent to the second electrode EL2 may have the first positive GSP. The first positive GSP may be equal to or greater than about 10 mV/nm. For example, the first positive GSP may be in a range of about 10 mV/nm to about 50 mV/nm, but embodiments are not limited thereto.

Referring to FIGS. 7 and 8, the electron transport layer ETL may include the first electron transport layer ETL1 and the second electron transport layer ETL2 disposed between the emission layer EML and the second electrode EL2. The first electron transport layer ETL1 and the second electron transport layer ETL2 may be sequentially disposed on the emission layer EML. The first electron transport layer ETL1 may be directly disposed on the emission layer EML, but embodiments are not limited thereto. Although not shown in FIGS. 7 and 8, in an embodiment, a hole blocking layer HBL (FIG. 5) may be disposed between the first electron transport layer ETL1 and the emission layer EML.

The first electron transport layer ETL1 may be positioned adjacent to the emission layer EML, and the second electron transport layer ETL2 may be positioned adjacent to the second electrode EL2. The second electron transport layer ETL2 may be positioned closer to the second electrode EL2 than the first electron transport layer ETL1. The second electron transport layer ETL2 that is adjacent to the second electrode EL2, among the first electron transport layer ETL1 and the second electron transport layer ETL2, may have the first positive GSP. The second electron transport layer ETL2 may be an organic layer that includes a compound having the first positive GSP.

In the light emitting element ED shown in FIGS. 7 and 8, the first electron transport layer ETL1 may be positioned closer to the emission layer EML and may be spaced farther away from the second electrode EL2 than the second electron transport layer ETL2. The first electron transport layer ETL1 may not have the first positive GSP. The first electron transport layer ETL1 may have the fifth positive GSP or the fifth negative GSP. The first electron transport layer ETL1 may be an organic layer that includes a compound having the fifth positive GSP or a compound having the fifth negative GSP. The fifth positive GSP may be different from the first positive GSP.

In embodiments, the fifth positive GSP may have an absolute value equal to or less than about 10 mV/nm (|fifth positive GSP|≤10 mV/nm), and the fifth negative GSP may have an absolute value equal to or less than about 10 mV/nm (|fifth negative GSP|≤10 mV/nm). The fifth positive GSP and the fifth negative GSP that are applicable to the first electron transport layer ETL1 may each independently have an absolute value equal to or less than about 10 mV/nm, but embodiments are not limited thereto.

In an embodiment, an absolute value of the fifth positive GSP and an absolute value of the fifth negative GSP may each not be equal to or greater than the absolute value of the first positive GSP (|fifth positive GSP or the fifth negative GSP|<|first positive GSP|). Thus, when the first electron transport layer ETL1 has the fifth positive GSP or the fifth negative GSP, the fifth positive GSP and the fifth negative GSP may each have an absolute value that is less than an absolute value of first positive GSP. For example, when the first electron transport layer ETL1 has the fifth positive GSP, the fifth positive GSP may have a smaller absolute value than the first positive GSP of the second electron transport layer ETL2. When the first electron transport layer ETL1 has the fifth negative GSP, the absolute value of the fifth negative GSP may be less than the absolute value of the first positive GSP of the second electron transport layer ETL2.

In embodiments, when the electron transport layer ETL includes multiple electron transport layers, an electron transport layer ETL adjacent to the second electrode EL2 among the electron transport layers ETL may not have the first positive GSP. For example, in the light emitting element ED shown in FIG. 8, the second electron transport layer ETL2 may not have the first positive GSP. In the light emitting element ED shown in FIG. 8, the hole transport layer HTL may have a multilayered structure, and the second hole transport layer HTL2 adjacent to the emission layer EML among the hole transport layers HTL1 and HTL2 may have the second negative GSP.

Referring to FIG. 9, the electron transport layer ETL may have a multilayered structure that includes three layers. The electron transport layer ETL may include a first electron transport layer ETL1, a second electron transport layer ETL2, and a third electron transport layer ETL3 disposed between the emission layer EML and the second electrode EL2. The first electron transport layer ETL1, the second electron transport layer ETL2, and the third electron transport layer ETL3 may be sequentially disposed on the emission layer EML. Accordingly, the second electron transport layer ETL2 may be positioned closer to the second electrode EL2 than the first electron transport layer ETL1, and the third electron transport layer ETL3 may be positioned closer to the second electrode EL2 than the second electron transport layer ETL2. The first electron transport layer ETL1 is spaced farther away from the second electrode EL2 than the second and third electron transport layers ETL2 and ETL3 and may be adjacent to the emission layer EML.

As described above, in the electron transport layer ETL having a multilayered structure, an electron transport layer ETL adjacent to the second electrode EL2 may have the first positive GSP. In the light emitting element ED shown in FIG. 9, at least one of the second electron transport layer ETL2 and the third electron transport layer ETL3, which are adjacent to the second electrode EL2 among the first to third electron transport layers ETL1, ETL2, and ETL3, may each independently have the first positive GSP. For example, among the first to third electron transport layers ETL1, ETL2, and ETL3, the second electron transport layer ETL2 may have the first positive GSP, and the first electron transport layer ETL1 and the third electron transport layer ETL3 may not have the first positive GSP. As another example, among the first to third electron transport layers ETL1, ETL2, and ETL3, the third electron transport layer ETL3 may have the first positive GSP, and the first electron transport layer ETL1 and the second electron transport layer ETL2 may not have the first positive GSP. The second electron transport layer ETL2 or the third electron transport layer ETL3 may be an organic layer that includes a compound having the first positive GSP.

In the light emitting element ED shown in FIG. 9, among the first to third electron transport layers ETL1, ETL2, and ETL3, the first electron transport layer ETL1 may be adjacent to the emission layer EML and spaced away from the second electrode EL2. The first electron transport layer ETL1 may not have the first positive GSP. In an embodiment, the first electron transport layer ETL1 may have a sixth positive GSP or a sixth negative GSP. In an embodiment, among the second electron transport layer ETL2 and the third electron transport layer ETL3, the layer that does not have the first positive GSP may have the sixth positive GSP or the sixth negative GSP.

For example, the second electron transport layer ETL2 may have the first positive GSP. Thus, the first electron transport layer ETL1 and the third electron transport layer ETL3 may not have the first positive GSP. In an embodiment, the first electron transport layer ETL1 and the third electron transport layer ETL3 may each independently have the sixth positive GSP or the sixth negative GSP. The first electron transport layer ETL1 and the third electron transport layer ETL3 may each be an organic layer that includes a compound having the sixth positive GSP or a compound having the sixth negative GSP. The GSP of the first electron transport layer ETL1 and the GSP of the third electron transport layer ETL3 may be the same as or different from each other.

For example, the third electron transport layer ETL3 may have the first positive GSP, and the first electron transport layer ETL1 and the second electron transport layer ETL2 may each not have the first positive GSP. Thus, the first electron transport layer ETL1 and the second electron transport layer ETL2 may each independently have the sixth positive GSP or the sixth negative GSP. The first electron transport layer ETL1 and the second electron transport layer ETL2 may each be an organic layer that includes a compound having the sixth positive GSP or a compound having the sixth negative GSP. The GSP of the first electron transport layer ETL1 and the GSP of the second electron transport layer ETL2 may be the same as or different from each other.

In an embodiment, an absolute value of the sixth positive GSP may be equal to or less than about 10 mV/nm (|sixth positive GSP|≤10 mV/nm), and an absolute value of the sixth negative GSP may be equal to or less than about 10 mV/nm (|sixth negative GSP|≤10 mV/nm). An absolute value of the sixth positive GSP and an absolute value of the sixth negative GSP may each independently be equal to or less than about 10 mV/nm, but embodiments are not limited thereto.

In an embodiment, the absolute value of the sixth positive GSP may not be equal to or greater than the absolute value of the first positive GSP (|sixth positive GSP|<|first positive GSP|), and the absolute value of the sixth negative GSP may not be equal to or greater than the absolute value of the first positive GSP (|sixth negative GSP|<|first positive GSP|). Thus, an absolute value of the sixth positive GSP and an absolute value of the sixth negative GSP of the first electron transport layer ETL1 may each be less than the absolute value of the first positive GSP. In embodiments, an absolute value of the sixth positive GSP and an absolute value of the sixth negative GSP of the second electron transport layer ETL2 or the third electron transport layer ETL3 may each be less than the absolute value of the first positive GSP.

For example, when the first electron transport layer ETL1 has the sixth positive GSP, an absolute value of the sixth positive GSP may be less than the absolute value of first positive GSP of the second electron transport layer ETL2 or the third electron transport layer ETL3. For example, when the first electron transport layer ETL1 has the sixth negative GSP, an absolute value of the sixth negative GSP may be less than the absolute value of first positive GSP of the second electron transport layer ETL2 or the third electron transport layer ETL3.

In embodiments, when the second electron transport layer ETL2 has the sixth positive GSP and the third electron transport layer ETL3 has the first positive GSP, an absolute value of the sixth positive GSP may be less than an absolute value of the first positive GSP. In embodiments, when the second electron transport layer ETL2 has the sixth negative GSP and the third electron transport layer ETL3 has the first positive GSP, an absolute value of the sixth negative GSP may be less than an absolute value of the first positive GSP. When the third electron transport layer ETL3 has the sixth positive GSP and the second electron transport layer ETL2 has the first positive GSP, an absolute value of the sixth positive GSP may be less than an absolute value of the first positive GSP of the second electron transport layer ETL2. When the third electron transport layer ETL3 has the sixth negative GSP and the second electron transport layer ETL2 has the first positive GSP, an absolute value of the sixth negative GSP may be less than an absolute value of the first positive GSP of the second electron transport layer ETL2.

In embodiments, among the first to third electron transport layers ETL1, ETL2, and ETL3, at least one of the second electron transport layer ETL2 and the third electron transport layer ETL3 adjacent to the second electrode EL2 may not have the first positive GSP. For example, in the light emitting element ED shown in FIG. 9, the second electron transport layer ETL2 and/or the third electron transport layer ETL3 may not have the first positive GSP. Thus, as shown in FIG. 9, the hole transport layer HTL may have a multilayered structure, and the hole transport layer HTL that is adjacent to the emission layer EML may have the second negative GSP.

In the light emitting element ED according to an embodiment, the electron transport region ETR may include a compound represented by Formula ET-2:

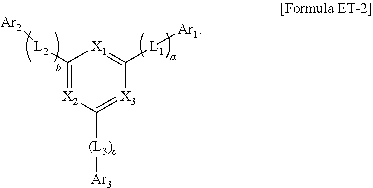

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium (bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one of Compound ET1 to Compound ET36:

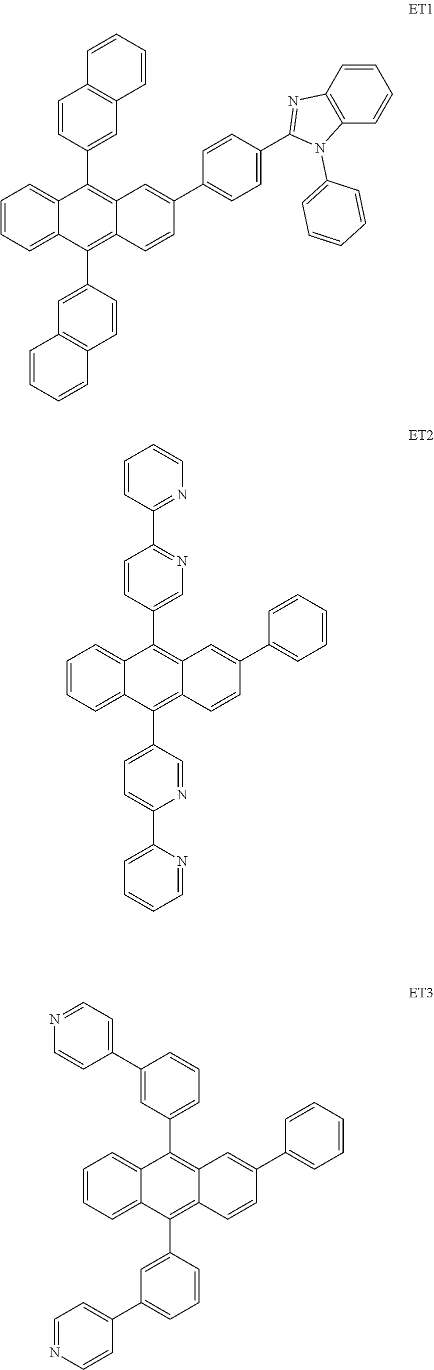 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

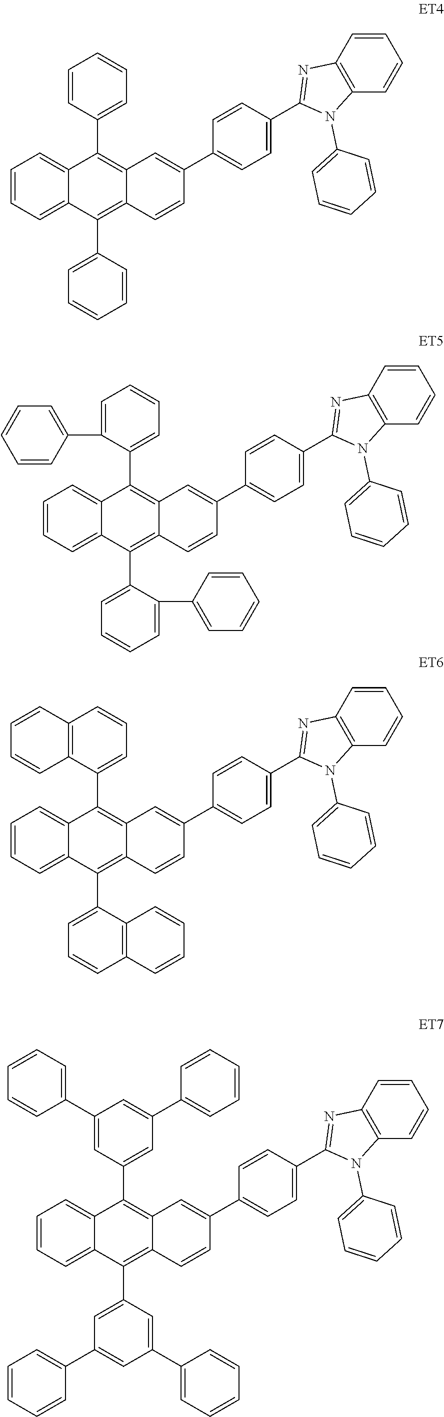 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

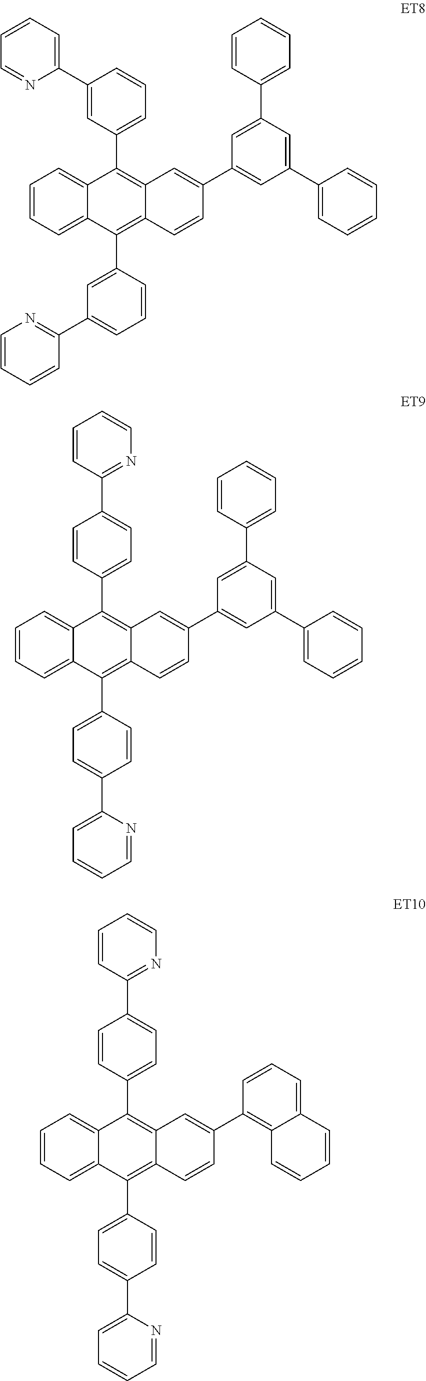

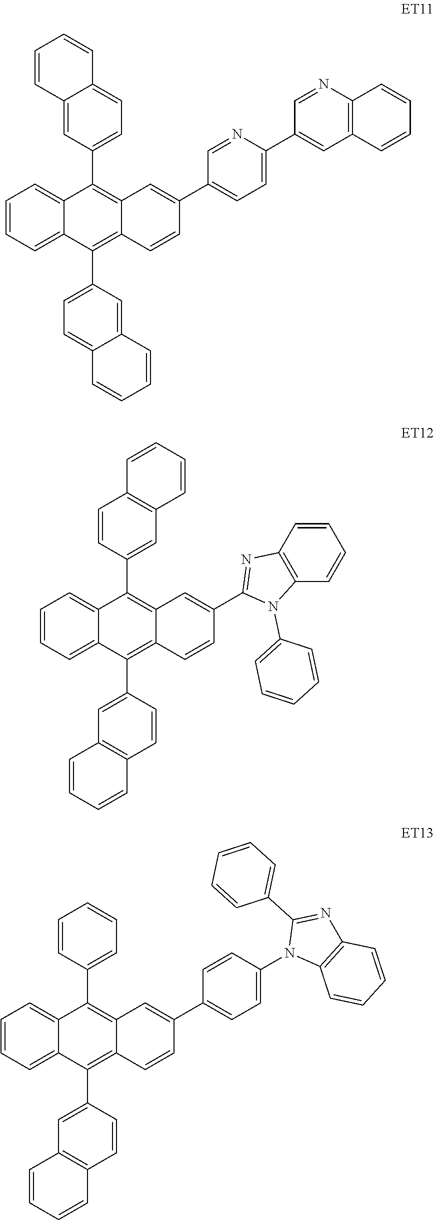 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

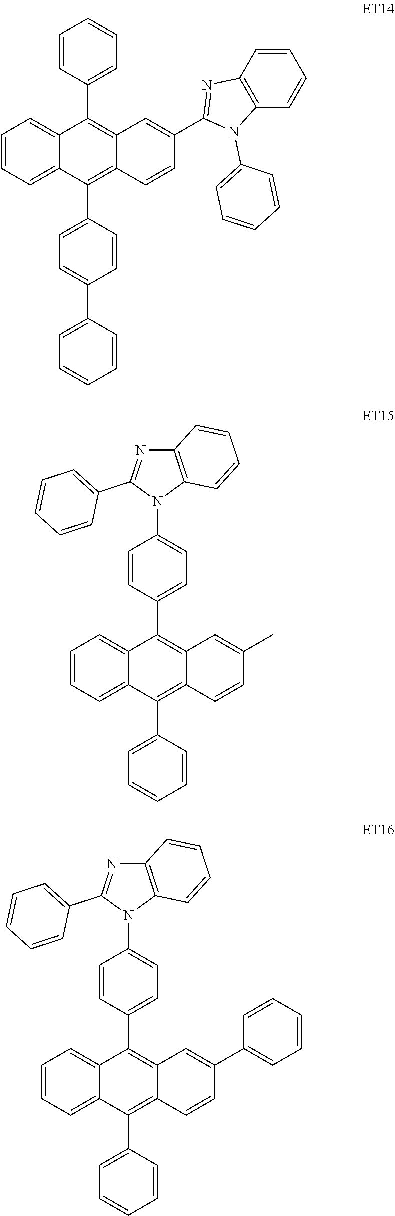

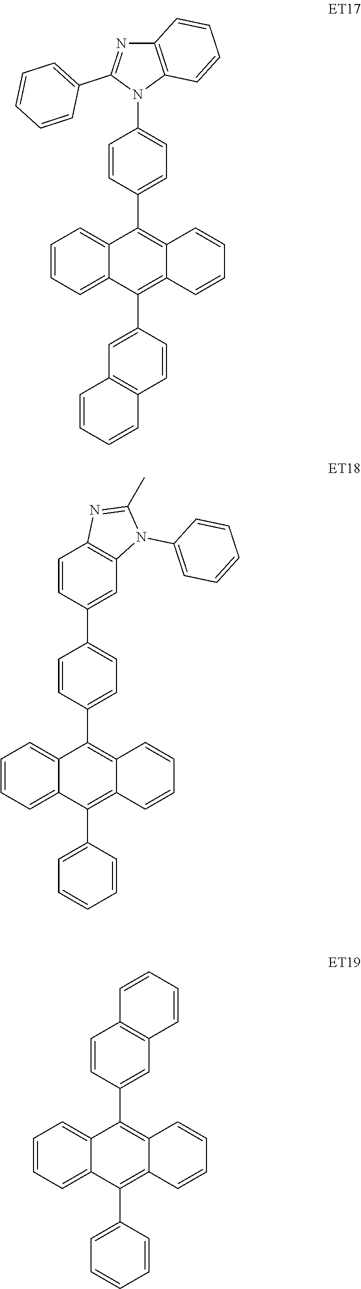

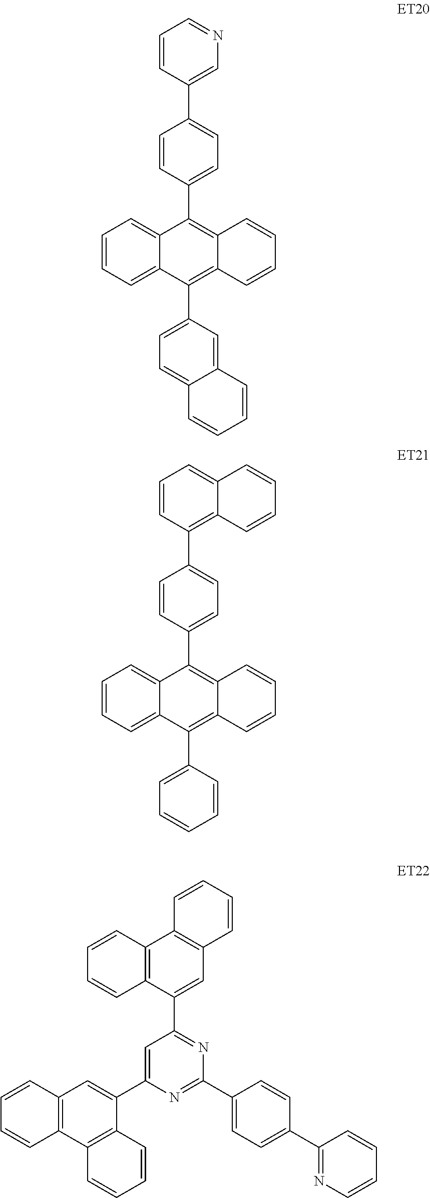

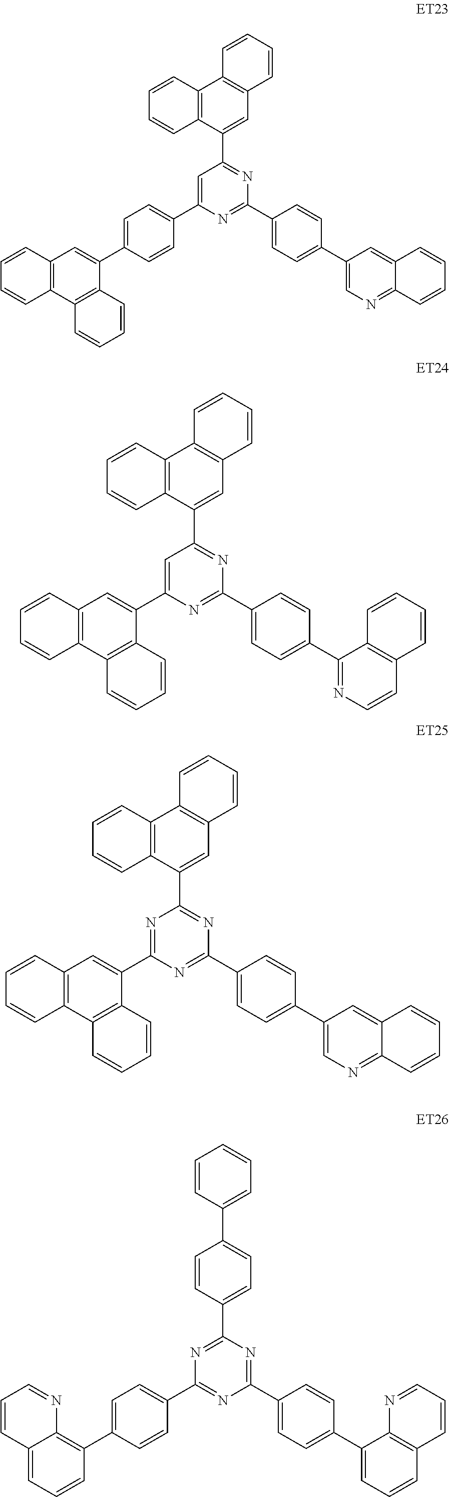 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

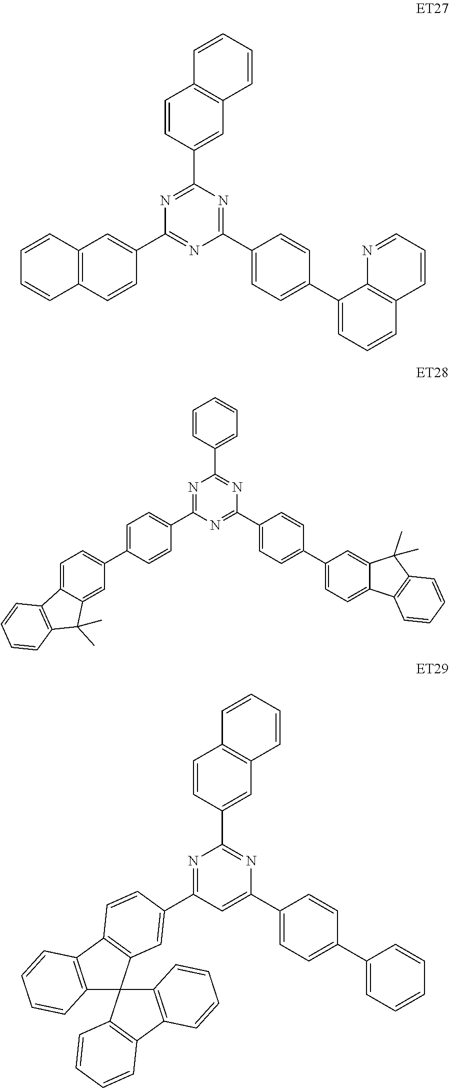 [SMILES: c1ccc2cc(-c3nc(-c4ccc(-c5cccc6cccnc56)cc4)nc(-c4ccc5ccccc5c4)n3)ccc2c1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1]

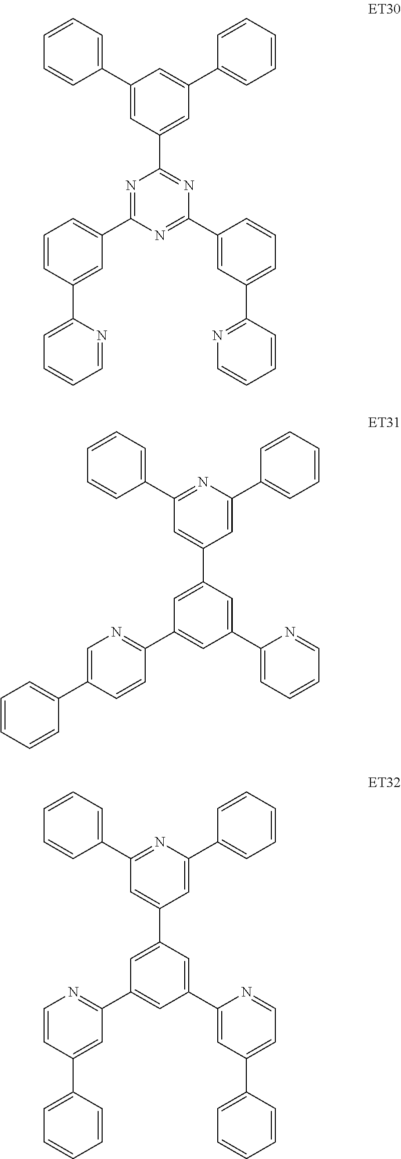 [SMILES: c1ccc(-c2cc(-c3ccccc3)cc(-c3nc(-c4cccc(-c5ccccn5)c4)nc(-c4cccc(-c5ccccn5)c4)n3)c2)cc1 ; c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1]

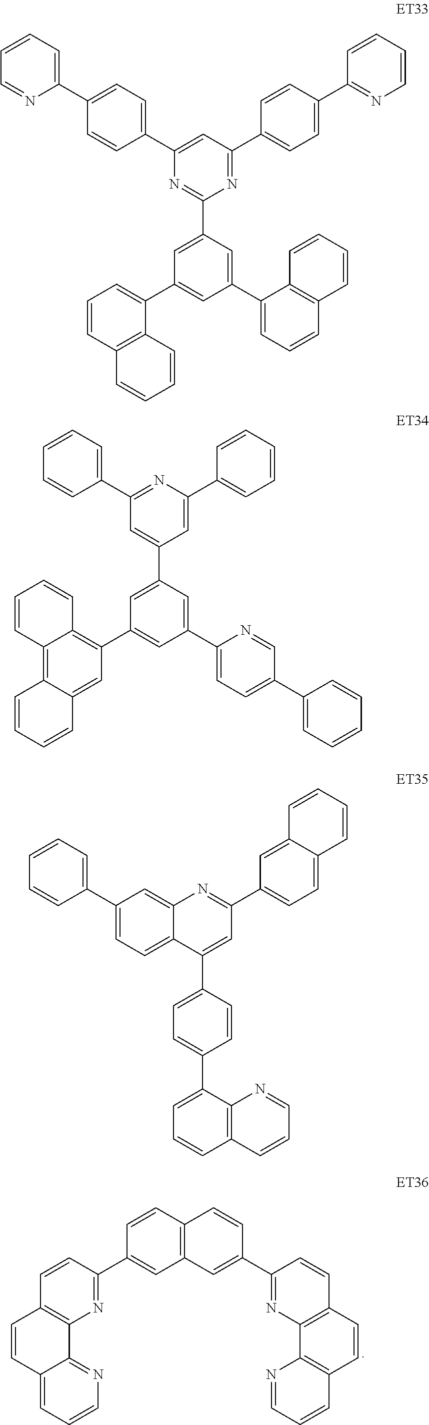

In an embodiment, the electron transport region ETR may include a metal halide such as LiF, NaCl, CsF, RbCl, RbI, CuI, and KI; a lanthanide such as Yb; or a co-deposited material of a metal halide and a lanthanide. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. In another embodiment, the electron transport region ETR may include a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region ETR in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies any of the aforementioned ranges, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies any of the above-described ranges, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may include a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In an embodiment, the second electrode EL2 may have a multilayered structure that includes a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, in an embodiment, the second electrode EL2 may be electrically connected to an auxiliary electrode. If the second electrode EL2 is electrically connected to an auxiliary electrode, resistance of the second electrode EL2 may decrease.

As shown in FIG. 10, in an embodiment, the light-emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, when the capping layer CPL includes an inorganic material, the inorganic material may include an alkaline metal compound (e.g., LiF), an alkaline earth metal compound (e.g., MgF₂), SiON, SiNx, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

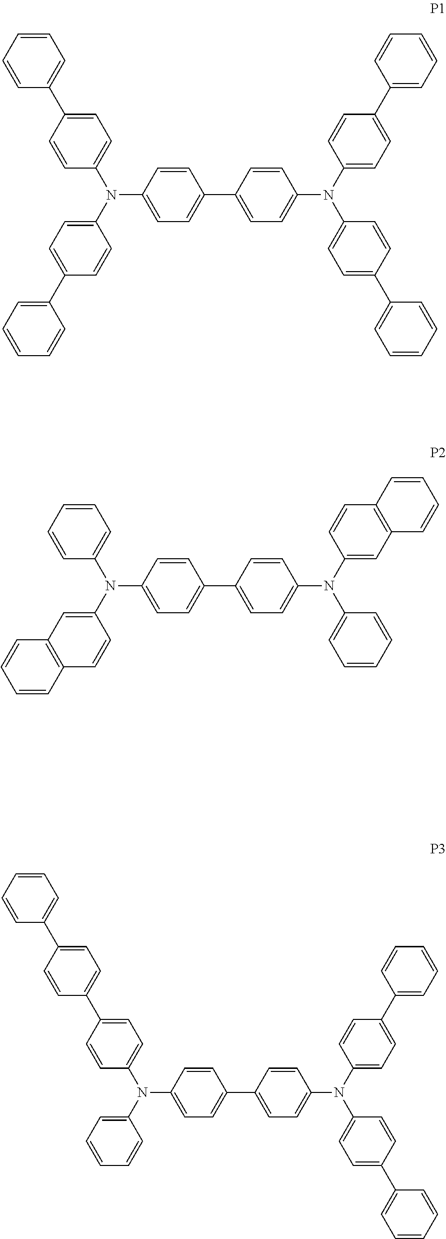 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

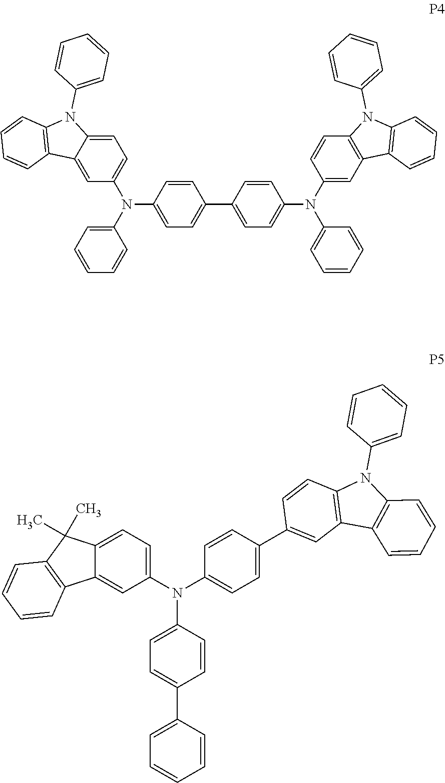 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

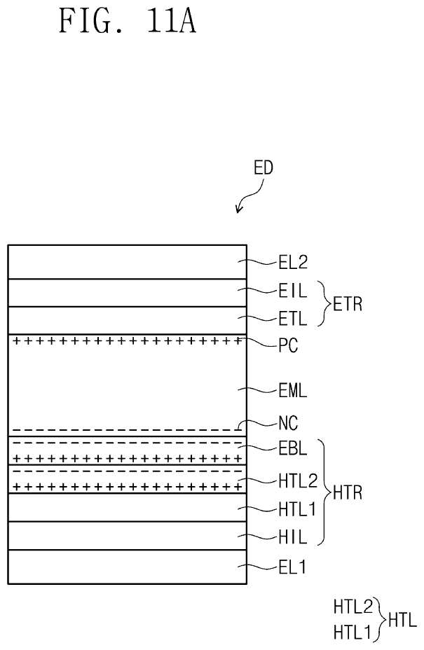

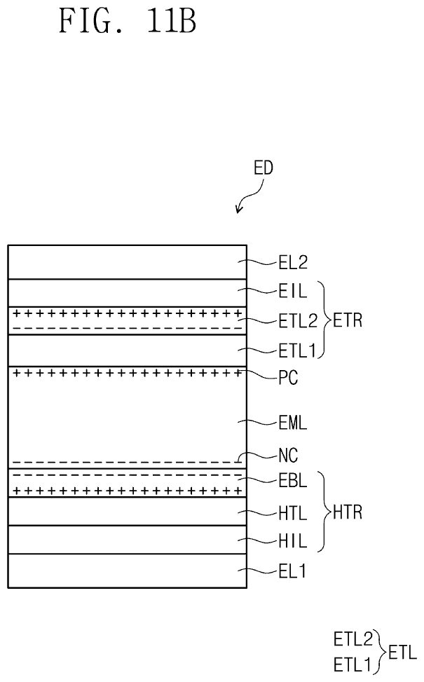

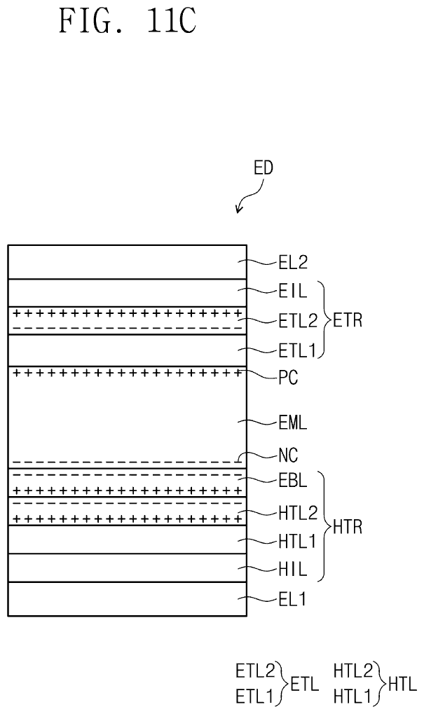

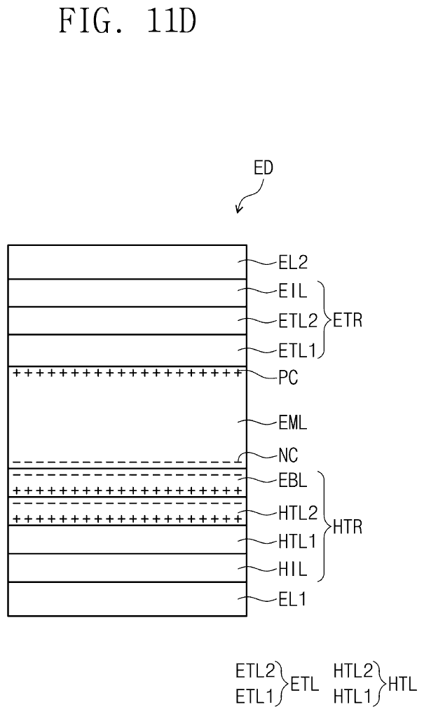

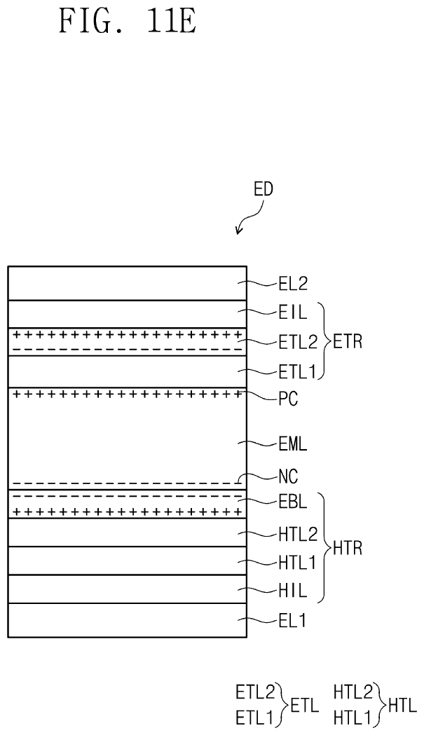

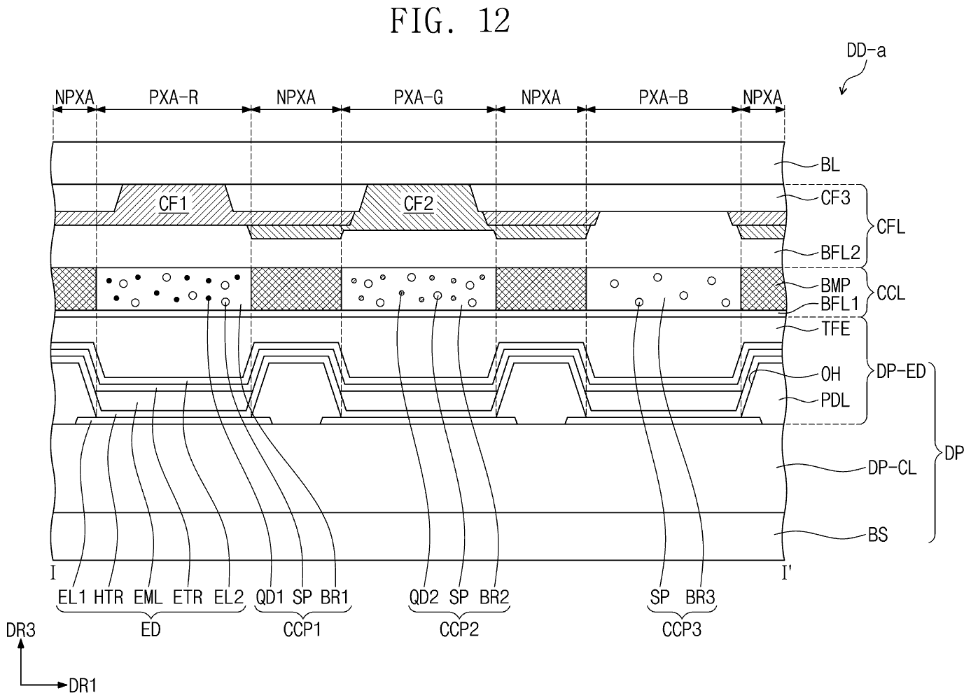

FIGS. 11A to 11E are each a schematic cross-sectional view of a light emitting element according to an embodiment. FIGS. 11A to 11E each show a light emitting element according to one of FIGS. 6 to 8, and display positive and negative charges induced on surfaces of emission layers, electron blocking layers, hole transport layers, and/or electron transport layers to show GSP characteristics provided from each layer.

In the light emitting elements ED shown in FIGS. 11A to 11E, the electron blocking layer EBL included in the hole transport region HTR may have a surface potential in which positive charges PC are induced in a direction of the first electrode EL1 and negative charges NC are induced in a direction of the second electrode EL2. The electron blocking layer EBL may have the first negative GSP as described above. In the light emitting elements ED shown in FIGS. 11A to 11E, the emission layer EML may have a surface potential in which negative charges NC are induced in the direction of the first electrode EL1 and positive charges PC are induced in the direction of the second electrode EL2. The emission layer EML may have the fourth positive GSP as described above.

In the light emitting element ED shown in FIG. 11A, the hole transport layer HTL may have a multilayered structure, and the electron transport layer ETL may have a single-layered structure. For example, the hole transport layer HTL may include a first hole transport layer HTL1 and a second hole transport layer HTL2. Among the first and second hole transport layers HTL1 and HTL2, the second hole transport layer HTL2 adjacent to the emission layer EML may have a surface potential in which positive charges PC are induced in the direction of the first electrode EL1 and negative charges NC are induced in the direction of the second electrode EL2. The second hole transport layer HTL2 may have the second negative GSP as described above. The electron transport layer ETL having a single-layered structure may have the fifth positive GSP or the fifth negative GSP, but embodiments are not limited thereto.

In the light emitting element ED shown in FIG. 11B, the hole transport layer HTL may have a single-layered structure, and the electron transport layer ETL may have a multilayered structure. For example, the electron transport layer ETL may include a first electron transport layer ETL1 and a second electron transport layer ETL2. Among the first and second electron transport layers ETL1 and ETL2, the second electron transport layer ETL2 adjacent to the second electrode EL2 may have a surface potential in which negative charges NC are induced in the direction of the first electrode EL1 and positive charges PC are induced in the direction of the second electrode EL2. The second electron transport layer ETL2 may have the first positive GSP. The hole transport layer HTR having a single-layered structure may have the second positive GSP or the third negative GSP, but embodiments are not limited thereto.

In the light emitting elements ED shown in FIGS. 11C to 11E, the hole transport layer HTL and the electron transport layer ETL may each have multilayered structure. For example, the hole transport layer HTL may include a first hole transport layer HTL1 and a second hole transport layer HTL2, and the electron transport layer ETL may include a first electron transport layer ETL1 and a second electron transport layer ETL2.

Referring to FIG. 11C, among the first and second hole transport layers HTL1 and HTL2, the second hole transport layer HTL2 adjacent to the emission layer EML may have a surface potential in which positive charges PC are induced in the direction of the first electrode EL1 and negative charges NC are induced in the direction of the second electrode EL2. Among the first and second electron transport layers ETL1 and ETL2, the second electron transport layer ETL2 adjacent to the second electrode EL2 may have a surface potential in which negative charges NC are induced in the direction of the first electrode EL1 and positive charges PC are induced in the direction of the second electrode EL2. For example, the second hole transport layer HTL2 may have the second negative GSP, the second electron transport layer ETL2 may have the first positive GSP, the first hole transport layer HTL1 may have the second positive GSP or the third negative GSP, and the first electron transport layer ETL1 may have the fifth positive GSP or the fifth negative GSP.

Referring to FIG. 11D, among the first and second hole transport layers HTL1 and HTL2, the second hole transport layer HTL2 adjacent to the emission layer EML may have a surface potential in which positive charges PC are induced in the direction of the first electrode EL1 and negative charges NC are induced in the direction of the second electrode EL2. For example, the second hole transport layer HTL2 may have the second negative GSP, the first hole transport layer HTL1 may have the second positive GSP or the third negative GSP, and the first electron transport layer ETL1 and the second electron transport layer ETL2 may each independently have the fifth positive GSP or the fifth negative GSP.

Referring to FIG. 11E, among the first and second electron transport layers ETL1 and ETL2, the second electron transport layer ETL2 adjacent to the second electrode EL2 may have a surface potential in which negative charges NC are induced in the direction of the first electrode EL1 and positive charges PC are induced in the direction of the second electrode EL2. For example, the second electron transport layer ETL2 may have the first positive GSP, the first hole transport layer HTL1 and the second hole transport layer HTL2 may each independently have the second positive GSP or the third negative GSP, and the first electron transport layer ETL1 may have the fifth positive GSP or the fifth negative GSP.

FIGS. 12 to 15 are each a schematic cross-sectional view of a display device according to embodiments. Hereinafter, in the description of the display devices according to embodiments as shown in FIGS. 12 to 15, the features that have been described above with respect to FIGS. 1 to 11E will not be explained again, and the differing features will be described.

Referring to FIG. 12, a display device DD-a according to an embodiment may include a display panel DP that includes a display device layer DP-ED, a light control layer CCL disposed on the display panel DP, and a color filter layer CFL. In an embodiment shown in FIG. 12, the display panel DP may include a base layer BS, a circuit layer DP-CL provided on the base layer BS, and the display device layer DP-ED, and the display device layer DP-ED may include a light-emitting element ED.

The light-emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 12 may be the same as a structure of a light emitting element ED according to one of FIGS. 3 to 10 as described above.

The emission layer EML of the light emitting element ED included in the display device DD-a according to embodiment may include at least one hole transport layer HTL and/or at least one electron transport layer ETL as described above.

Referring to FIG. 12, the emission layer EML may be disposed in an opening OH defined in a pixel defining film PDL. For example, the emission layer EML, which is separated by the pixel defining film PDL and provided to correspond to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 12, divided patterns BMP may be disposed between the light control parts CCP1, CCP2, and CCP3, which are spaced apart from each other, but embodiments are not limited thereto. In FIG. 12, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 including a first quantum dot QD1 that converts first color light provided from the light-emitting element ED into second color light, a second light control part CCP2 including a second quantum dot QD2 that converts the first color light into third color light, and a third light control part CCP3 that transmits the first color light. In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light-emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may respectively include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, a barrier layer BFL2 may be provided between the light control parts CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each further include an organic film. The barrier layers BFL1 and BFL2 may be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or a dye. The third filter CF3 may include a polymeric photosensitive resin and may not include a pigment or a dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate the boundaries between adjacent filters CF1, CF2, and CF3.

The first to third filters CF1, CF2, and CF3 may be disposed so that they respectively correspond to the red light emitting region PXA-R, the green light emitting region PXA-G, and the blue light emitting region PXA-B. A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

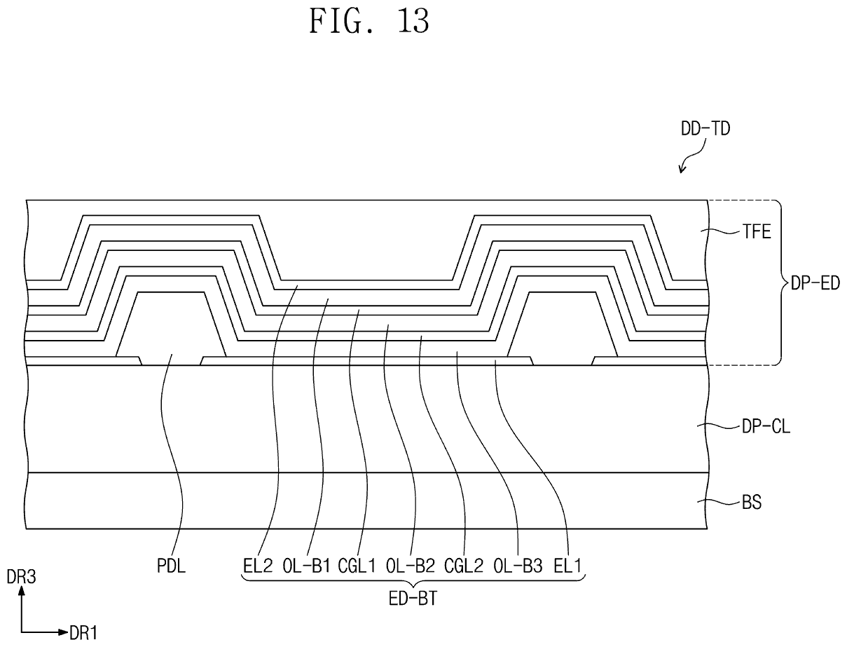

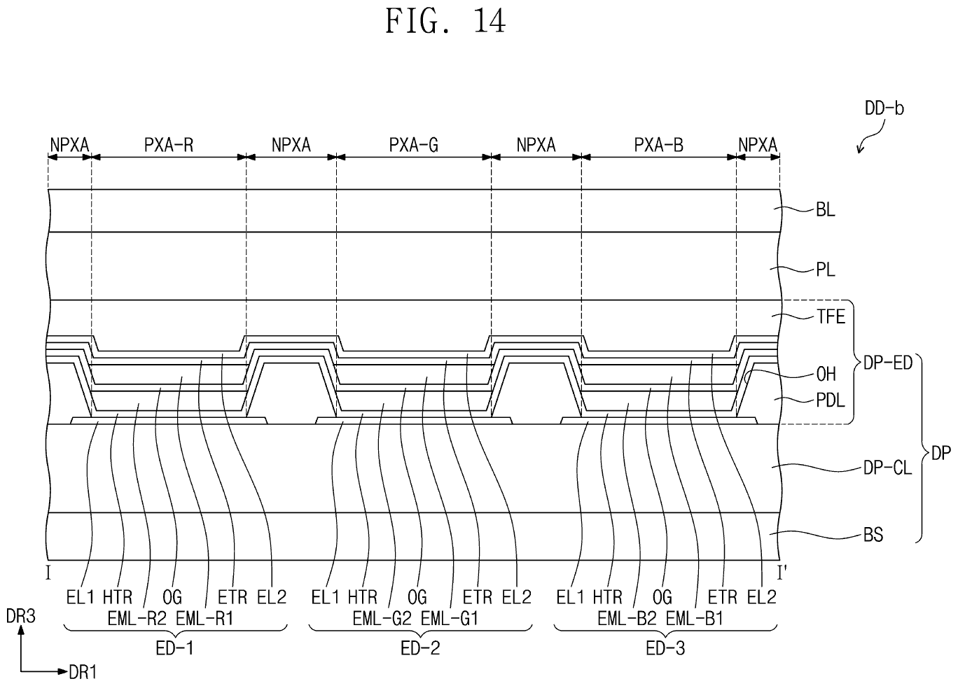

FIG. 13 is a schematic cross-sectional view of a portion of a display device according to an embodiment. In the display device DD-TD according to an embodiment, a light-emitting element ED-BT may include light emitting structures OL-B1, OL-B2, and OL-B3. The light-emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 12), and an electron transport region ETR, which may be disposed in that order between the first electrode EL1 and the second electrode EL2.

For example, the light-emitting element ED-BT included in the display device DD-TD may be a light-emitting element having a tandem structure that includes multiple emission layers.

In an embodiment shown in FIG. 13, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light-emitting element ED-BT that includes the light emitting structures OL-B1, OL-B2, and OL-B3, which emit light in different wavelength ranges, may emit white light.

Charge generation layers CGL1 and CGL2 may be each disposed between two adjacent light emitting structures among the light emitting structures OL-B1, OL-B2, and OL-B3. Charge generation layers CGL1 and CGL2 may each independently include a p-type charge generation layer and/or an n-type charge generation layer.

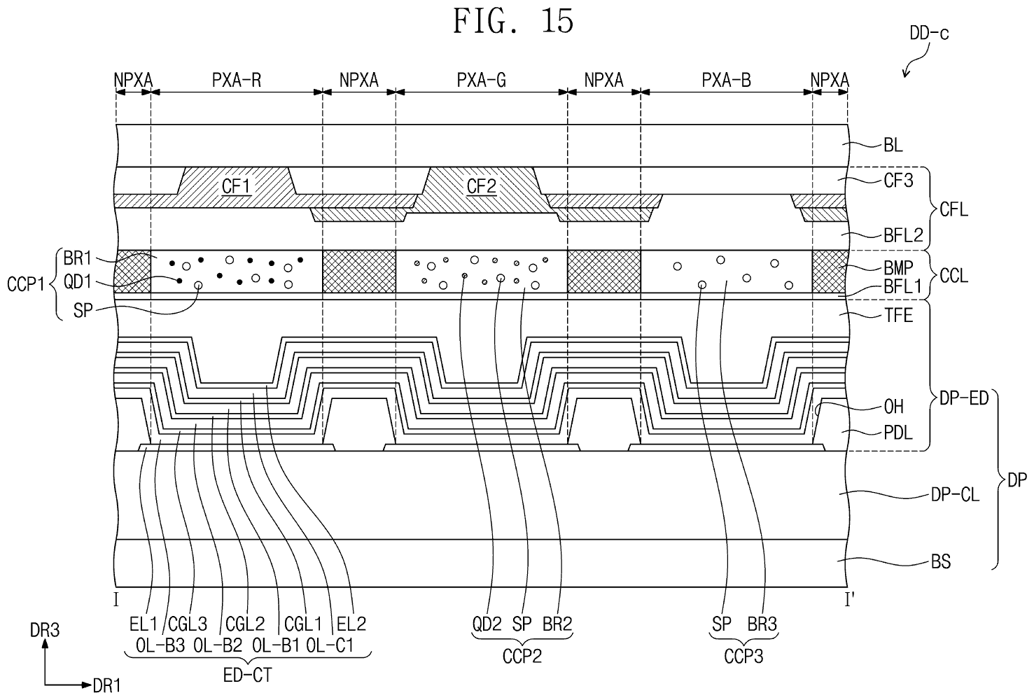

FIG. 14 is a schematic cross-sectional view of a display device DD-b according to an embodiment. FIG. 15 is a schematic cross-sectional view of a display device DD-c according to an embodiment.

Referring to FIG. 14, a display device DD-b according to an embodiment may include light-emitting elements ED-1, ED-2, and ED-3 in which two emission layers are stacked. In comparison to the display device DD shown in FIG. 2, the embodiment shown in FIG. 14 is different at least in that the first to third light-emitting elements ED-1, ED-2, and ED-3 each include two emission layers that are stacked in a thickness direction. In the first to third light-emitting elements ED-1, ED-2, and ED-3, the two emission layers may emit light in a same wavelength region.

The first light-emitting element ED-1 may include a first red emission layer EML-R1 and a second red emission layer EML-R2. The second light-emitting element ED-2 may include a first green emission layer EML-G1 and a second green emission layer EML-G2. The third light-emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for the first to third light-emitting elements ED-1, ED-2, and ED-3. However, embodiments are not limited thereto, and the emission auxiliary part OG may be provided by being patterned within the openings OH defined in the pixel defining film PDL.

The first red emission layer EML-R1, the first green emission layer EML-G1, and the first blue emission layer EML-B1 may be disposed between the emission auxiliary part OG and the electron transport region ETR. The second red emission layer EML-R2, the second green emission layer EML-G2, and the second blue emission layer EML-B2 may be disposed between the hole transport region HTR and the emission auxiliary part OG.

The first light-emitting element ED-1 may include the first electrode EL1, the hole transport region HTR, the second red emission layer EML-R2, the emission auxiliary part OG, the first red emission layer EML-R1, the electron transport region ETR, and the second electrode EL2, which are stacked in that order. The second light-emitting element ED-2 may include the first electrode EL1, the hole transport region HTR, the second green emission layer EML-G2, the emission auxiliary part OG, the first green emission layer EML-G1, the electron transport region ETR, and the second electrode EL2, which are stacked in that order. The third light-emitting element ED-3 may include the first electrode EL1, the hole transport region HTR, the second blue emission layer EML-B2, the emission auxiliary part OG, the first blue emission layer EML-B1, the electron transport region ETR, and the second electrode EL2, are stacked in that order.

An optical auxiliary layer PL may be disposed on the display device layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

In contrast to FIGS. 13 and 14, FIG. 15 shows a display device DD-c that is different at least in that it includes four light emitting structures OL-B1, OL-B2, OL-B3, and OL-C1. A light-emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. Charge generation layers CGL1, CGL2, and CGL3 may each be disposed between two adjacent light emitting structures among the first to fourth light emitting structures OL-B1, OL-B2, OL-B3, and OL-C1. Among the four light emitting structures OL-B1, OL-B2, OL-B3, and OL-C1, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light in wavelength regions that are different from each other.

The charge generation layers CGL1, CGL2, and CGL3 may each independently include a p-type charge generation layer and/or an n-type charge generation layer.

The light emitting element ED according to an embodiment includes an electron blocking layer EBL having a first negative GSP, and a layer that is adjacent to an emission layer among multiple hole transport layers HTL has a negative GSP, and/or a layer that adjacent to a second electrode among multiple electron transport layers ETL has a positive GSP, and accordingly, capacitance may be reduced, resistance may be reduced, and displacement of standard chromaticity may decline. Accordingly, the light emitting element ED may exhibit low driving voltage. When the light emitting element ED according an embodiment is included in a display device, the capacitance of a particular pixel may increase, thereby preventing an issue of ‘first frame response’ regarding color deviation caused when scrolling in a display device. Therefore, the light emitting element ED, when included in a display device, may prevent display quality issues caused by delay in the turn-on time of the light emitting element due to RC delay when implementing a display device having a high refresh rate.

In embodiments, the electronic device may include a display device that includes light-multiple emitting elements, and a control part that controls the display device. The electronic device may be a device that is activated according to an electrical signal. The electronic device may include one or more display devices according to various embodiments. Examples of an electronic device may include large, medium-sized, and small devices, such as a television set, a monitor, a billboard, a personal computer, a laptop computer, a personal digital terminal, a display device for a vehicle, a game console, a portable electronic device, and a camera.

The display device, electronic device, a device of manufacturing thereof, and/or any other relevant devices or components according to embodiments as described herein may be implemented utilizing any suitable hardware, firmware (e.g., an application-specific integrated circuit), software, or a combination of software, firmware, and hardware. For example, the components of the display and/or electronic device may be formed on one integrated circuit (IC) chip or on separate IC chips. In another embodiment, the components of display and/or electronic apparatus and/or device may be implemented on a flexible printed circuit film, a tape carrier package (TCP), a printed circuit board (PCB), or formed on a substrate. In an embodiment, the components of the display and/or electronic device may be a process or thread, running on one or more processors, in one or more computing devices, executing computer program instructions and interacting with other system components for performing the one or more suitable functions described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Persons skilled in the related art should recognize that the functionality of one or more suitable computing devices may be combined or integrated into a single computing device, or the functionality of a particular computing device may be distributed across one or more other computing devices, and such embodiments are considered within the scope of the disclosure.

Hereinafter, a light emitting element according to an embodiment will be described with reference to the Examples and the Comparative Examples. The Examples shown below are only provided to facilitate understanding of the disclosure, and the scope thereof is not limited thereto.

### Examples

### 1. Preparation of Light Emitting Element

For the preparation of light emitting elements according to the Examples and the Comparative Examples, as an anode, a glass substrate having an ITO electrode (Corning, 15 Ω/cm², 1,200 Å) formed thereon was cut to a size of about 50 mm×50 mm×0.7 mm, subjected to ultrasonic cleaning using isopropyl alcohol and pure water for 5 minutes each and ultraviolet irradiation for 30 minutes, and exposed to ozone for cleaning to be mounted on a vacuum deposition apparatus.

On an upper portion of the anode, a hole injection layer having a thickness of 100 Å was formed through the deposition of a p-dopant, and on an upper portion of the hole injection layer, a hole transport layer having a thickness of 1,000 Å was formed, and on an upper portion of the hole transport layer, an electron blocking layer having a thickness of 100 Å was formed through the deposition of Compound EBL1.

A hole transporting host, an electron transporting host, and a phosphorescent dopant were co-deposited to form an emission layer having a thickness of 300 Å, and an electron transport layer having a thickness of 360 Å was formed on an upper portion of the emission layer. An electron injection layer having a thickness of 12 Å was formed through the deposition of Yb on an upper portion of the electron transport layer. A cathode having a thickness of 110 Å was formed through the deposition of AgMg (10%) on an upper portion of the electron injection layer to prepare a light emitting element.

Each layer was formed through vacuum deposition. As for the hole transport layer and the electron transport layer, the materials listed in Table 1 below were used. Each element was prepared to have a pixel size of 2 mm×2 mm.

Compounds used to prepare light emitting elements in the Examples and the Comparative Examples were commercially available products purified through sublimation and used to prepare the elements.

In Table 1, “-” indicates that the corresponding layer is not formed, 1n-GSP indicates Compound EBL1 having a giant surface potential equal to or less than about −10 mV/nm, and 1p-GSP indicates a compound of 2,4,6-tris(biphenyl-3-yl)-1,3,5-triazine having a giant surface potential equal to or greater than about 10 mV/nm. The 1ab-GSP has a smaller absolute GSP value than the 1n-GSP. 4p-GSP is an emission layer having a giant surface potential equal to or greater than about 10 mV/nm and includes SiCzCz as a hole transporting host, SiTrzCz2 as an electron transporting host, and Compound M-b-12 as a phosphorescent dopant (deposition ratio of hole transporting host:electron transporting host:phosphorescent dopant=5.5:3.5:1). Compound 1ab-GSP is a material having an absolute GSP value equal to or less than about 10 mV/nm, and the structure thereof is shown below, and SiCzCz is a material having a negative GSP and an absolute GSP value equal to or less than about 10 mV/nm. Compound 2ab-GSP is mSiTrZ having substantially no or low GSP, with an absolute GSP value equal to or less than about 10 mV/nm.

### (Compounds Used in the Preparation of Light Emitting Elements)

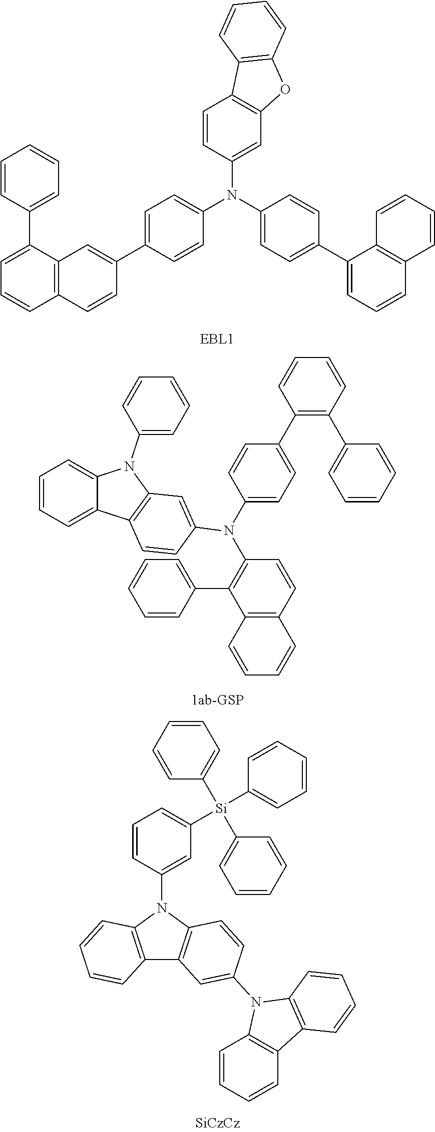 [SMILES: c1ccc(-c2cccc3ccc(-c4ccc(N(c5ccc(-c6cccc7ccccc67)cc5)c5ccc6c(c5)oc5ccccc56)cc4)cc23)cc1 ; c1ccc(-c2ccccc2-c2ccc(N(c3ccc4c5ccccc5n(-c5ccccc5)c4c3)c3ccc4ccccc4c3-c3ccccc3)cc2)cc1 ; c1ccc([Si](c2ccccc2)(c2ccccc2)c2cccc(-n3c4ccccc4c4cc(-n5c6ccccc6c6ccccc65)ccc43)c2)cc1]

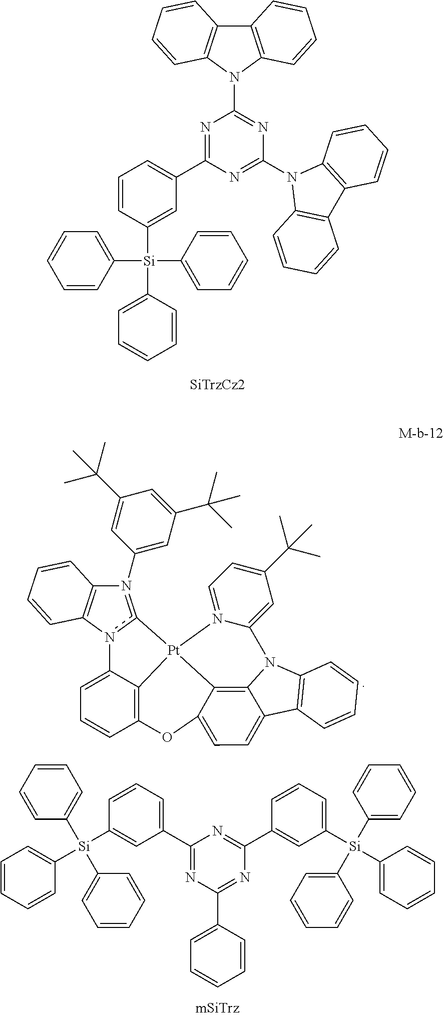

TABLE 1

| | HTL1 | HTL2 | EBL | EML | ETL1 | ETL2 |
|---|---|---|---|---|---|---|
| Example 1 | 1ab-GSP | 1n-GSP | 1n-GSP | 4p-GSP | 2ab-GSP | — |
| Example 2 | 1ab-GSP | — | 1n-GSP | 4p-GSP | 2ab-GSP | 1p-GSP |
| Example 3 | 1ab-GSP | 1n-GSP | 1n-GSP | 4p-GSP | 2ab-GSP | 1p-GSP |
| Comparative | 1ab-GSP | — | SiCzCz | 4p-GSP | 2ab-GSP | — |
| Example 1 | | | | | | |
| Comparative | 1ab-GSP | — | 1n-GSP | 4p-GSP | 2ab-GSP | — |
| Example 2 | | | | | | |
| Comparative | 1n-GSP | — | 1n-GSP | 4p-GSP | 2ab-GSP | — |
| Example 3 | | | | | | |
| Comparative | 1n-GSP | 1ab-GSP | 1n-GSP | 4p-GSP | 2ab-GSP | — |
| Example 4 | | | | | | |
| Comparative | 1ab-GSP | 1ab-GSP | 1n-GSP | 4p-GSP | 1p-GSP | — |
| Example 5 | | | | | | |
| Comparative | 1ab-GSP | — | 1n-GSP | 4p-GSP | 1p-GSP | 2ab-GSP |
| Example 6 | | | | | | |
| Comparative | 1p-GSP | — | 1n-GSP | 4p-GSP | 2ab-GSP | — |
| Example 7 | | | | | | |
| Comparative | 1ab-GSP | 1p-GSP | 1n-GSP | 4p-GSP | 2ab-GSP | — |
| Example 8 | | | | | | |
| Comparative | 1p-GSP | 1ab-GSP | 1n-GSP | 4p-GSP | 2ab-GSP | — |
| Example 9 | | | | | | |
| Comparative | 1ab-GSP | 1ab-GSP | 1n-GSP | 4p-GSP | 1n-GSP | — |
| Example 10 | | | | | | |
| Comparative | 1ab-GSP | 1ab-GSP | 1n-GSP | 4p-GSP | 2ab-GSP | 1n-GSP |
| Example 11 | | | | | | |
| Comparative | 1ab-GSP | 1ab-GSP | 1n-GSP | 4p-GSP | 1n-GSP | 2ab-GSP |
| Example 12 | | | | | | |
| Comparative | 1ab-GSP | 1n-GSP | SiCzCz | 4p-GSP | 2ab-GSP | — |
| Example 13 | | | | | | |
| Comparative | 1ab-GSP | 1n-GSP | 1p-GSP | 4p-GSP | 2ab-GSP | — |
| Example 14 | | | | | | |

### 2. Property Evaluation of Light Emitting Elements

Table 2 shows evaluation results of light emitting elements for Examples 1 to 3 and Comparative Examples 1 to 14. To evaluate the light emitting element characteristics of Examples 1 to 3 and Comparative Examples 1 to 14, maximum capacitance (Cₘₐₓ) was measured from about −2 V to about 5 V in capacitance-voltage mode with the frequency of impedance analyzer set to about 1000 Hz and VAC set to about 100 mV, and a value having a greatest capacitance was calculated. Resistance was calculated by measuring the resistance of the light emitting elements of Examples 1 to 3 and Comparative Examples 1 to 14 at 4 V (R=V/I at 4 V).

Standard chromaticity displacement (Δu′v′) was measured after producing a panel composed of red, green, and blue pixels using the light emitting elements of Examples 1 to 3 and Comparative Examples 1 to 14. The luminance ratio of each RGB pixel was 0.24, 0.68, and 0.08, and for each Example and Comparative Example, after starting the panel operation, the color coordinates of the 1st and 10th frames were calculated. The maximum efficiency of white was 400 nits, but when comparing the color coordinates of the 1st and 10th frames, the luminance was measured in a low grayscale range, under conditions corresponding to 11 gray based on blue 10th frame. Using the x, y color coordinates obtained from the measurement, u′ v′ was converted through the equations, u′=4x/(−2x+12y+3) and v′=9y/(−2x+12y+3), and Δu′ v′ was calculated through the equation Δu′v′=sqrt(u′\hat{ }2+v′\hat{ }2).

The measurement results of maximum capacitance (Cₘₐₓ), resistance, and standard chromaticity displacement (Δu′v′) are shown in Table 2.

TABLE 2

| | Cₘₐₓ (nF) | Resistance | Δu′v′ |
|---|---|---|---|
| Example 1 | 2.0 | 30 | 0.0080 |
| Example 2 | 2.2 | 32 | 0.0094 |
| Example 3 | 1.5 | 31 | 0.0050 |
| Comparative Example 1 | 4 | 31 | 0.0351 |
| Comparative Example 2 | 3.0 | 35 | 0.0150 |
| Comparative Example 3 | 2.8 | 30 | 0.0138 |
| Comparative Example 4 | 2.7 | 31 | 0.0101 |
| Comparative Example 5 | 2.4 | 38 | 0.0150 |
| Comparative Example 6 | 2.3 | 34 | 0.110 |
| Comparative Example 7 | 2.2 | 48 | 0.0301 |
| Comparative Example 8 | 2.3 | 42 | 0.0205 |
| Comparative Example 9 | 2.3 | 44 | 0.0254 |
| Comparative Example 10 | 2.9 | 30 | 0.0190 |
| Comparative Example 11 | 2.8 | 31 | 0.0189 |
| Comparative Example 12 | 2.9 | 30 | 0.0190 |
| Comparative Example 13 | 4.1 | 30 | 0.0360 |
| Comparative Example 14 | 4.1 | 29 | 0.0350 |

Referring to the results in Table 2, the light emitting elements of the Examples are found to have lower maximum capacitance (Cₘₐₓ), resistance, and/or displacement of standard chromaticity (Δu′v′) than the light emitting elements of the Comparative Examples.

In Example 1, the electron blocking layer is found to have a negative GSP, and the second hole transport layer adjacent to the emission layer among multiple hole transport layers is found to have a negative GSP, thereby showing a maximum capacitance (Cₘₐₓ) of 2.0, indicating low capacitance. Example 1 is found to have a lower resistance value than the Comparative Examples, and to have a small displacement value of less than 0.01 in standard chromaticity, thereby showing excellent color characteristics.

In Example 2, the electron blocking layer is found to have a negative GSP, and the electron transport layer adjacent to the second electrode (cathode) among multiple electron transport layers is found to have a positive GSP, resulting in low capacitance and small displacement of standard chromaticity. Example 2 is found to have lower resistance than some Comparative Examples.

In Example 3, the electron blocking layer is found to have a negative GSP, the hole transport layers and the electron transport layers are all found to have GSP characteristics according to an embodiment, resulting in low capacitance and small displacement of standard chromaticity. Example 3 is found to have lower resistance than some Comparative Examples.

In comparison, in Comparative Example 1, the electron blocking layer, the hole transport layer, and the electron transport layer all are found not to have the GSP characteristics according to an embodiment, showing high capacitance, and a displacement value of 0.01 or greater in standard chromaticity, which is greater than that of the light emitting elements of the Examples.

In Comparative Example 2, although the electron blocking layer included a material having negative GSP characteristics, holes were blocked excessively, resulting in a relatively high resistance of the light emitting element. In Comparative Example 2, the hole transport layer and the electron transport layer each had a single-layered structure and did not have the GSP characteristics according to an embodiment, thereby showing a higher resistance value than the light emitting elements according to the Examples, and also showing large displacement of standard chromaticity.

It is seen that Comparative Example 3 included the electron blocking layer and the hole transport layer each having a negative GSP, but the single-layered hole transport layer had a negative GSP, showing a relatively higher capacitance than the Examples, and also showing a large displacement value of 0.01 or greater in standard chromaticity.

It is seen that Comparative Example 4 included the electron blocking layer and the hole transport layer each having a negative GSP, but the hole transport layer adjacent to the first electrode among the two hole transport layers had a negative GSP, showing a relatively higher capacitance than the Examples, and also showing a large displacement value of 0.01 or greater in standard chromaticity.

Comparative Example 5 includes an electron blocking layer having a negative GSP and an electron transport layer having a positive GSP, but a hole transport layer that is adjacent to an emission layer among multiple hole transport layers does not have a negative GSP. Comparative Example 5 showed a higher capacitance and a greater resistance value than the Examples, and showed large displacement of standard chromaticity.

Comparative Example 6 has a structure in which, among two electron transport layers, an electron transport layer having a positive GSP is adjacent to an emission layer and spaced away from a second electrode. Comparative Example 6 showed a higher capacitance than the Examples, and showed large resistance and displacement of standard chromaticity.

Comparative Examples 7 to 9 each have a structure in which a hole transport layer having a single-layered structure has a positive GSP, or one of two hole transport layers has a positive GSP. Comparative Examples 7 to 9 showed significantly higher resistance and displacement of standard chromaticity than the Examples.

Comparative Examples 10 to 12 each have a structure in which an electron transport layer having a single-layered structure has a negative GSP, or one of two electron transport layers has a negative GSP. Comparative Examples 10 to 12 are found to have a similar level of resistance as the Examples, but also having a higher capacitance than the Examples, and also having a large displacement value of 0.01 or greater in standard chromaticity. As shown by Comparative Examples 10 to 12, having a negative GSP does not make it less effective in preventing electron leakage.

Comparative Example 13 includes a structure in which a second hole transport layer that is adjacent to an emission layer among multiple hole transport layers has a negative GSP. In Comparative Example 13, the electron blocking layer does not contain a material having a negative GSP, and thus is less effective in inhibiting hole injection or preventing electron leakage. Accordingly, Comparative Example 13 is found to have a higher capacitance than the Examples, and also to have a large displacement of 0.01 or greater in standard chromaticity.

Comparative Example 14 includes a structure in which an electron blocking layer has a positive GSP and a second hole transport layer adjacent to an emission layer among multiple hole transport layers has a negative GSP. Accordingly, Comparative Example 14 is found to have a higher capacitance than the Examples, and also to have a large displacement value of 0.01 or greater in standard chromaticity.

A light emitting element according to embodiments may exhibit low capacitance and also show low resistance and displacement of standard chromaticity. Accordingly, the light emitting element may exhibit low driving voltage properties.

A display device according to an embodiment includes the above-described light emitting element, and may thus provide enhanced display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a hole transport region disposed on the first electrode;
an emission layer disposed on the hole transport region;
an electron transport region disposed on the emission layer; and
a second electrode disposed on the electron transport region, wherein
the hole transport region includes:
a hole injection layer disposed on the first electrode;
at least one hole transport layer disposed on the hole injection layer; and
an electron blocking layer disposed on the hole transport layer and having a first negative giant surface potential,
the electron transport region includes:
at least one electron transport layer disposed on the emission layer; and
an electron injection layer disposed on the electron transport layer,
the at least one hole transport layer includes a plurality of hole transport layers and/or the at least one electron transport layer includes a plurality of electron transport layers,
when the light emitting element includes a plurality of hole transport layers, a hole transport layer adjacent to the emission layer among the plurality of hole transport layers has a second negative giant surface potential, and
when the light emitting element includes a plurality of electron transport layers, an electron transport layer adjacent to the second electrode among the plurality of electron transport layers has a first positive giant surface potential.

2. The light emitting element of claim 1, wherein the second negative giant surface potential has an absolute value that is less than an absolute value of the first negative giant surface potential.

3. The light emitting element of claim 1, wherein the first negative giant surface potential is equal to or less than about −10 mV/nm.

4. The light emitting element of claim 1, wherein
the at least one hole transport layer comprises:
a first hole transport layer disposed on the hole injection layer; and
a second hole transport layer disposed on the first hole transport layer and having the second negative giant surface potential, and
the second negative giant surface potential is equal to or less than about −10 mV/nm.

5. The light emitting element of claim 4, wherein
the first hole transport layer has a second positive giant surface potential or a third negative giant surface potential, and
an absolute value of the second positive giant surface potential and an absolute value of the third negative giant surface potential are each independently equal to or less than about 10 mV/nm.

6. The light emitting element of claim 5, wherein the second positive giant surface potential and the third negative giant surface potential each have a smaller absolute value than the second negative giant surface potential.

7. The light emitting element of claim 1, wherein
the at least one hole transport layer comprises:
a first hole transport layer disposed on the hole injection layer;
a second hole transport layer disposed on the first hole transport layer; and
a third hole transport layer disposed on the second hole transport layer,
at least one of the second hole transport layer and the third hole transport layer has the second negative giant surface potential, and
the second negative giant surface potential is equal to or less than about −10 mV/nm.

8. The light emitting element of claim 7, wherein
the second hole transport layer has the second negative giant surface potential,
the first hole transport layer and the third hole transport layer each independently have a third positive giant surface potential or a fourth negative giant surface potential, and
an absolute value of the third positive giant surface potential and an absolute value of the fourth negative giant surface potential are each independently equal to or less than about 10 mV/nm.

9. The light emitting element of claim 7, wherein
the third hole transport layer has the second negative giant surface potential,
the first hole transport layer and the second hole transport layer each independently have a third positive giant surface potential or a fourth negative giant surface potential, and
an absolute value of the third positive giant surface potential and an absolute value of the fourth negative giant surface potential are each independently equal to or less than about 10 mV/nm.

10. The light emitting element of claim 1, wherein the emission layer has a fourth positive giant surface potential.

11. The light emitting element of claim 1, wherein
the at least one electron transport layer comprises:
a first electron transport layer disposed on the emission layer; and
a second electron transport layer disposed on the first electron transport layer and having the first positive giant surface potential, and
the first positive giant surface potential is equal to or greater than about 10 mV/nm.

12. The light emitting element of claim 11, wherein
the first electron transport layer has a fifth positive giant surface potential or a fifth negative giant surface potential, and
an absolute value of the fifth positive giant surface potential and an absolute value of the fifth negative giant surface potential are each independently equal to or less than about 10 mV/nm.

13. The light emitting element of claim 1, wherein
the at least one electron transport layer comprises:
a first electron transport layer disposed on the emission layer;
a second electron transport layer disposed on the first electron transport layer; and
a third electron transport layer disposed on the second electron transport layer,
the second electron transport layer or the third electron transport layer has the first positive giant surface potential, and
the first positive giant surface potential is equal to or greater than about 10 mV/nm.

14. The light emitting element of claim 13, wherein
the second electron transport layer has the first positive giant surface potential,
the first electron transport layer and the third electron transport layer each independently have a sixth positive giant surface potential or a sixth negative giant surface potential, and
an absolute value of the sixth positive giant surface potential and an absolute value of the sixth negative giant surface potential are each independently equal to or less than about 10 mV/nm.

15. The light emitting element of claim 13, wherein
the third electron transport layer has the first positive giant surface potential,
the first electron transport layer and the second electron transport layer each independently have a sixth positive giant surface potential or a sixth negative giant surface potential, and
an absolute value of the sixth positive giant surface potential and an absolute value of the sixth negative giant surface potential are each independently equal to or less than about 10 mV/nm.

16. The light emitting element of claim 1, wherein
the at least one hole transport layer comprises:
a first hole transport layer disposed on the hole injection layer; and
a second hole transport layer disposed on the first hole transport layer and having the second negative giant surface potential,
the at least one electron transport layer comprises a first electron transport layer disposed on the emission layer,
the second negative giant surface potential is equal to or less than about −10 mV/nm, and
an absolute value of the giant surface potential of the first hole transport layer and an absolute value of the giant surface potential of the first electron transport layer are each independently equal to or less than about 10 mV/nm.

17. The light emitting element of claim 1, wherein
the at least one hole transport layer comprises a first hole transport layer disposed on the hole injection layer,
the at least one electron transport layer comprises:
a first electron transport layer disposed on the emission layer; and
a second electron transport layer disposed on the first electron transport layer and having the first positive giant surface potential,
the first positive giant surface potential is equal to or greater than about 10 mV/nm, and
an absolute value of the giant surface potential of the first hole transport layer and an absolute value of the giant surface potential of the first electron transport layer are each independently equal to or less than about 10 mV/nm.

18. The light emitting element of claim 1, wherein
the at least one hole transport layer comprises:
a first hole transport layer disposed on the hole injection layer; and
a second hole transport layer disposed on the first hole transport layer and having the second negative giant surface potential,
the at least one electron transport layer comprises:
a first electron transport layer disposed on the emission layer; and
a second electron transport layer disposed on the first electron transport layer and having the first positive giant surface potential,
the second negative giant surface potential is equal to or less than about −10 mV/nm,
the first positive giant surface potential is equal to or greater than about 10 mV/nm, and
an absolute value of the giant surface potential of the first hole transport layer and an absolute value of the giant surface potential of the first electron transport layer are each independently equal to or less than about 10 mV/nm.

19. An electric device comprising:
a display device, the display device comprising:
a circuit layer disposed on a base layer;
a pixel defining film disposed on the circuit layer and having a plurality of pixel openings defined therein; and
a plurality of light emitting elements disposed on the circuit layer, wherein
each light emitting element includes a first electrode, a hole transport region, an emission layer, an electron transport region, and a second electrode that are sequentially stacked,
the hole transport region includes:
a hole injection layer disposed on the first electrode;
at least one hole transport layer disposed on the hole injection layer; and
an electron blocking layer disposed on the hole transport layer and having a first negative giant surface potential,
the electron transport region comprises:
at least one electron transport layer disposed on the emission layer; and
an electron injection layer disposed on the electron transport layer,
the at least one hole transport layer includes a plurality of hole transport layers and/or the at least one electron transport layer includes a plurality of electron transport layers,
when the at least one hole transport layer includes a plurality of hole transport layers, a hole transport layer adjacent to the emission layer among the plurality of hole transport layers has a second negative giant surface potential, and
when the at least one electron transport layer includes a plurality of electron transport layers, an electron transport layer adjacent to the second electrode among the plurality of electron transport layers has a first positive giant surface potential.

20. The electric device of claim 19, further comprising:
a light control layer including quantum dots; and
a color filter layer disposed on the light control layer, wherein
the color filter layer includes:
a first filter that transmits red light,
a second filter that transmits green light, and
a third filter that transmits blue light.
